(19) United States
(12) Patent Application Publication
(10) Pub. No.: US 2014/0131686 A1
(43) Pub. Date: May 15, 2014

(54) Light-Emitting Element, Light-Emitting Device, Lighting Device, and Electronic Device

(71) Applicant: Semiconductor Energy Laboratory Co., Ltd., Kanagawa-ken (JP)

(72) Inventors: Sachiko KAWAKAMI, Atsugi (JP); Kaori OGITA, Isehara (JP); Nobuharu OHSAWA, Zama (JP); Hiromi SEO, Sagamihara (JP); Satoshi SEO, Sagamihara (JP)

(73) Assignee: Semiconductor Energy Laboratory Co., Ltd., Kanagawa-ken (JP)

(21) Appl. No.: 14/077,560

(22) Filed: Nov. 12, 2013

(30) Foreign Application Priority Data
Nov. 13, 2012 (JP) 2012-249635

(51) Int. Cl. H01L 51/50; H01L 51/00

(52) U.S. Cl. CPC H01L 51/5012; H01L 51/0072; H01L 51/0074
USPC 257/40; 548/440

(57) ABSTRACT

To provide a light-emitting element including a novel compound, which is capable of being used for a transport layer, a host material, or a light-emitting material in a light-emitting element. A light-emitting element which includes an EL layer between a pair of electrodes. In an analysis of the EL layer by liquid chromatography mass spectrometry, an ion having a mass/charge ratio (m/z) of 772 is detected, and by collision of an argon gas with the ion at an energy greater than or equal to 30 eV and less than or equal to 100 eV, one or more of an ion having a mass/charge ratio (m/z) of 349 and an ion having a mass/charge ratio (m/z) of 425 is or are detected.

### BACKGROUND OF THE INVENTION

1. Field of the Invention

The present invention relates to a light-emitting element. The present invention also relates to a light-emitting device, a lighting device, and an electronic device each of which includes the light-emitting element.

2. Description of the Related Art

As next generation lighting devices or light-emitting devices, light-emitting devices using light-emitting elements (organic EL elements) in which organic compounds are used as light-emitting substances have been developed rapidly because of their advantages of thinness, lightweightness, high-speed response to input signals, low power consumption, and the like.

In an organic EL element, voltage application between electrodes between which a light-emitting layer is provided causes recombination of electrons and holes injected from the electrodes, which brings a light-emitting substance into an excited state, and the return from the excited state to the ground state is accompanied by light emission. Since the wavelength of light emitted from a light-emitting substance is peculiar to the light-emitting substance, use of different types of organic compounds for light-emitting substances makes it possible to provide light-emitting elements which exhibit various wavelengths, i.e., various colors.

In the case of light-emitting devices which are expected to display images, such as displays, at least three-color light, i.e., red light, green light, and blue light, is necessary for reproduction of full-color images. Furthermore, in application to lighting devices, light having wavelength components in the entire visible light region is ideal for obtaining a high color rendering property. Actually, light obtained by mixing two or more kinds of light having different wavelengths is often used for lighting application. Note that it is known that with a mixture of three-color light, i.e., red light, green light, and blue light, white light having a high color rendering property can be provided.

Light emitted from a light-emitting substance is peculiar to the substance as described above. However, important performances as a light-emitting element, such as a lifetime, power consumption, and even emission efficiency, are not only dependent on the light-emitting substance but also greatly dependent on layers other than the light-emitting layer, an element structure, properties of an emission center substance and a host material, compatibility between them, carrier balance, and the like. For the above-described reasons, light-emitting element materials with a variety of molecular structures have been proposed (e.g., see Patent Document 1).

However, as commercialization of light-emitting devices, lighting devices, and the like which include light-emitting elements (organic EL elements) is advanced, a further reduction of power consumption and an improvement, of reliability are demanded. Accordingly, a light-emitting element having more favorable characteristics, e.g., a light-emitting element with a longer lifetime, higher efficiency, and lower drive voltage, is expected to be developed.

### REFERENCE

### Patent Document

[Patent Document 1] Japanese Published Patent Application No. 2007-15933

### SUMMARY OF THE INVENTION

Thus, an object of one embodiment of the present invention is to provide a light-emitting element having favorable characteristics. Another object of one embodiment of the present invention is to provide a light-emitting device, a lighting device, and an electronic device each of which includes the light-emitting element.

One embodiment of the present invention is a light-emitting element which includes an EL layer between a pair of electrodes. In an analysis of the EL layer by liquid chromatography mass spectrometry, an ion having a mass/charge ratio (m/z) of 772 is detected, and by collision of an argon gas with the ion having a mass/charge ratio (m/z) of 772 at an energy greater than or equal to 50 eV and less than or equal to 100 eV, at least one of an ion having a mass/charge ratio (m/z) of 349 and an ion having a mass/charge ratio (m/z) of 425 is detected.

In the above structure, the ion having a mass/charge ratio (m/z) of 349 and the ion having a mass/charge ratio (m/z) of 425 may each be a product ion of the ion having a mass/charge ratio (m/z) of 772.

One embodiment of the present invention is a light-emitting element which includes an EL layer between a pair of electrodes. In an analysis of the EL layer by liquid chromatography mass spectrometry, at least one of an ion having a mass/charge ratio (m/z) of 349 and being a compound in which a carbazole skeleton and a dibenzothiophene skeleton are bonded and an ion having a mass/charge ratio (m/z) of 425 and being a compound in which a carbazole skeleton, a dibenzothiophene skeleton, and a benzene ring are bonded is detected.

One embodiment of the present invention is a light-emitting element which includes an EL layer between a pair of electrodes. In an analysis of the EL layer by liquid chromatography mass spectrometry, an ion whose composition formula is C₅₄H₃₀N₂S₂, C₅₄H₃₁N₂S₂, C₅₄H₃₂N₂S₂, C₅₄H₃₃N₂S₂ or C₅₄H₃₄N₂S₂ is detected, and in a mass spectrometric analysis of the ion whose composition formula is C₅₄H₃₀N₂S₂, C₅₄H₃₁N₂S₂, C₅₄H₃₂N₂S₂, C₅₄H₃₃N₂S₂ or C₅₄H₃₄N₂S₂ and which is separated by liquid chromatography, at least one of an ion whose composition formula is C₂₄H₁₂NS, C₂₄H₁₃NS, C₂₄H₁₄NS, C₂₄H₁₅NS or C₂₄H₁₆NS and an ion whose composition formula is C₃₀H₁₇NS, C₃₀H₁₈NS, C₃₀H₁₉NS, C₃₀H₂₀NS or C₃₀H₂₁NS is detected.

One embodiment of the present invention is a light-emitting element which includes an EL layer including a compound between a pair of electrodes. In an analysis of the compound by liquid chromatography mass spectrometry, at least one of a mass/charge ratio (m/z) corresponding to a molecular weight of C₅₄H₃₀N₂S₂, C₅₄H₃₁N₂S₂, C₅₄H₃₂N₂S₂, C₅₄H₃₃N₂S₂ or C₅₄H₃₄N₂S₂, a mass/charge ratio (m/z) corresponding to a molecular weight of C₃₀H₁₇NS, C₃₀H₁₈NS, C₃₀H₁₉NS, C₃₀H₂₀NS or C₃₀H₂₁NS, and a mass/charge ratio (m/z) corresponding to a molecular weight of C₂₄H₁₂NS, C₂₄H₁₃NS, C₂₄H₁₄NS, C₂₄H₁₅NS or C₂₄H₁₆NS is detected.

In the above structure, a molecular structure of the compound preferably includes a carbazole skeleton and a dibenzothiophene skeleton.

One embodiment of the present invention is a light-emitting element which includes an EL layer between a pair of electrodes. The EL layer contains a compound which is represented by General Formula (G1) and includes a carbazole skeleton and a dibenzothiophene skeleton. In an analysis of the EL layer by liquid chromatography mass spectrometry, by collision of an argon gas with an ion of the compound represented by General Formula (G1) at an energy greater than or equal to 50 eV and less than or equal to 100 eV, one or both of an ion of a compound represented by General Formula (G2) and an ion of a compound represented by General Formula (G3) are detected.

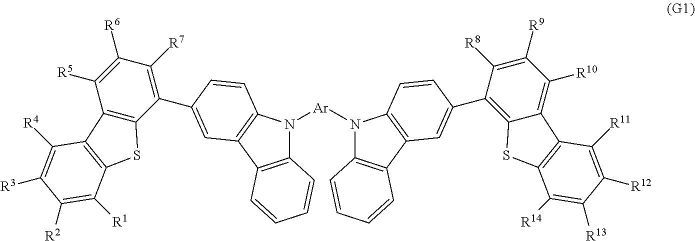

Note that in General Formula (G1), Ar represents a substituted or unsubstituted phenylene group or a substituted or unsubstituted biphenyldiyl group, and R¹ to R¹⁴ separately represent hydrogen, an alkyl group having 1 to 4 carbon atoms, or an aryl group having 6 to 12 carbon atoms.

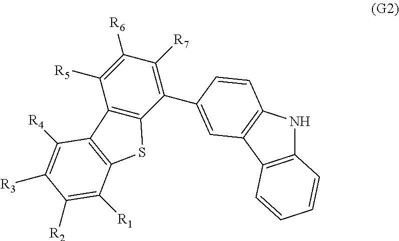

Note that in General Formula (G2), R¹ to R⁷ separately represent hydrogen, an alkyl group having 1 to 4 carbon atoms, or an aryl group having 6 to 12 carbon atoms.

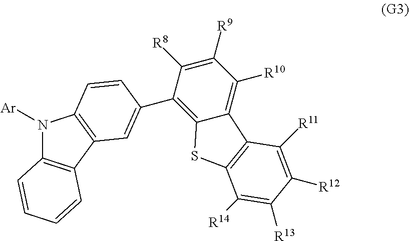

Note that in General Formula (G3), Ar represents a substituted or unsubstituted phenyl group or a substituted or unsubstituted biphenyl group, and R⁸ to R¹⁴ separately represent hydrogen, an alkyl group having 1 to 4 carbon atoms, or an aryl group having 6 to 12 carbon atoms.

Embodiments of the present invention are a light-emitting device, a lighting device, and an electronic device each of which includes any of the above light-emitting elements.

In one embodiment of the present invention, a light-emitting element having favorable characteristics can be provided. In embodiments of the present invention, a light-emitting device, a lighting device, and an electronic device each of which includes the light-emitting element can be provided.

### BRIEF DESCRIPTION OF THE DRAWINGS

FIGS. 1A and 1B are conceptual diagrams of light-emitting elements.

FIG. 2 illustrates application modes of a light-emitting element.

FIGS. 3A and 3B are NMR charts of mDBTCz2P-II.

FIGS. 4A and 4B each show an absorption spectrum and an emission spectrum of mDBTCz2P-II.

FIG. 5 shows luminance-current density characteristics of a light-emitting element 1.

FIG. 6 shows luminance-voltage characteristics of a light-emitting element 1.

FIG. 7 shows current efficiency-luminance characteristics of a light-emitting element 1.

FIG. 8 shows current-voltage characteristics of a light-emitting element 1.

FIG. 9 shows an emission spectrum of a light-emitting element 1.

FIG. 10 shows normalized luminance-time characteristics of a light-emitting element 1.

FIG. 11 shows luminance-current density characteristics of a light-emitting element 2.

FIG. 12 shows luminance-voltage characteristics of a light-emitting element 2.

FIG. 13 shows current efficiency-luminance characteristics of a light-emitting element 2.

FIG. 14 shows current-voltage characteristics of a light-emitting element 2.

FIG. 15 shows luminance-current density characteristics of a comparative light-emitting element 2.

FIG. 16 shows luminance-voltage characteristics of a comparative light-emitting element 2.

FIG. 17 shows current efficiency-luminance characteristics of a comparative light-emitting element 2.

FIG. 18 shows current-voltage characteristics of a comparative light-emitting element 2.

FIG. 19 shows emission spectra of a light-emitting element 2 and a comparative light-emitting element 2.

FIG. 20 shows normalized luminance-time characteristics of a light-emitting element 2 and a comparative light-emitting element 2.

FIG. 21 shows luminance-current density characteristics of a light-emitting element 3.

FIG. 22 shows luminance-voltage characteristics of a light-emitting element 3.

FIG. 23 shows current efficiency-luminance characteristics of a light-emitting element 3.

FIG. 24 shows current-voltage characteristics of a light-emitting element 3.

FIG. 25 shows luminance-current density characteristics of a light-emitting element 4.

FIG. 26 shows luminance-voltage characteristics of a light-emitting element 4.

FIG. 27 shows current efficiency-luminance characteristics of a light-emitting element 4.

FIG. 28 shows current-voltage characteristics of a light-emitting element 4.

FIG. 29 shows an emission spectrum of a light-emitting element 3.

FIG. 30 shows an emission spectrum of a light-emitting element 4.

FIG. 31 shows normalized luminance-time characteristics of a light-emitting element 3.

FIG. 32 shows normalized luminance-time characteristics of a light-emitting element 4.

FIG. 33 shows luminance-current density characteristics of a light-emitting element 5.

FIG. 34 shows luminance-voltage characteristics of a light-emitting element 5.

FIG. 35 shows current efficiency-luminance characteristics of a light-emitting element 5.

FIG. 36 shows current-voltage characteristics of a light-emitting element 5.

FIG. 37 shows luminance-current density characteristics of a light-emitting element 6.

FIG. 38 shows luminance-voltage characteristics of a light-emitting element 6.

FIG. 39 shows current efficiency-luminance characteristics of a light-emitting element 6.

FIG. 40 shows current-voltage characteristics of a light-emitting element 6.

FIG. 41 shows an emission spectrum of a light-emitting element 5.

FIG. 42 shows an emission spectrum of a light-emitting element 6.

FIG. 43 shows normalized luminance-time characteristics of a light-emitting element 5.

FIG. 44 shows normalized luminance-time characteristics of a light-emitting element 6.

FIG. 45 shows an LC/MS spectrum of mDBTCz2P-II.

FIG. 46 shows an LC/MS spectrum of mDBTCz2P-II.

FIG. 47 shows an LC/MS spectrum of mDBTCz2P-II.

FIG. 48 shows an LC/MS spectrum of mDBTCz2P-II.

FIG. 49 shows an LC/MS spectrum of mDBTCz2P-II.

FIG. 50 shows a ToF-SIMS spectrum of mDBTCz2P-II.

FIG. 51 shows a ToF-SIMS spectrum of mDBTCz2P-II.

### DETAILED DESCRIPTION OF THE INVENTION

Hereinafter, embodiments of the present invention will be described. However, the present invention can be implemented in many different modes, and it is easily understood by those skilled in the art that modes and details of the present invention can be modified in various ways without departing from the spirit and the scope of the present invention. Therefore, the present invention is not construed as being limited to description of the embodiments.

In this specification and the like, a mass/charge ratio (m/z) and a molecular weight are each expressed as a value obtained by rounding the least significant digit up or down. For example, a numerical value of 0.01 has a range of greater than or equal to 0.005 and less than or equal to 0.014. In a similar manner, a numerical value of 3 has a range of greater than or equal to 2.5 and less than or equal to 3.4.

### Embodiment 1

A light-emitting element in this embodiment includes a compound having a structure in which two carbazole skeletons each include carbazole, the 3-position of which is bonded to the 4-position of a dibenzothiophene skeleton and these two carbazole skeletons are linked via a benzene ring or biphenyl.

The compound is a novel compound that has a wide band gap and high triplet excitation energy and can be suitably used for a material in a light-emitting element. The compound also has an excellent carrier-transport property.

Carbon in the dibenzothiophene skeleton may also have a substituent. The substituent can be either an alkyl group having 1 to 4 carbon atoms or an aryl group having 6 to 12 carbon atoms. Specific examples of the alkyl group having 1 to 4 carbon atoms are a methyl group, an ethyl group, a propyl group, and a butyl group. Specific examples of the aryl group having 6 to 12 carbon atoms are a phenyl group, a naphthyl group, a biphenyl group, and a tolyl group.

Further, the compound having such a structure has a wide band gap, and therefore can be suitably used for a host material, in which an emission center substance that emits fluorescence or phosphorescence having a wavelength equal to or longer than a wavelength of blue light is dispersed. Since the compound has a wide band gap and thus high triplet excitation energy, the energy of carriers that recombine at the host material can be effectively transferred to the emission center substance. Thus, a light-emitting element with high emission efficiency can be fabricated.

Also for a carrier-transport layer adjacent to a light-emitting layer containing an emission center substance that emits fluorescence or phosphorescence having a wavelength equal to or longer than a wavelength of blue light, the compound having a wide band gap can be suitably used without deactivating excitation energy of the emission center substance. Thus, a light-emitting element with high emission efficiency can be fabricated.

The compound has a high carrier-transport property and can be suitably used for a host material or a carrier-transport layer in a light-emitting element. Since the compound has a high carrier-transport property, a light-emitting element having low driving voltage can be fabricated.

The above-described compound can also be represented by General Formula (G1).

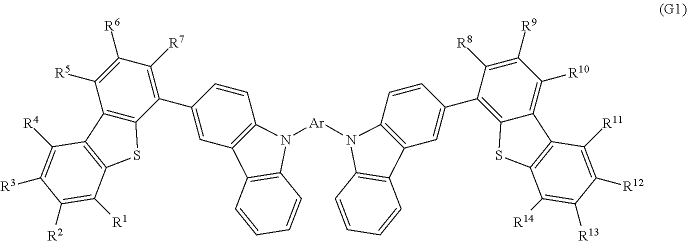

Note that in General Formula (G1), Ar represents a substituted or unsubstituted phenylene group or a substituted or unsubstituted biphenyldiyl group, and R¹ to R¹⁴ separately represent hydrogen, an alkyl group having 1 to 4 carbon atoms, or an aryl group having 6 to 12 carbon atoms.

In General Formula (G1), when the group represented by Ar has a substituent, the substituent can be an alkyl group having 1 to 4 carbon atoms, an alkoxyl group having 1 or 2 carbon atoms, fluorine, an aryl group having 6 to 12 carbon atoms, a trialkylsilyl group, or the like.

Specific examples of the group represented by Ar in General Formula (G1) are groups represented by Structural Formulae (Ar-1) to (Ar-30).

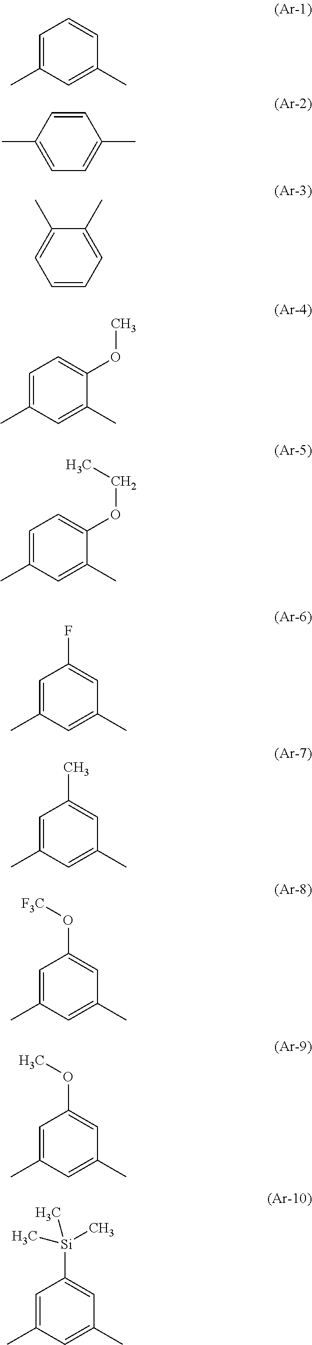

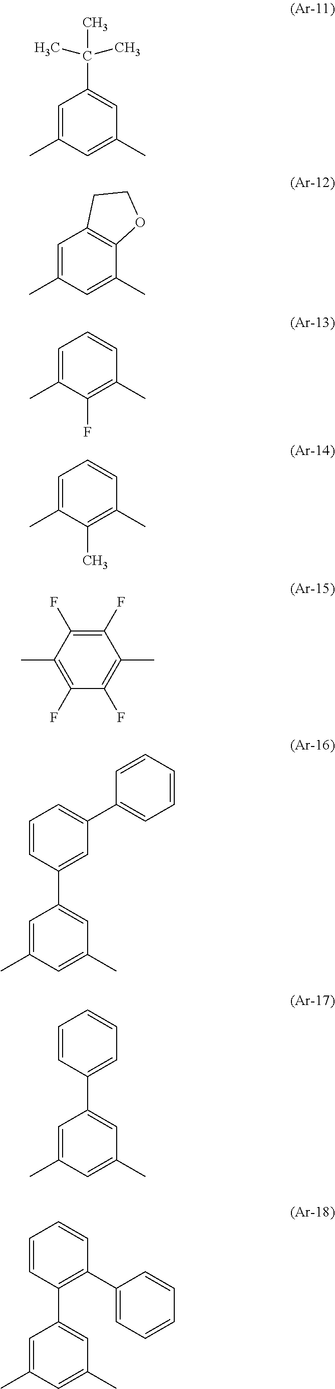

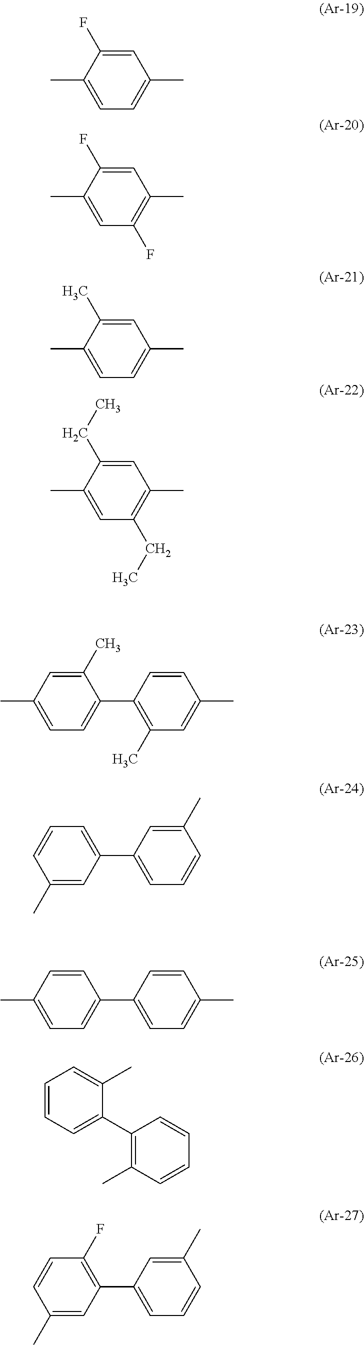

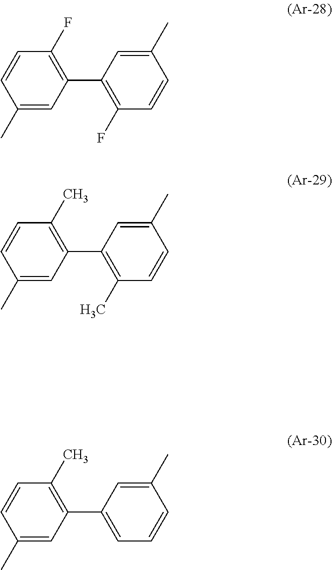

Specific examples of the groups represented by R¹ to R¹⁴ in General Formula (G1) are groups represented by Structural Formulae (R-1) to (R-6).

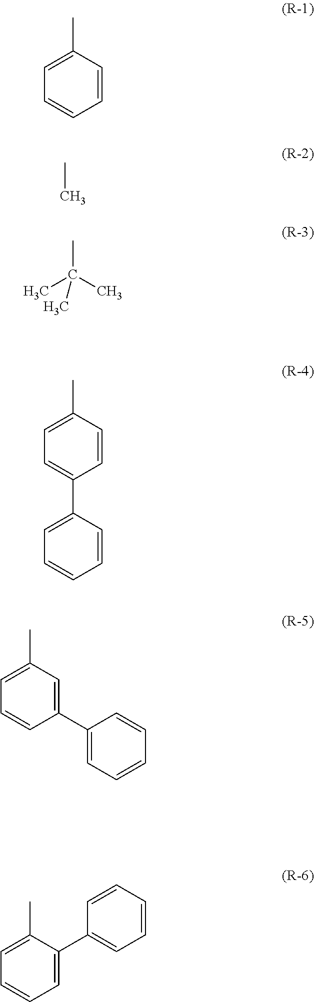

It is preferable in General Formula (G1) that, when the dibenzothiophene skeleton has a substituent, the substituent be positioned at one or more of R¹, R³, R⁶, R⁹, R¹², and R¹⁴. This is because the substituent is easy to introduce through bromination or conversion into a boronic acid and a compound having such a substituent is easy to synthesize. It is further preferable that R¹ to R¹⁴ be each hydrogen, in which case the compound can have an advantage in terms of availability of a raw material and synthesis can be inexpensive.

When Ar is a phenylene group, the phenylene group is preferably meta-substituted or ortho-substituted, in which case the compound can have an advantage in terms of energy gap. Also when Ar is a biphenyl group, the biphenyl group is preferably meta-substituted or ortho-substituted, in which case the compound can have a wide energy gap and high triplet excitation energy. Also when Ar is a biphenyldiyl group, the biphenyldiyl group is preferably meta-substituted or ortho-substituted, in which case the compound can have an advantage in terms of energy gap.

It is conceivable that when an EL layer which is included in a light-emitting element and which contains the compound represented by General Formula (G1) is analyzed by mass spectrometry, the C—N bond between N of the carbazole skeleton and the aryl group to which the N of the carbazole skeleton is bonded in General Formula (G1) is cleaved due to, energy applied at the time of the mass spectrometric analysis. As a result of this cleavage, a compound (General Formula (G2)) in which the carbazole skeleton and the dibenzothiophene skeleton are bonded, and a compound (General Formula (G3)) in which the carbazole skeleton, the dibenzothiophene skeleton, and the aryl group are bonded are possibly generated.

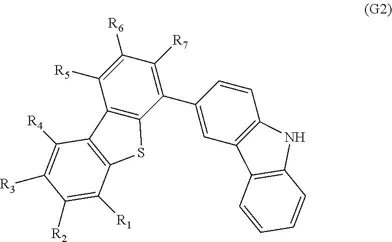

Note that in General Formula (G2), R¹ to R⁷ separately represent hydrogen, an alkyl group having 1 to 4 carbon atoms, or an aryl group having 6 to 12 carbon atoms.

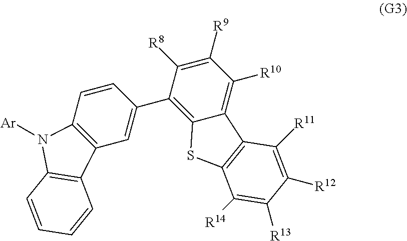

Note that in General Formula (G3), Ar represents a substituted or unsubstituted phenyl group or a substituted or unsubstituted biphenyl group, and R⁸ to R¹⁴ separately represent hydrogen, an alkyl group having 1 to 4 carbon atoms, or an aryl group having 6 to 12 carbon atoms.

Thus, results of the mass spectrometric analysis possibly show detection of an ion presumed to be the compound represented by General Formula (G1), an ion presumed to be the compound (General Formula (G2)) in which the carbazole skeleton and the dibenzothiophene skeleton are bonded, and/or an ion presumed to be the compound (General Formula (G3)) in which the carbazole skeleton, the dibenzothiophene skeleton, and the benzene ring are bonded.

To the mass spectrometric analysis, for example, analysis using a liquid chromatography mass spectrometer (LC/MS), analysis using a time-of-flight secondary ion mass spectrometer (ToF-SIMS), or the like can be applied.

Specific examples of structures of the compound represented by General Formula (G1) are substances represented by Structural Formulae (100) to (136) and the like.

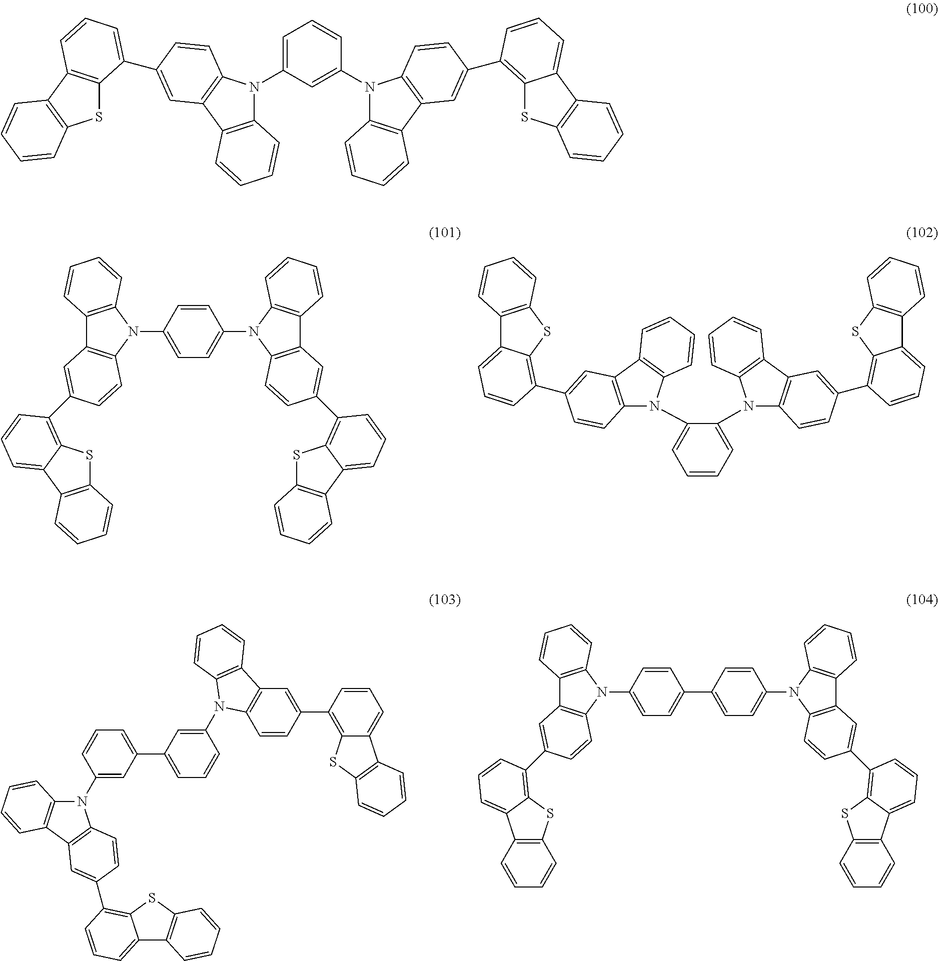

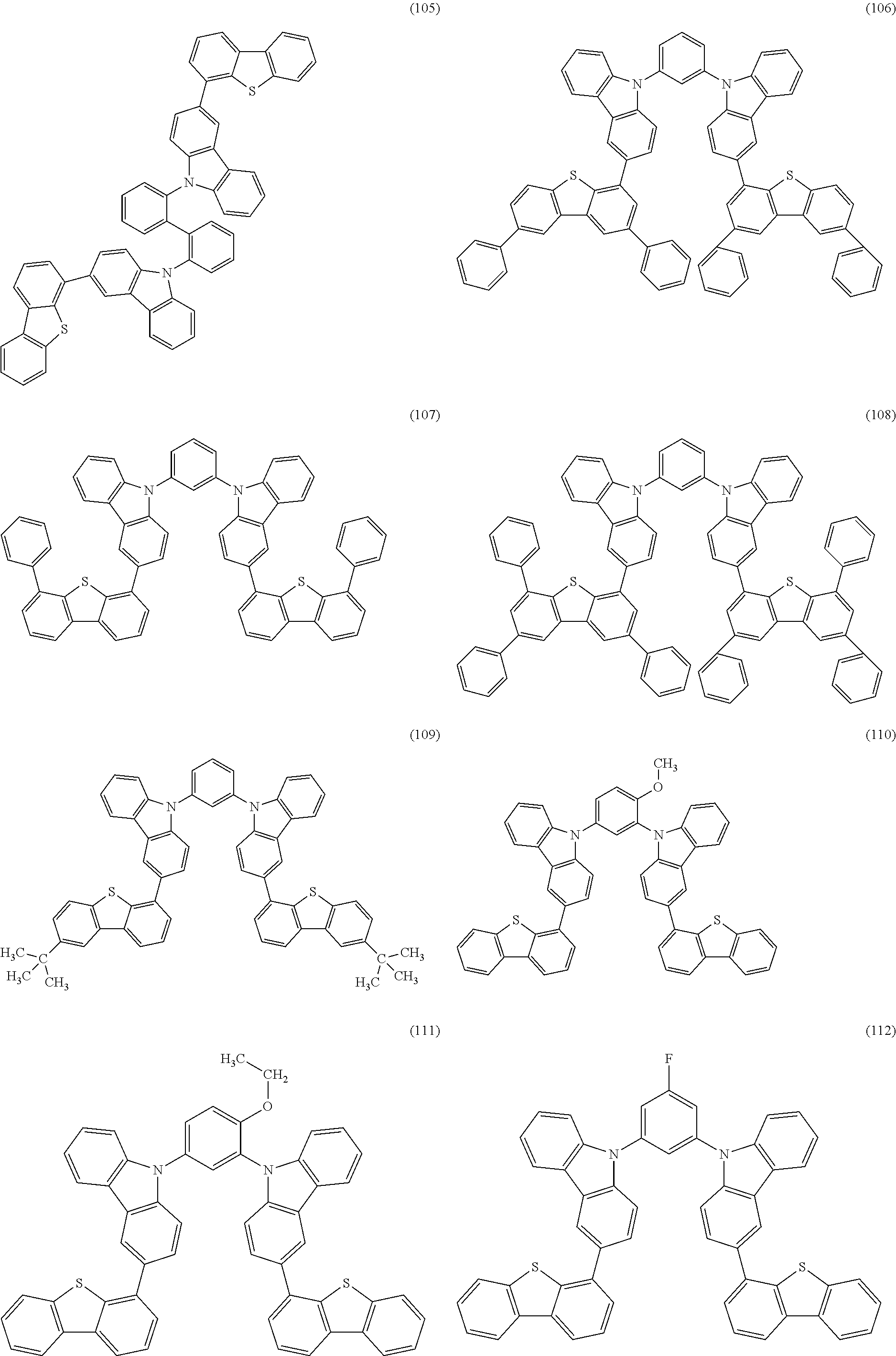

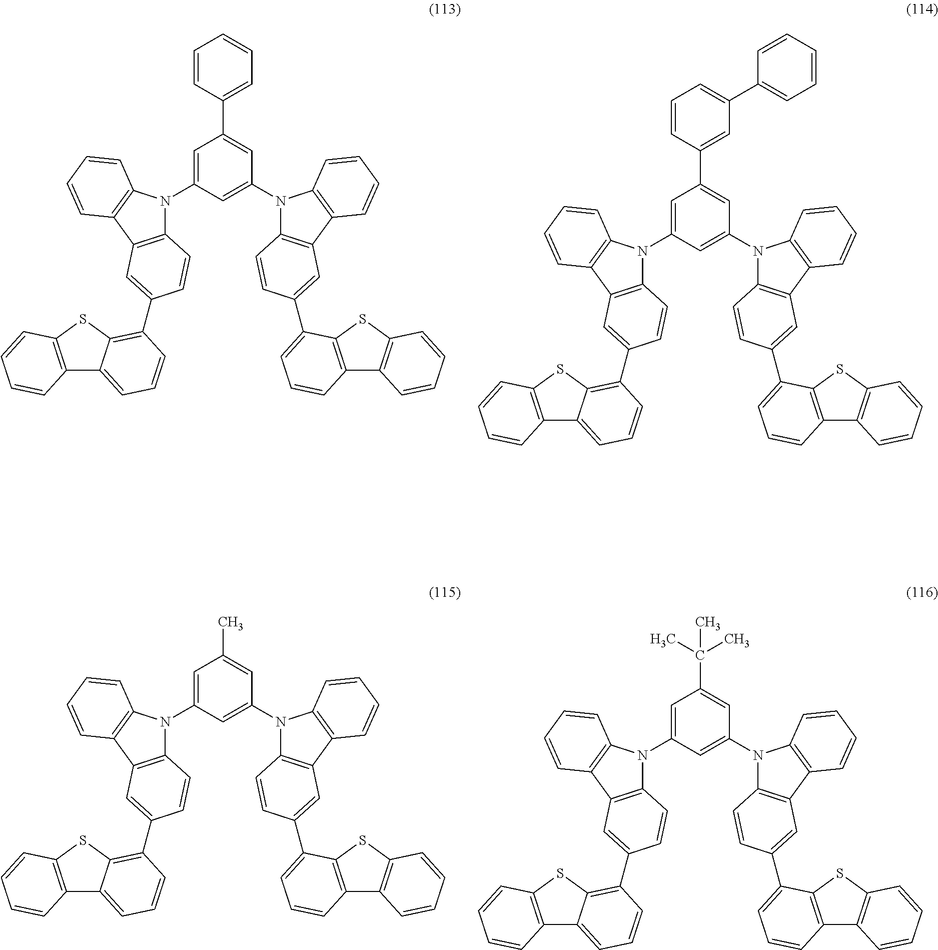

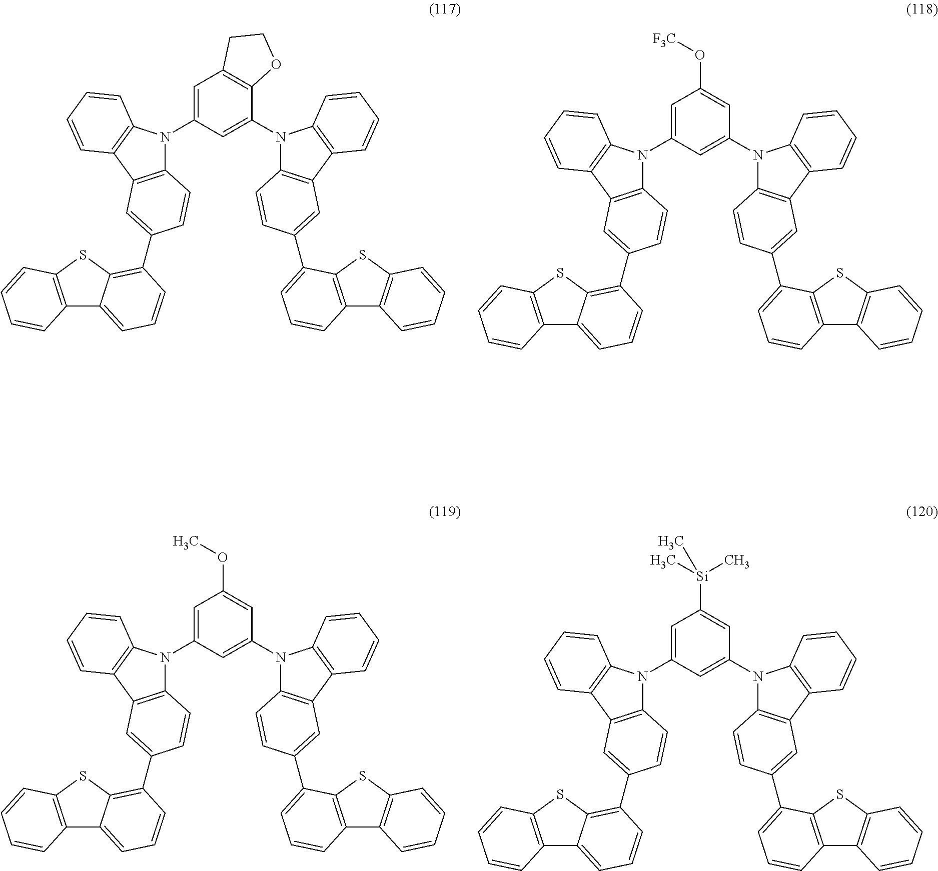

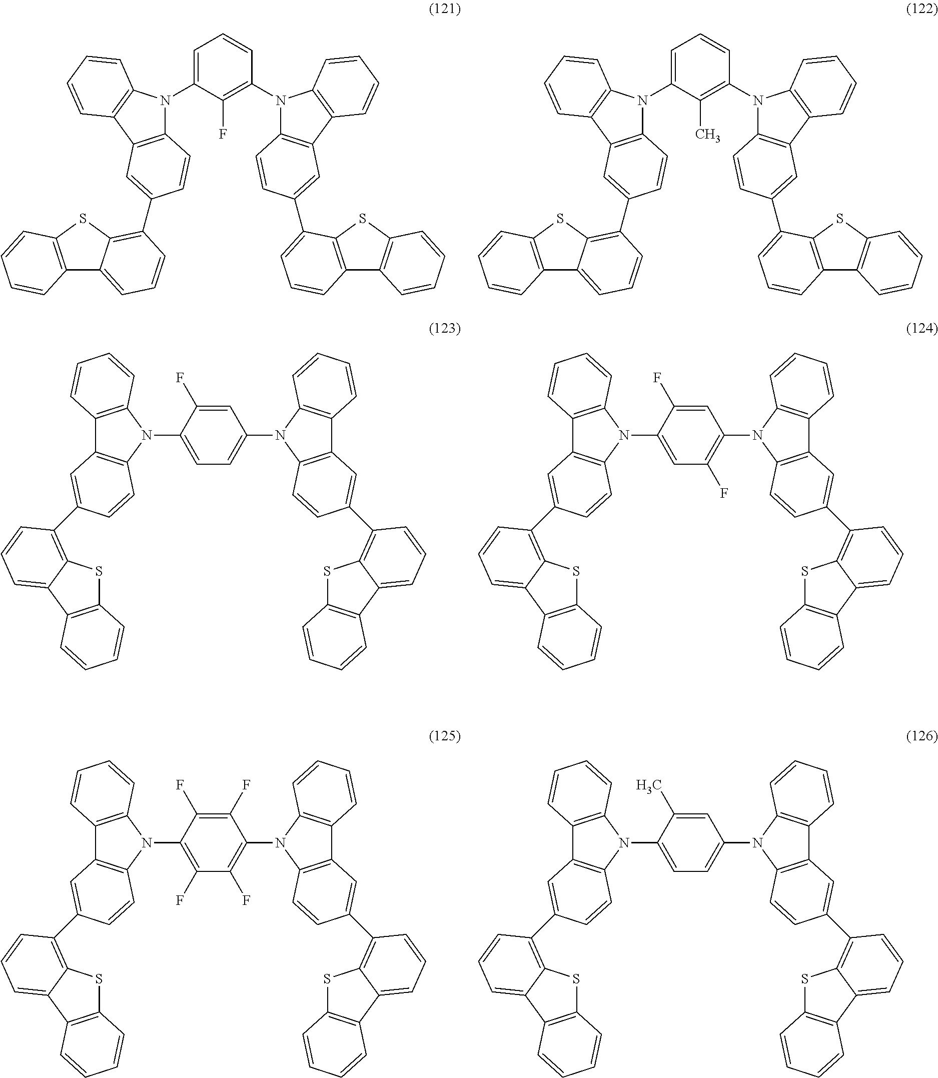

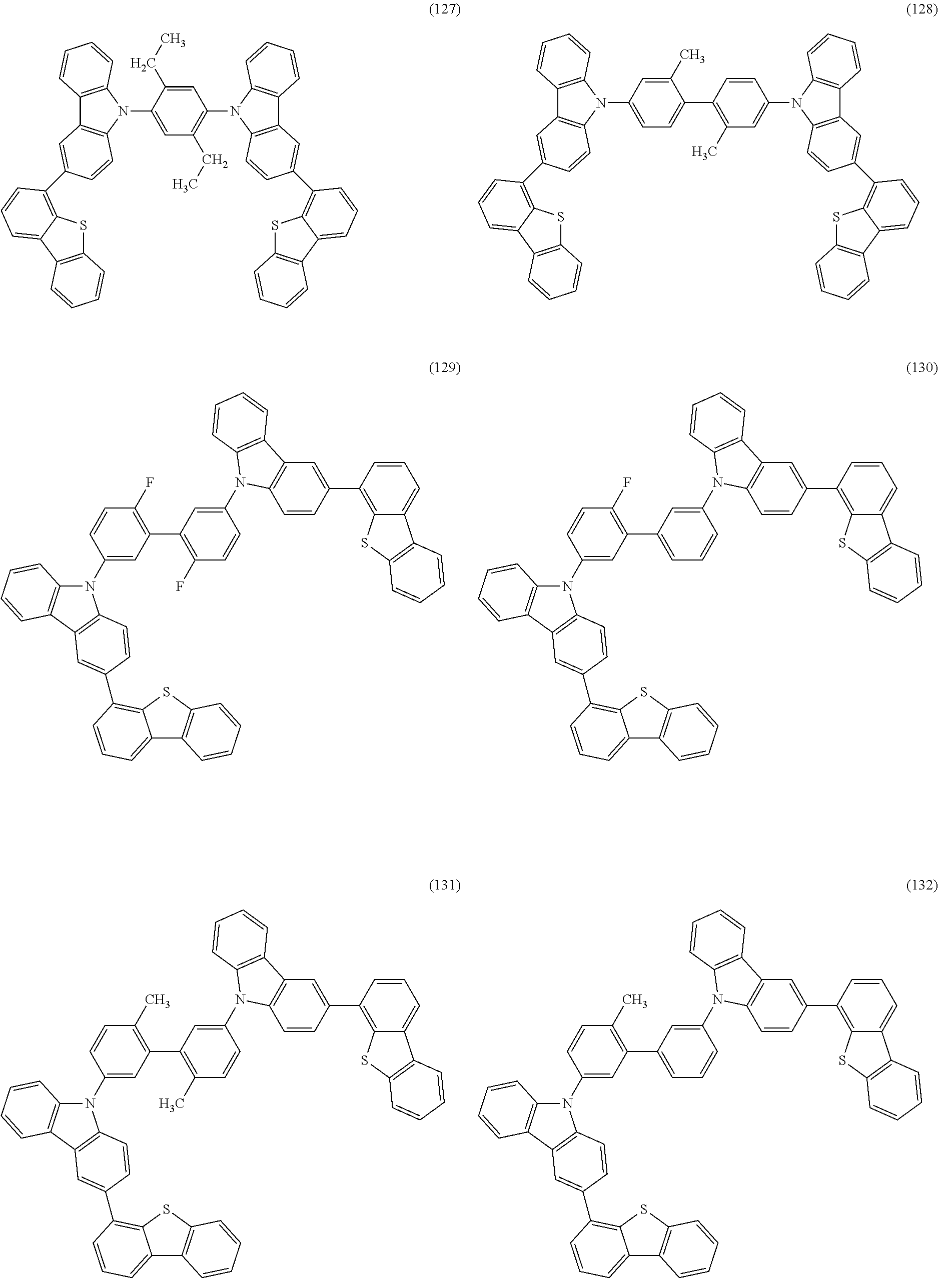

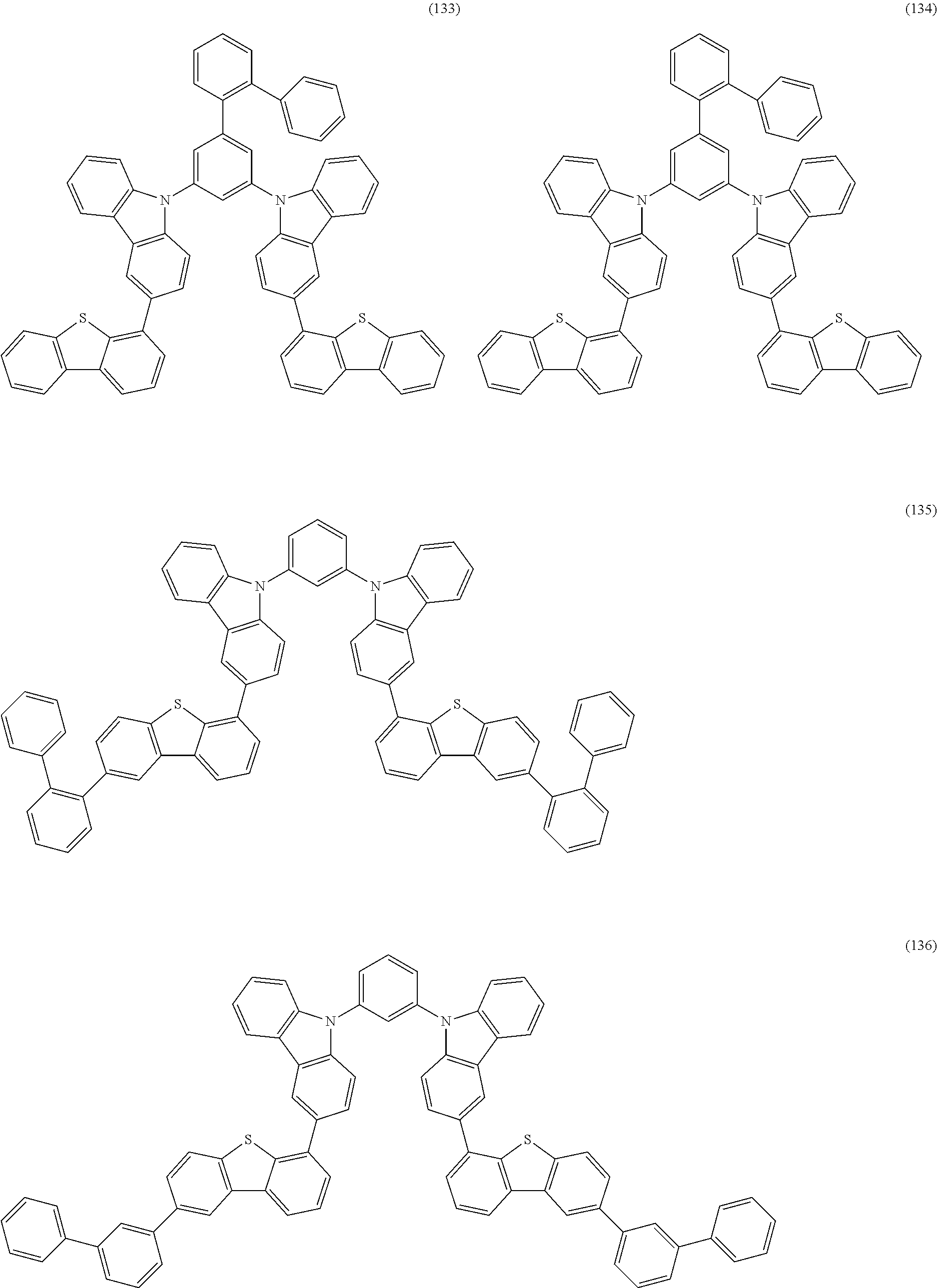

It is conceivable that when an EL layer which contains the compound represented by Structural Formula (100), i.e., 3,3′-bis(dibenzothiophen-4-yl)-N,N′-(1,3-phenylene)bicarbazole (abbreviation: mDBTCz2P-II, composition formula: C₅₄H₃₂N₂S₂, exact mass: 772.201), is analyzed by mass spectrometry, the C—N bond between N at the 9-position of the carbazole skeleton and the benzene ring which is bonded to the 9-position of the carbazole skeleton in Structural Formula (100) is cleaved due to energy applied at the time of the mass spectrometric analysis. As a result of this cleavage, a compound represented by Structural Formula (201) (composition formula: C₂₄H₁₅NS, exact mass: 349.093) in which the carbazole skeleton and the dibenzothiophene skeleton are bonded, and a compound represented by Structural Formula (202) (composition formula: C₃₀H₁₉NS, exact mass: 425.124) in which the carbazole skeleton, the dibenzothiophene skeleton, and the aryl group are bonded are possibly generated.

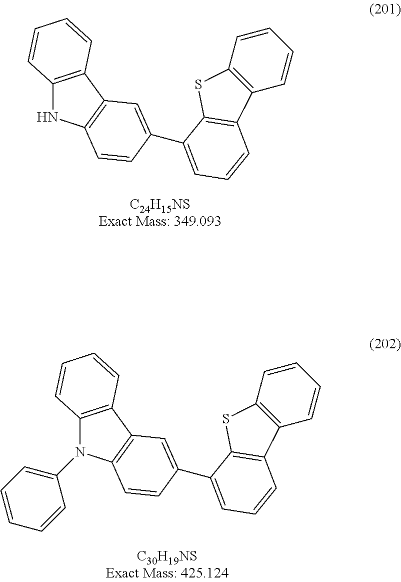 [SMILES: c1ccc2c(c1)[nH]c1ccc(-c3cccc4c3sc3ccccc34)cc12 ; c1ccc(-n2c3ccccc3c3cc(-c4cccc5c4sc4ccccc45)ccc32)cc1]

Thus, results of the mass spectrometric analysis possibly show detection of an ion presumed to be the compound represented by Structural Formula (100), an ion presumed to be the compound (Structural Formula (201)) in which the carbazole skeleton and the dibenzothiophene skeleton are bonded, and/or an ion presumed to be the compound (Structural Formula (202)) in which the carbazole skeleton, the dibenzothiophene skeleton, and the benzene ring are bonded.

This can also be described as follows. When an EL layer which is included in a light-emitting element and which contains the compound represented by Structural Formula (100), i.e., 3,3′-bis(dibenzothiophen-4-yl)-N,N′-(1,3-phenylene)bicarbazole (abbreviation: mDBTCz2P-II), is analyzed by mass spectrometry, an ion having a mass/charge ratio (m/z) of 772 is detected. When cleavage in the ion occurs, at least one of an ion having a mass/charge ratio (m/z) of 349 and an ion having a mass/charge ratio (m/z) of 425 is possibly detected. Here, the ion having a mass/charge ratio (m/z) of 349 and the ion having a mass/charge ratio (m/z) of 425 can be regarded as product ions of the ion having a mass/charge ratio (m/z) of 772.

The above may also be described as follows. When an EL layer which is included in a light-emitting element and which contains the compound (mDBTCz2P-II) represented by Structural Formula (100) is analyzed by mass spectrometry, an ion whose composition formula is C₅₄H₃₀N₂S₂, C₅₄H₃₁N₂S₂, C₅₄H₃₂N₂S₂, C₅₄H₃₃N₂S₂ or C₅₄H₃₄N₂S₂ is detected. When the ion is analyzed by mass spectrometry, at least one of an ion whose composition formula is C₂₄H₁₂NS, C₂₄H₁₃NS, C₂₄H₁₄NS, C₂₄H₁₅NS or C₂₄H₁₆NS and an ion whose composition formula is C₃₀H₁₇NS, C₃₀H₁₈NS, C₃₀H₁₉NS, C₃₀H₂₀NS or C₃₀H₂₁NS is possibly detected. Note that protonation to the compound or deprotonation from the compound possibly occurs at the time of the mass spectrometric analysis; thus, in some cases, the ion which is possibly detected has a mass/charge ratio (m/z) obtained by adding or subtracting a mass/charge ratio (m/z) of approximately 1 to or from a mass/charge ratio (m/z) estimated in the above manner.

The above may also be described as follows. When an EL layer which is included in a light-emitting element and which contains the compound (mDBTCz2P-II) represented by Structural Formula (100) is analyzed by mass spectrometry, at least one of a mass/charge ratio (m/z) corresponding to a molecular weight of C₅₄H₃₀N₂S₂, C₅₄H₃₁N₂S₂, C₅₄H₃₂N₂S₂, C₅₄H₃₃N₂S₂ or C₅₄H₃₄N₂S₂, a mass/charge ratio (m/z) corresponding to a molecular weight of C₃₀H₁₇NS, C₃₀H₁₈NS, C₃₀H₁₉NS, C₃₀H₂₀NS or C₃₀H₂₁NS, and a mass/charge ratio (m/z) corresponding to a molecular weight of C₂₄H₁₂NS, C₂₄H₁₃NS, C₂₄H₁₄NS, C₂₄H₁₅NS or C₂₄H₁₆NS is possibly detected.

Note that to the mass spectrometric analysis, analysis using a liquid chromatography mass spectrometer (LC/MS), analysis using a time-of-flight secondary ion mass spectrometer (ToF-SIMS), or the like can be applied.

A compound as described above has an excellent carrier-transport property and therefore is suitable for a carrier-transport material or a host material; thus, a light-emitting element having low driving voltage can also be provided. Further, the compound has high triplet excitation energy (a large energy difference between the triplet excited state and the ground state), and thus a phosphorescent light-emitting element having high emission efficiency can be obtained. In addition, since having high triplet excitation energy indicates also having a wide band gap, the compound enables even a light-emitting element for emitting blue fluorescence to efficiently emit light.

Furthermore, the compound in this embodiment has a dibenzothiophene skeleton that is a rigid group, and therefore has excellent morphology, gives stable film quality, and also has an excellent thermophysical property. Thus, a light-emitting element using the compound in this embodiment can have a long lifetime which shows a small luminance decrease relative to driving time.

In addition, the compound in this embodiment can be used for a light-emitting material that emits blue to ultraviolet light.

Next, a method for synthesizing the compound represented by General Formula (G1) is described. A variety of reactions can be applied to the method for synthesizing the compound. For example, synthesis reactions described below enable the synthesis of the compound represented by General Formula (G1). In General Formula (G1), Ar represents a substituted or unsubstituted phenylene group or a substituted or unsubstituted biphenyldiyl group, and R¹ to R¹⁴ separately represent hydrogen, an alkyl group having 1 to 4 carbon atoms, or an aryl group having 6 to 12 carbon atoms.

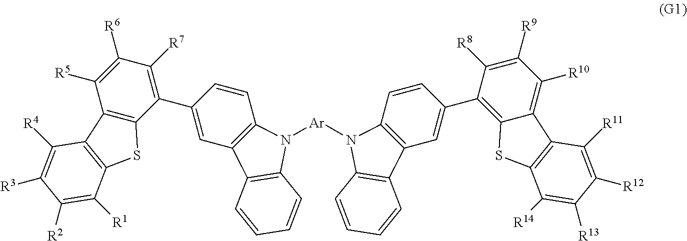

First, a compound 1 having a halogen group or a triflate group at the 3-position of 9H-carbazole is coupled with a boronic acid compound (compound 2) of dibenzothiophene, so that a 9H-carbazole compound (compound 12) having a structure in which the 3-position of 9H-carbazole is bonded to the 4-position of dibenzothiophene can be obtained (Reaction Formula (A-1)).

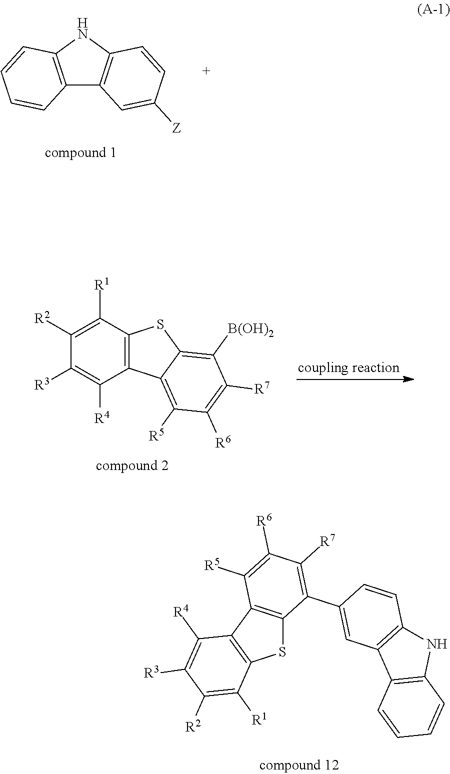

In Reaction Formula (A-1), Z represents a halogen group, a triflate group, or the like, and R¹ to R⁷ separately represent hydrogen, an alkyl group having 1 to 4 carbon atoms, or an aryl group having 6 to 12 carbon atoms. The aryl group may have a substituent. Further, the compound 2 may be a boron compound in which a boronic acid is protected with ethylene glycol or the like. As the coupling reaction in Reaction Formula (A-1), a Suzuki-Miyaura coupling reaction using a palladium catalyst can be used.

It is also possible to perform, for example, a Kumada coupling reaction using a Grignard reagent in which the carbon bonded to the boron in the compound 2 has, as a substituent, a magnesium reagent containing magnesium bromide or the like; a Negishi coupling reaction using an organozinc compound in which the carbon bonded to the boron in the compound 2 has a zinc atom as a substituent; or a Migita-Kosugi-Stille coupling reaction using an organotin compound in which the carbon bonded to the boron in the compound 2 has a tin atom as a substituent.

To synthesize a 9H-carbazole compound having a structure in which the 2-position of 9H-carbazole is bonded to the 4-position of dibenzothiophene, the method as described above is employed with, instead of the compound 1, a compound having a halogen group or a triflate group at the 2-position of 9H-carbazole.

Similarly, the compound 1 having a halogen group or a triflate group at the 3-position of 9H-carbazole is coupled with the boronic acid compound (compound 2) of dibenzothiophene, so that a 9H-carbazole compound (compound 14) having a structure in which the 3-position of 9H-carbazole is bonded to the 4-position of dibenzothiophene can be obtained (Reaction Formula (A-1′)).

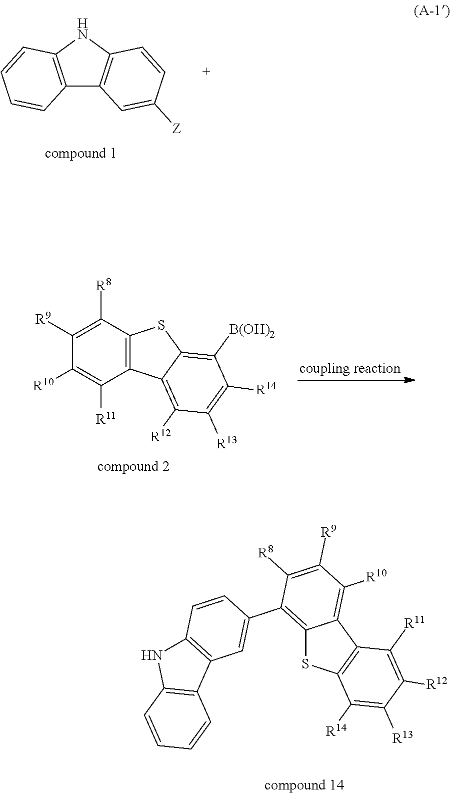

In Reaction Formula (A-1′), Z represents a halogen group, a triflate group, or the like, and R⁸ to R¹⁴ separately represent hydrogen, an alkyl group having 1 to 4 carbon atoms, or an aryl group having 6 to 12 carbon atoms. The aryl group may have a substituent.

Then, an aryl compound (compound 11) and the carbazole compound (compound 12) undergo a coupling reaction, so that a carbazole derivative (compound 13) can be obtained (Reaction Formula (A-2)). In Reaction Formula (A-2), X¹¹ and X¹² each represent a halogen group, and R¹ to R⁷ separately represent hydrogen, an alkyl group having 1 to 4 carbon atoms, or an aryl group having 6 to 12 carbon atoms.

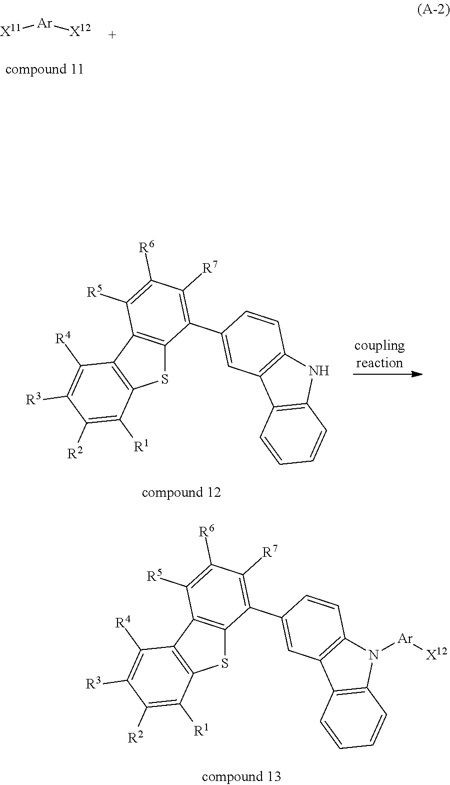

A variety of reaction conditions can be employed for the coupling reaction of the aryl compound having a halogen group (compound 11) and the 9-position of the carbazole compound (compound 12) in Reaction Formula (A-2). For example, it is possible to use a coupling reaction using a metal catalyst in the presence of a base, such as a Hartwig-Buchwald reaction using a palladium catalyst or an Ullmann reaction using copper or a copper compound.

A case where a Hartwig-Buchwald reaction is performed is described. A palladium catalyst can be used as the metal catalyst, and a mixture of a palladium complex and a ligand thereof can be used as the palladium catalyst. As examples of the palladium catalyst, bis(dibenzylideneacetone)palladium(0), palladium(II) acetate, and the like can be given. As examples of the ligand, tri(tert-butyl)phosphine, tri(n-hexyl)phosphine, tricyclohexylphosphine, and the like are given. In addition, as examples of the substance that can be used as the base, an organic base such as sodium tert-butoxide, an inorganic base such as potassium carbonate, and the like are given. The reaction is preferably performed in a solution, and toluene, xylene, benzene, tetrahydrofuran, and the like can be given as a solvent that can be used. Note that the catalyst, ligand, base, and solvent which can be used are not limited to the above. Note that this reaction is preferably performed in an inert atmosphere of nitrogen, argon, or the like.

A case where an Ullmann reaction is performed in Reaction Formula (A-2) is described. A copper catalyst can be used as the metal catalyst, and copper, copper(I) iodide, copper(II) acetate, and the like can be given as the copper catalyst. As a substance that can be used as the base, an inorganic base such as potassium carbonate can be given. The above reaction is preferably performed in a solution, and 1,3-dimethyl-3,4,5,6-tetrahydro-2(1H)pyrimidinone (abbreviation: DMPU), toluene, xylene, benzene, and the like can be given as a solvent that can be used. Note that the catalyst, base, and solvent which can be used are not limited to the above. In addition, this reaction is preferably performed under an inert atmosphere of nitrogen, argon, or the like. Note that DMPU or xylene, which has a high boiling point, is preferably used in an Ullmann reaction, in which case the object of the synthesis can be obtained in a shorter time and a higher yield at a reaction temperature of 100° C. or more. A reaction temperature of 150° C. or more is further preferred and accordingly DMPU is more preferably used.

Next is described a method for synthesizing the compound represented by General Formula (G1) in accordance with Reaction Formula (A-3).

The carbazole compound (compound 13) and the carbazole compound (compound 14) undergo a coupling reaction, so that the compound (G1) which is the object of the synthesis can be obtained (Reaction Formula (A-3)). Note that in Reaction Formula (A-3), X¹² represents a halogen group, Ar represents a substituted or unsubstituted phenylene group or a substituted or unsubstituted biphenyldiyl group, and R¹ to R¹⁴ separately represent hydrogen, an alkyl group having 1 to 4 carbon atoms, or an aryl group having 6 to 12 carbon atoms.

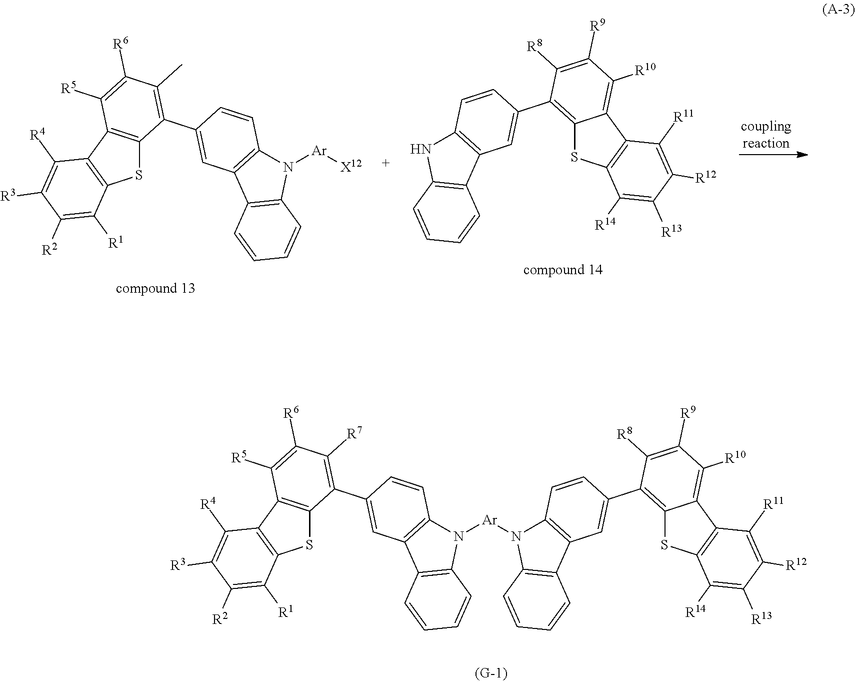

A variety of reaction conditions can be employed for the coupling reaction of the aryl compound having a halogen group (compound 13) and the 9-position of the carbazole compound (compound 14) in Reaction Formula (A-3). For example, it is possible to use a coupling reaction using a metal catalyst in the presence of a base, such as a Hartwig-Buchwald reaction using a palladium catalyst or an Ullmann reaction using copper or a copper compound.

A case where a Hartwig-Buchwald reaction is performed is described. A palladium catalyst can be used as the metal catalyst, and a mixture of a palladium complex and a ligand thereof can be used as the palladium catalyst. As examples of the palladium catalyst, bis(dibenzylideneacetone)palladium(0), palladium(II) acetate, and the like can be given. As examples of the ligand, tri(tert-butyl)phosphine, tri(n-hexyl)phosphine, tricyclohexylphosphine, and the like are given. In addition, as examples of the substance that can be used as the base, an organic base such as sodium tert-butoxide, an inorganic base such as potassium carbonate, and the like are given. The reaction is preferably performed in a solution, and toluene, xylene, benzene, tetrahydrofuran, and the like can be given as a solvent that can be used. Note that the catalyst, ligand, base, and solvent which can be used are not limited to the above. Note that this reaction is preferably performed in an inert atmosphere of nitrogen, argon, or the like.

A case where an Ullmann reaction is performed in Reaction Formula (A-3) is described. A copper catalyst can be used as the metal catalyst, and copper, copper(I) iodide, copper(II) acetate, and the like can be given as the copper catalyst. As a substance that can be used as the base, an inorganic base such as potassium carbonate can be given. The above reaction is preferably performed in a solution, and 1,3-dimethyl-3,4,5,6-tetrahydro-2(1H)pyrimidinone (abbreviation: DMPU), toluene, xylene, benzene, and the like can be given as a solvent that can be used. Note that the catalyst, base, and solvent which can be used are not limited to the above. In addition, this reaction is preferably performed under an inert atmosphere of nitrogen, argon, or the like. Note that DMPU or xylene, which has a high boiling point, is preferably used in an Ullmann reaction, in which case the object of the synthesis can be obtained in a shorter time and a higher yield at a reaction temperature of 100° C. or more. A reaction temperature of 150° C. or more is further preferred and accordingly DMPU is more preferably used.

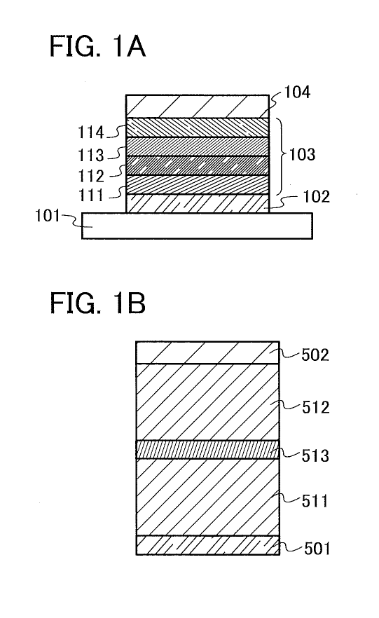

One embodiment of a light-emitting element which includes a compound capable of being synthesized by any of the above methods is described below with reference to FIG. 1A.

A light-emitting element of one embodiment of the present invention includes a plurality of layers between a pair of electrodes. In one embodiment of the present invention, the light-emitting element includes a first electrode 102, a second electrode 104, and a layer 103 containing an organic compound, which is provided between the first electrode 102 and the second electrode 104. Note that in one embodiment of the present invention, the first electrode 102 functions as an anode and the second electrode 104 functions as a cathode. In other words, when a voltage is applied between the first electrode 102 and the second electrode 104 so that the potential of the first electrode 102 is higher than that of the second electrode 104, light emission can be obtained.

A substrate 101 is used as a support of the light-emitting element. As the substrate 101, glass, plastic or the like can be used, for example. Note that a material other than glass or plastic can be used as far as it can function as a support of the light-emitting element.

For the first electrode 102, any of metals, alloys, electrically conductive compounds, and mixtures thereof which have a high work function (specifically, a work function of 4.0 eV or more) or the like is preferably used. Specifically, for example, indium oxide-tin oxide (ITO: indium tin oxide), indium oxide-tin oxide containing silicon or silicon oxide, indium oxide-zinc oxide, indium oxide containing tungsten oxide and zinc oxide (IWZO), and the like can be given. Films of these electrically conductive metal oxides are usually formed by sputtering but may be formed by application of a sol-gel method or the like. For example, indium oxide-zinc oxide can be formed by a sputtering method using a target in which zinc oxide is added to indium oxide at 1 wt % to 20 wt %. Moreover, indium oxide containing tungsten oxide and zinc oxide (IWZO) can be formed by a sputtering method using a target in which tungsten oxide is added to indium oxide at 0.5 wt % to 5 wt % and zinc oxide is added to indium oxide at 0.1 wt % to 1 wt %. Besides, gold (Au), platinum (Pt), nickel (Ni), tungsten (W), chromium (Cr), molybdenum (Mo), iron (Fe), cobalt (Co), copper (Cu), palladium (Pd), nitrides of metal materials (e.g., titanium nitride), and the like can be given. Graphene may also be used.

There is no particular limitation on a stacked structure of the layer 103 containing an organic compound. The layer 103 containing an organic compound can be formed by combining a layer that contains a substance having a high electron-transport property, a layer that contains a substance having a high hole-transport property, a layer that contains a substance having a high electron-injection property, a layer that contains a substance having a high hole-injection property, a layer that contains a bipolar substance (a substance having high electron-transport and hole-transport properties), and the like as appropriate. For example, the layer 103 containing an organic compound can be formed by combining a hole-injection layer, a hole-transport layer, a light-emitting layer, an electron-transport layer, an electron-injection layer, and the like as appropriate. In this embodiment, the layer 103 containing an organic compound has a structure in which a hole-injection layer 111, a hole-transport layer 112, a light-emitting layer 113, and an electron-transport layer 114 are stacked in this order over the first electrode 102 functioning as an anode. Note that when the second electrode 104 is an electrode functioning as an anode, in a layer containing an organic compound having a structure similar to the above, the hole-injection layer 111, the hole-transport layer 112, the light-emitting layer 113, and the electron-transport layer 114 are stacked in order from the second electrode 104. Materials included in the layers are specifically given below.

The hole-injection layer 111 is a layer containing a substance having a high hole-injection property. Molybdenum oxide, vanadium oxide, ruthenium oxide, tungsten oxide, manganese oxide, or the like can be used. Alternatively, the hole-injection layer 111 can be formed with a phthalocyanine-based compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or N,N′-bis{4-[bis(3-methylphenyl)amino]phenyl}-N,N′-diphenyl-(1,1′-biphenyl)-4,4′-diamine (abbreviation: DNTPD), a high molecular compound such as poly(3,4-ethylenedioxythiophene)/poly(styrenesulfonic acid) (abbreviation: PEDOT/PSS), or the like.

Alternatively, a composite material in which a substance having a high hole-transport property contains a substance having an acceptor property can be used for the hole-injection layer 111. In this specification, the composite material refers to not a material in which two materials are simply mixed but a material in the state where charge transfer between the materials can be caused by a mixture of a plurality of materials. This charge transfer includes charge transfer that can occur only when there is an auxiliary effect of an electric field.

Note that the use of such a substance having a high hole-transport property which contains a substance having an acceptor property enables selection of a material used to form an electrode regardless of its work function. In other words, besides a material having a high work function, a material having a low work function can also be used for the first electrode 102. As the substance having an acceptor property, 7,7,8,8-tetracyano-2,3,5,6-tetrafluoroquinodimethane (abbreviation: F₄-TCNQ), chloranil, and the like can be given. In addition, transition metal oxides can be given. Oxides of the metals that belong to Group 4 to Group 8 of the periodic table can be given. Specifically, vanadium oxide, niobium oxide, tantalum oxide, chromium oxide, molybdenum oxide, tungsten oxide, manganese oxide, and rhenium oxide are preferable in that their electron-accepting property is high. Among these, molybdenum oxide is especially preferable in that it is stable in the air, has a low hygroscopic property, and is easy to handle.

As the substance having a high hole-transport property used for the composite material, any of a variety of organic compounds such as aromatic amine compounds, carbazole compounds, aromatic hydrocarbons, and high molecular compounds (e.g., oligomers, dendrimers, or polymers) can be used. Note that the organic compound used for the composite material is preferably an organic compound having a high hole-transport property. Specifically, a substance having a hole mobility of 10⁻⁶ cm²/Vs or more is preferably used. Further, other than these substances, any substance that has a property of transporting more holes than electrons may be used. Organic compounds that can be used as the substance having a high hole-transport property in the composite material are specifically given below.

Examples of the aromatic amine compounds are N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis{4-[bis(3-methylphenyl)amino]phenyl}-N,N′-diphenyl-(1,1′-biphenyl)-4,4′-diamine (abbreviation: DNTPD), 1,3,5-tris[N-(4-diphenylaminophenyl)-N-phenylamino]benzene (abbreviation: DPA3B), and the like.

Specific examples of the carbazole compounds that can be used for the composite material are 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), and the like.

Other examples of the carbazole compounds that can be used for the composite material are 4,4′-bis(N-carbazolyl)biphenyl (abbreviation: CBP), 1,3,5-tris[4-(N-carbazolyl)phenyl]benzene (abbreviation: TCPB), 9-[4-(10-phenyl-9-anthryl)phenyl]-9H-carbazole (abbreviation: CzPA), 1,4-bis[4-(N-carbazolyl)phenyl]-2,3,5,6-tetraphenylbenzene, and the like.

Examples of the aromatic hydrocarbons that can be used for the composite material are 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, and the like. Besides, pentacene, coronene, or the like can also be used. The aromatic hydrocarbon which has a hole mobility of 1×10⁻⁶ cm²/Vs or more and which has 14 to 42 carbon atoms is particularly preferable.

Note that the aromatic hydrocarbons that can be used for the composite material may have a vinyl skeleton. Examples of the aromatic hydrocarbon having a vinyl group are 4,4′-bis(2,2-diphenylvinyl)biphenyl (abbreviation: DPVBi), 9,10-bis[4-(2,2-diphenylvinyl)phenyl]anthracene (abbreviation: DPVPA), and the like.

A high molecular compound such as poly(N-vinylcarbazole) (abbreviation: PVK), poly(4-vinyltriphenylamine) (abbreviation: PVTPA), poly[N-(4-{N′-[4-[4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: poly-TPD) can also be used.

The compound represented by General Formula (G1) is also the aromatic hydrocarbon that can be used for the composite material.

The hole-transport layer 112 is a layer that contains a substance having a high hole-transport property. As the substance having a high hole-transport property, the substances given as the substances having a high hole-transport property which can be used for the above composite material can also be used. Note that a detailed explanation is omitted to avoid repetition. Refer to the explanation of the composite material.

The compound represented by General Formula (G1) has an excellent hole-transport property and accordingly can be suitably used for the hole-transport layer 112. The compound having a wide band gap can also be suitably used for a material contained in a carrier-transport layer adjacent to a light-emitting layer containing an emission center substance that emits blue fluorescence or green phosphorescence, without deactivating excitation energy of the emission center substance. Thus, a light-emitting element with high emission efficiency can be fabricated. It is needless to say that the compound can be used for a material included in a carrier-transport layer adjacent to a light-emitting layer containing an emission center substance that emits fluorescence having a longer wavelength than blue light or phosphorescence having a longer wavelength than green light or an emission center substance that emits fluorescence having a shorter wavelength than blue light or phosphorescence having a shorter wavelength than green light.

The light-emitting layer 113 is a layer containing a light-emitting substance. The light-emitting layer 113 may be formed with a film containing only a light-emitting substance or a film in which an emission center substance is dispersed in a host material.

There is no particular limitation on a material that can be used as the light-emitting substance or the emission center substance in the light-emitting layer 113, and light emitted from the material may be either fluorescence or phosphorescence. Examples of the above light-emitting substance or emission center substance are the following substances: fluorescent substances such as N,N′-bis[4-(9-phenyl-9H-fluoren-9-yl)phenyl]-N,N′-diphenylpyrene-1,6-diamine (abbreviation: 1,6FLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis[N,N′,N′-triphenyl-1,4-phen ylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), and N,N′-bis[4-(9-phenyl-9H-fluoren-9-yl)phenyl]-N,N′-diphenylpyrene-1,6-diamine (abbreviation: 1,6FLPAPrn); and phosphorescent substances such as bis{2-[3′,5′-bis(trifluoromethyl)phenyl]pyridinato-N,C^{2′}}iridium(III) picolinate (abbreviation: Ir(CF₃ ppy)₂(pic)), bis[2-(4′,6′-difluorophenyl)pyridinato-N,C^{2′}]iridium(III) acetylacetonate (abbreviation: FIracac), tris(2-phenylpyridinato)iridium(III) (abbreviation: Ir(ppy)₃), bis(2-phenylpyridinato)iridium(III) acetylacetonate (abbreviation: Ir(ppy)₂(acac)), tris(acetylacetonato)(monophenanthroline)terbium(III) (abbreviation: Tb(acac)₃(Phen)), bis(benzo quinolinato)iridium(III) acetylacetonate (abbreviation: Ir(bzq)₂(acac)), bis(2,4-diphenyl-1,3-oxazolato-N,C^{2′})iridium(III) acetylacetonate (abbreviation: Ir(dpo)₂(acac)), bis{2-[4′-(perfluorophenyl)phenyl]pyridinato-N,C^{2′}}iridium(III) acetylacetonate (abbreviation: Ir(p-PF-ph)₂(acac)), bis(2-phenylbenzothiazolato-N,C^{2′})iridium(III) acetylacetonate (abbreviation: Ir(bt)₂(acac)), bis[2-(2′-benzo[4,5-α]thienyl)pyridinato-N,C^{3′}]iridium(III) acetylacetonate (abbreviation: Ir(btp)₂(acac)), bis(1-phenylisoquinolinato-N,C^{2′})iridium(III) acetylacetonate (abbreviation: Ir(piq)₂(acac)), (acetylacetonato)bis[2,3-bis(4-fluorophenyl)quinoxalinato]iridium(III) (abbreviation: Ir(Fdpq)₂(acac)), (acetylacetonato)bis(2,3,5-triphenylpyrazinato)iridium(III) (abbreviation: Ir(tppr)₂(acac)), 2,3,7,8,12,13,17,18-octaethyl-21H,23H-porphine platinum(II) (abbreviation: PtOEP), tris(1,3-diphenyl-1,3-propanedionato)(monophenanthroline)europium(III) (abbreviation: Eu(DBM)₃(Phen)), and tris[1-(2-thenoyl)-3,3,3-trifluoroacetonato](monophenanthroline)europium(III) (abbreviation: Eu(TTA)₃(Phen)). Note that a compound of one embodiment of the present invention, a typical example of which is the compound represented by General Formula (G1), emits light in the blue to ultraviolet region, and therefore can also be used as an emission center material.

Since the compound represented by General Formula (G1) has a wide band gap and has high triplet excitation energy (a large energy difference between the triplet excited state and the ground state), the compound can be suitably used for an emission center substance exhibiting light emission with high energy and emitting blue fluorescence, or for a host material in which an emission center substance emitting green phosphorescence is dispersed. It is needless to say that the compound can be used for a host material, in which an emission center substance that emits fluorescence having a longer wavelength than blue light or phosphorescence having a longer wavelength than green light is dispersed, or for a material included in a carrier-transport layer adjacent to a light-emitting layer containing an emission center substance that emits fluorescence having a shorter wavelength than blue light or phosphorescence having a shorter wavelength than green light. Since the compound has a wide band gap and high triplet excitation energy, the energy of carriers that recombine at the host material can be effectively transferred to the emission center substance. Thus, a light-emitting element with high emission efficiency can be fabricated. Note that when the compound represented by General Formula (G1) is used for a host, an emission center material is preferably selected from, but not limited to, substances having a narrower band gap or lower triplet excitation energy than the compound.

When the compound represented by General Formula (G1) is not used as the host material described above, any of the following substances can be used for the host material: metal complexes such as tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ); heterocyclic compounds such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), bathophenanthroline (abbreviation: BPhen), bathocuproine (abbreviation: BCP), and 9-[4-(5-phenyl-1,3,4-oxadiazol-2-yl)phenyl]-9H-carbazole (abbreviation: CO11); and aromatic amine compounds such as 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), and 4,4′-bis[N-(spiro-9,9′-bifluoren-2-yl)-N-phenylamino]-1,1-biphenyl (abbreviation: BSPB). In addition, condensed polycyclic aromatic compounds such as anthracene derivatives, phenanthrene derivatives, pyrene derivatives, chrysene derivatives, and dibenzo[g,p]chrysene derivatives can be given, and specific examples are 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryfitriphenylamine (abbreviation: DPhPA), 4-(9H-carbazol-9-yl)-4′-(10-phenyl-9-anthryl)triphenylamine (abbreviation: YGAPA), N,9-diphenyl-N-[4-(10-phenyl-9-anthryl)phenyl]-9H-carbazol-3-amine (abbreviation: PCAPA), N,9-diphenyl-N-{4-[4-(10-phenyl-9-anthryl)phenyl]phenyl}-9H-carbazol-3-amine (abbreviation: PCAPBA), N,9-diphenyl-N-(9,10-diphenyl-2-anthryl)-9H-carbazol-3-amine (abbreviation: 2PCAPA), 6,12-dimethoxy-5,11-diphenylchrysene, N,N,N′,N′,N″,N″,N′″,N′″-octaphenyldibenzo[g,p]chrysene-2,7,10,15-tetramine (abbreviation: DBC1), 9-[4-(10-phenyl-9-anthryl)phenyl]-9H-carbazole (abbreviation: CzPA), 3,6-diphenyl-9-[4-(10-phenyl-9-anthryl)phenyl]-9H-carbazole (abbreviation: DPCzPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), and the like. Other than these, known materials can be given.

Note that the light-emitting layer 113 can also be a stack of two or more layers. For example, when the light-emitting layer 113 is formed by stacking a first light-emitting layer and a second light-emitting layer in that order over the hole-transport layer, a substance having a hole-transport property is used for the host material of the first light-emitting layer and a substance having an electron-transport property is used for the host material of the second light-emitting layer.

When the light-emitting layer having the above-described structure includes a plurality of materials, co-evaporation by a vacuum evaporation method can be used, or alternatively an inkjet method, a spin coating method, a dip coating method, or the like with a solution of the materials can be used.

The electron-transport layer 114 is a layer containing a substance having a high electron-transport property. For example, a layer containing a metal complex having a quinoline skeleton or a benzoquinoline skeleton, such as tris(8-quinolinolato)aluminum (abbreviation: Alq), tris(4-methyl-8-quinolinolato)aluminum (abbreviation: Almq₃), bis(10-hydroxybenzo[h]quinolinato)beryllium (abbreviation: BeBq₂), or bis(2-methyl-8-quinolinolato)(4-phenylphenolato)aluminum(III) (abbreviation: BAlq), or the like can be used. Alternatively, a metal complex having an oxazole-based or thiazole-based ligand, such as bis[2-(2-hydroxyphenyl)benzoxazolato]zinc (abbreviation: Zn(BOX)₂) or bis[2-(2-hydroxyphenyl)benzothiazolato]zinc (abbreviation: Zn(BTZ)₂), or the like can be used. Besides the metal complexes, 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), bathophenanthroline (abbreviation: BPhen), bathocuproine (abbreviation: BCP), or the like can also be used. The substances mentioned here mainly have an electron mobility of 10⁻⁶ cm²/Vs or more. Note that other than these substances, any substance that has a property of transporting more electrons than holes may be used.

Furthermore, the electron-transport layer is not limited to a single layer and may be a stack of two or more layers containing any of the above substances.

Between the electron-transport layer and the light-emitting layer, a layer that controls transport of electron carriers may be provided. This is a layer formed by addition of a small amount of a substance having a high electron-trapping property to a material having a high electron-transport property as described above, and the layer is capable of adjusting carrier balance by inhibiting transport of electron carriers. Such a structure is very effective in preventing a problem (such as a reduction in element lifetime) caused when electrons pass through the light-emitting layer.

In addition, an electron-injection layer may be provided in contact with the second electrode 104 between the electron-transport layer and the second electrode 104. For the electron-injection layer, an alkali metal, an alkaline earth metal, or a compound thereof such as lithium fluoride (LiF), cesium fluoride (CsF), or calcium fluoride (CaF₂) can be used. For example, a layer that is formed with a substance having an electron-transport property and contains an alkali metal, an alkaline earth metal, or a compound thereof can be used. For example, an Alq layer containing magnesium (Mg) can be used. Note that electron injection from the second electrode 104 is efficiently performed with the use of a layer that is formed with a substance having an electron-transport property and contains an alkali metal or an alkaline earth metal as the electron-injection layer, which is preferable.

For the second electrode 104, any of metals, alloys, electrically conductive compounds, and mixtures thereof which have a low work function (specifically, a work function of 3.8 eV or less) or the like can be used. As a specific example of such a cathode material, an element belonging to Group 1 or 2 of the periodic table, i.e., an alkali metal such as lithium (Li) or cesium (Cs), or an alkaline earth metal such as magnesium (Mg), calcium (Ca), or strontium (Sr); an alloy containing any of these (such as MgAg or AlLi); a rare earth metal such as europium (Eu) or ytterbium (Yb); an alloy containing such a rare earth metal; or the like can be given. However, when the electron-injection layer is provided between the second electrode 104 and the electron-transport layer, for the second electrode 104, any of a variety of conductive materials such as Al, Ag, ITO, or indium oxide-tin oxide containing silicon or silicon oxide can be used regardless of the work function. Films of these electrically conductive materials can be formed by a sputtering method, an inkjet method, a spin coating method, or the like.

Further, any of a variety of methods can be used to form the layer 103 containing an organic compound regardless whether it is a dry process or a wet process. For example, a vacuum evaporation method, an inkjet method, a spin coating method or the like may be used. Different formation methods may be used for the electrodes or the layers.

In addition, the electrode may be formed by a wet method using a sol-gel method, or by a wet method using paste of a metal material. Alternatively, the electrode may be formed by a dry method such as a sputtering method or a vacuum evaporation method.

In the light-emitting element having the above-described structure, current flows due to a potential difference between the first electrode 102 and the second electrode 104, and holes and electrons recombine in the light-emitting layer 113 which contains a substance having a high light-emitting property, so that light is emitted. That is, a light-emitting region is formed in the light-emitting layer 113.

Light emission is extracted out through one or both of the first electrode 102 and the second electrode 104. Therefore, one or both of the first electrode 102 and the second electrode 104 are light-transmitting electrodes. When only the first electrode 102 is a light-transmitting electrode, light emission is extracted from the substrate side through the first electrode 102. When only the second electrode 104 is a light-transmitting electrode, light emission is extracted from the side opposite to the substrate side through the second electrode 104. When both the first electrode 102 and the second electrode 104 are light-transmitting electrodes, light emission is extracted from both the substrate side and the side opposite to the substrate through the first electrode 102 and the second electrode 104.

The structure of the layers provided between the first electrode 102 and the second electrode 104 is not limited to the above-described structure. Preferably, a light-emitting region where holes and electrons recombine is positioned away from the first electrode 102 and the second electrode 104 so that quenching due to the proximity of the light-emitting region and a metal used for electrodes and carrier-injection layers can be prevented. The order of stacking the layers is not limited to that in the above structure and may be the following order obtained by reversing the order shown in FIG. 1A: the second electrode, the electron-injection layer, the electron-transport layer, the light-emitting layer, the hole-transport layer, the hole-injection layer, and the first electrode from the substrate side.

Further, in order that transfer of energy from an exciton generated in the light-emitting layer can be inhibited, preferably, the hole-transport layer and the electron-transport layer which are in direct contact with the light-emitting layer, particularly a carrier-transport layer in contact with a side closer to the light-emitting region in the light-emitting layer 113 is formed with a substance having a wider energy gap than the light-emitting substance of the light-emitting layer or the emission center substance included in the light-emitting layer.

In the light-emitting element in this embodiment, since the compound represented by General Formula (G1) having a wide energy gap is used for the host material and/or for the electron-transport layer, efficient light emission is possible even with the emission center substance that has a wide energy gap and emits blue fluorescence; accordingly, the light-emitting element can have high emission efficiency. Thus, a light-emitting element having lower power consumption can be provided. In addition, the host material or a material included in the carrier-transport layer does not easily emit light; thus, a light-emitting element capable of emitting light with high color purity can be provided. Further, the compound represented by General Formula (G1) has an excellent carrier-transport property; thus, a light-emitting element having low driving voltage can be provided.

In this embodiment, the light-emitting element is formed over a substrate formed of glass, plastic, or the like. With a plurality of such light-emitting elements over one substrate, a passive matrix light-emitting device can be fabricated. In addition, for example, a light-emitting element may be formed over an electrode electrically connected to a transistor which is formed over a substrate formed of glass, plastic, or the like; thus, an active matrix light-emitting device in which the transistor controls the drive of the light-emitting element can be fabricated. Note that there is no particular limitation on the structure of the transistor, which may be a staggered TFT or an inverted staggered TFT. In addition, crystallinity of a semiconductor used for the TFT is not particularly limited either; an amorphous semiconductor or a crystalline semiconductor may be used. In addition, a driver circuit formed in a TFT substrate may be fixated with an n-type TFT and a p-type TFT, or with either an n-type TFT or a p-type TFT.

### Embodiment 2

In this embodiment is described an example of a light-emitting element having a structure in which a plurality of light-emitting units are stacked (hereinafter, also referred to as a stacked-type element), with reference to FIG. 1B. This light-emitting element of one embodiment of the present invention is a light-emitting element including a plurality of light-emitting units between a first electrode and a second electrode. Each light-emitting unit can have the same structure as the layer 103 containing the organic compound which is described in Embodiment 1. In other words, the light-emitting element described in Embodiment 1 is a light-emitting element having one light-emitting unit while the light-emitting element described in this embodiment is a light-emitting element having a plurality of light-emitting units.

In FIG. 1B, a first light-emitting unit 511 and a second light-emitting unit 512 are stacked between a first electrode 501 and a second electrode 502, and a charge generation layer 513 is provided between the first light-emitting unit 511 and the second light-emitting unit 512. The first electrode 501 and the second electrode 502 correspond, respectively, to the first electrode 102 and the second electrode 104 in Embodiment 1, and materials described in Embodiment 1 can be used. Further, the structures of the first light-emitting unit 511 and the second light-emitting unit 512 may be the same or different.

The charge generation layer 513 contains a composite material of an organic compound and a metal oxide. This composite material of an organic compound and a metal oxide is the composite material described in Embodiment 1, and contains an organic compound and a metal oxide such as vanadium oxide, molybdenum oxide, or tungsten oxide. As the organic compound, any of a variety of compounds such as aromatic amine compounds, carbazole compounds, aromatic hydrocarbons, and high molecular compounds (oligomers, dendrimers, polymers, or the like) can be used. Note that as the organic compound, the one having a hole mobility of 10⁻⁶ cm²/Vs or more as an organic compound having a hole-transport property is preferably used. Further, other than these substances, any substance that has a property of transporting more holes than electrons may be used. Since a composite material of an organic compound and a metal oxide is excellent in carrier-injection property and carrier-transport property, low voltage driving and low current driving can be achieved.

The charge generation layer 513 may be formed in such a way that a layer containing the composite material of an organic compound and a metal oxide is combined with a layer containing another material, for example, with a layer that contains a compound selected from substances having an electron-donating property and a compound having a high electron-transport property. The charge generation layer 513 may be formed in such a way that a layer containing the composite material of an organic compound and a metal oxide is combined with a transparent conductive film.

The charge generation layer 513 provided between the first light-emitting unit 511 and the second light-emitting unit 512 may have any structure as far as electrons can be injected to a light-emitting unit on one side and holes can be injected to a light-emitting unit on the other side when a voltage is applied between the first electrode 501 and the second electrode 502. For example, in FIG. 1B, any layer can be used as the charge generation layer 513 as far as the layer injects electrons into the first light-emitting unit 511 and holes into the second light-emitting unit 512 when a voltage is applied such that the potential of the first electrode is higher than that of the second electrode.

Although the light-emitting element having two light-emitting units is described in this embodiment, the present invention can be similarly applied to a light-emitting element in which three or more light-emitting units are stacked. By arrangement of a plurality of light-emitting units, which are partitioned by the charge-generation layer between a pair of electrodes, as in the light-emitting element in this embodiment, light emission in a high luminance region can be obtained while current density is kept low; thus, a light-emitting element having a long lifetime can be obtained. Further, in application to lighting devices, a voltage drop due to resistance of an electrode material can be reduced and accordingly light emission in a large area is possible. Moreover, a light-emitting device having low driving voltage and lower power consumption can be obtained.

By making emission colors of the light-emitting units different from each other, light emission with a desired color can be obtained from the light-emitting element as a whole. For example, in a light-emitting element including two light-emitting units, the emission colors of the first light-emitting unit and the second light-emitting unit are made complementary, so that the light-emitting element which emits white light as the whole element can be obtained. Note that the term “complementary” means color relationship in which an achromatic color is obtained when colors are mixed. That is, a mixture of light emissions with complementary colors gives white light emission. The same can be applied to a light-emitting element including three light-emitting units. For example, a light-emitting element as a whole can emit white light when the emission color of the first light-emitting unit is red, the emission color of the second light-emitting unit is green, and the emission color of the third light-emitting unit is blue.

Since the light-emitting element in this embodiment includes the compound represented by General Formula (G1), the light-emitting element can have high emission efficiency and low driving voltage. In addition, since light emission with high color purity which originates from the emission center substance can be obtained from the light-emitting unit including the compound, color adjustment of the light-emitting element as a whole is easy.

Note that this embodiment can be combined with any of the other embodiments as appropriate.

### Embodiment 3

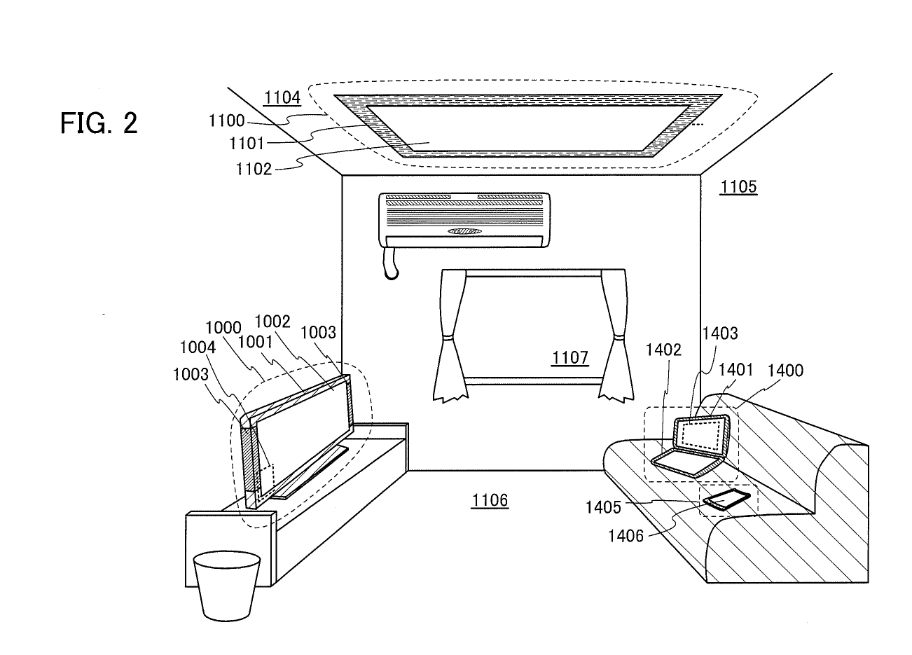

FIG. 2 illustrates examples of a light-emitting device, a lighting device, and an electronic device each of which includes the light-emitting element described in the above embodiment.

A light-emitting device 1000 illustrated in FIG. 2 is an example of a light-emitting device which includes the light-emitting element of one embodiment of the present invention. Specifically, the light-emitting device 1000 corresponds to a light-emitting device for TV broadcast reception and includes a housing 1001, a display portion 1002, speaker portions 1003, a lithium ion secondary battery 1004, and the like. The light-emitting element of one embodiment of the present invention can be applied to the display portion 1002.

Note that the light-emitting device includes, in its category, all of light-emitting devices for information display, for example, those for personal computers or those for advertisement displays, in addition to those for TV broadcast reception.

An installation lighting device 1100 in FIG. 2 is an example of a lighting device which includes the light-emitting element of one embodiment of the present invention. Specifically, the lighting device 1100 includes a housing 1101, a light source 1102, and the like. The light-emitting element of one embodiment of the present invention can be applied to the light source 1102.

Note that although FIG. 2 illustrates the example in which the installation lighting device 1100 provided in a ceiling 1104, the light-emitting element of one embodiment of the present invention can be used in an installation lighting device provided in, for example, a wall 1105, a floor 1106, a window 1107, or the like other than the ceiling 1104. In addition, the light-emitting element can be used in a tabletop lighting device and the like.

A tablet terminal 1400 in FIG. 2 is an example of an electronic device which includes the light-emitting element of one embodiment of the present invention. Specifically, the tablet terminal 1400 includes a housing 1401, a housing 1402, a lithium ion secondary battery 1403, and the like. The housing 1401 and the housing 1402 each include a display portion having a touch-panel function. A user can carry out operation of contents which are displayed on the display portion by touching the displayed contents with a finger or the like. Light-emitting devices each of which includes the light-emitting element of one embodiment of the present invention can be applied to the display portions of the housing 1401 and the housing 1402. In addition, the tablet terminal 1400 can be folded so that the display portions of the housing 1401 and the housing 1402 are inside, which enables protection of the display portions as well as an increase in portability.

A mobile phone 1405 in FIG. 2 is an example of an electronic device which includes the light-emitting element of one embodiment of the present invention. Specifically, the mobile phone 1405 includes a housing 1406, whose display portion has a touch-panel function. A light-emitting device which includes the light-emitting element of one embodiment of the present invention can be applied to the display portion of the housing 1406. Note that the display portion of the housing 1406 may be curved.

Note that this embodiment can be implemented in appropriate combination with any of the other embodiments and examples.

### Example 1

In this example is specifically described 3,3′-bis(dibenzothiophen-4-yl)-N,N′-(1,3-phenylene)bicarbazole (abbreviation: mDBTCz2P-II), which is represented by Structural Formula (100) in Embodiment 1. A structural formula of mDBTCz2P-II is shown below.

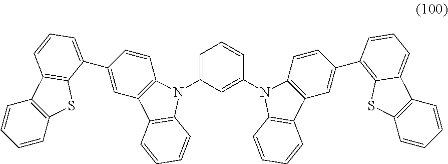 [SMILES: c1cc(-n2c3ccccc3c3cc(-c4cccc5c4sc4ccccc45)ccc32)cc(-n2c3ccccc3c3cc(-c4cccc5c4sc4ccccc45)ccc32)c1]

### Synthesis Example 1

A method for synthesizing mDBTCz2P-II is specifically described.

### Step 1: Synthesis of 3-(Dibenzothiophen-4-yl)-9H-carbazole (Abbreviation: DBTCz)

Into a 200 mL three-neck flask were placed 3.0 g (12 mmol) of 3-bromocarbazole, 2.8 g (12 mmol) of dibenzothiophene-4-boronic acid, and 0.15 g (0.5 mol) of tri(ortho-tolyl)phosphine, and the air in the flask was replaced with nitrogen. To this mixture were added 40 mL of toluene, 40 mL of ethanol, and 15 mL of an aqueous solution of potassium carbonate (2.0 mol/L). In the flask, the mixture was degassed by being stirred under reduced pressure. After the degassing, the air in the system was replaced with nitrogen, and 23 mg (0.10 mmol) of palladium(II) acetate was added to this mixture, and then the mixture was refluxed at 80° C. for 4 hours. After the reflux, the mixture was cooled to room temperature, whereby a solid was precipitated. About 100 mL of toluene was added to the mixture in which the solid was precipitated, and the resulting mixture was heated and stirred, so that the precipitated solid was dissolved. While kept hot, the obtained suspension was filtered through Celite (produced by Wako Pure Chemical Industries, Ltd., Catalog No. 531-16855), Florisil (produced by Wako Pure Chemical Industries, Ltd., Catalog No. 540-00135), and alumina. The solid obtained by concentration of the obtained filtrate was recrystallized from toluene, so that 3.4 g of a white solid which was an object of the synthesis was obtained in 79% yield. The reaction scheme of Step 1 is illustrated in a scheme (a-1) below.

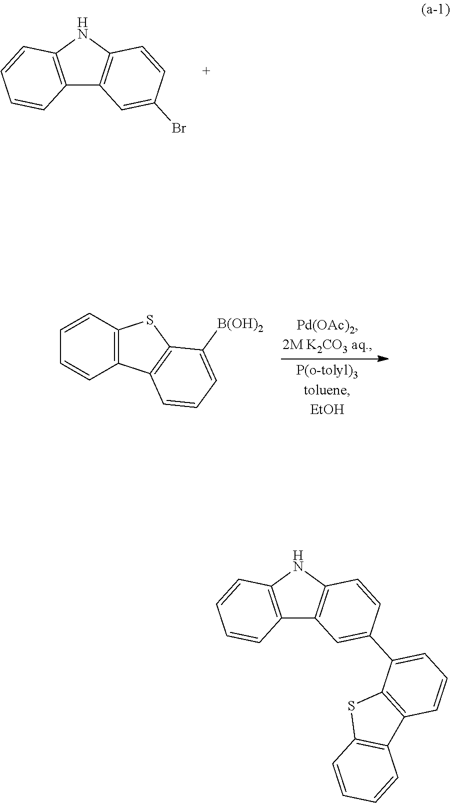 [SMILES: Brc1ccc2[nH]c3ccccc3c2c1 ; OB(O)c1cccc2c1sc1ccccc12 ; c1ccc2c(c1)[nH]c1ccc(-c3cccc4c3sc3ccccc34)cc12]

### Step 2: Synthesis of 3,3′-Bis(dibenzothiophen-4-yl)-N,N′-(1,3-phenylene)bicarbazole (Abbreviation: mDBTCz2P-II)

Into a 200 mL three-neck flask were placed 1.2 g (5.0 mmol) of 1,3-dibromobenzene and 3.5 g (10 mmol) of 3-(dibenzothiophen-4-yl)-9H-carbazole (abbreviation: DBTCz), and the air in the flask was replaced with nitrogen. To this mixture were added 40 mL of toluene, 0.10 mL of tri(tert-butyl)phosphine (a 10 wt % hexane solution), and 0.98 g (10 mmol) of sodium tert-butoxide. This mixture was degassed while being stirred under reduced pressure. After this mixture was stirred at 80° C. and dissolution of materials was confirmed, 61 mg (0.11 mmol) of bis(dibenzylideneacetone)palladium(0) was added thereto. This mixture was refluxed at 110° C. for 55 hours. After the reflux, the mixture was cooled to room temperature, and the precipitated white solid was collected by suction filtration. The obtained solid was washed with water and toluene to give 1.2 g of a white solid which was the object of the synthesis in 70% yield. The synthesis scheme of Step 2 is illustrated in a scheme (a-2) below.

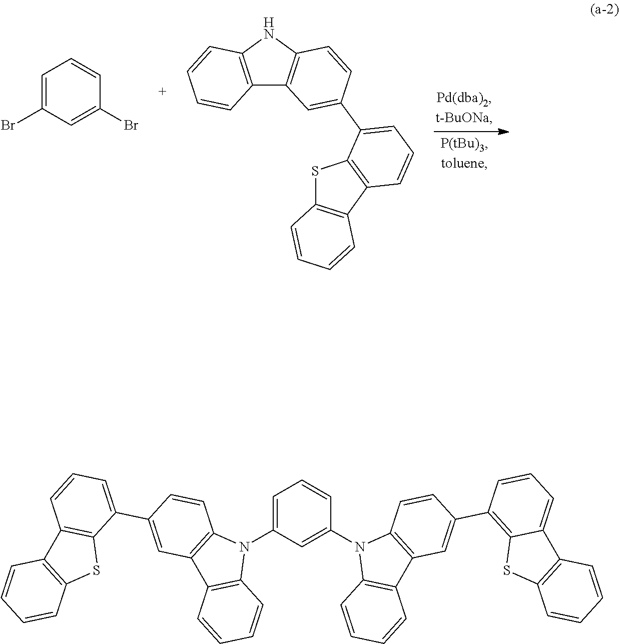 [SMILES: Brc1cccc(Br)c1 ; c1ccc2c(c1)[nH]c1ccc(-c3cccc4c3sc3ccccc34)cc12 ; c1cc(-n2c3ccccc3c3cc(-c4cccc5c4sc4ccccc45)ccc32)cc(-n2c3ccccc3c3cc(-c4cccc5c4sc4ccccc45)ccc32)c1]

By a train sublimation method, 1.1 g of the obtained white solid was purified by sublimation. In the purification by sublimation, the white solid was heated at 350° C. under a pressure of 2.8 Pa with a flow rate of argon gas of 10 mL/min. After the purification by sublimation, 0.89 g of a colorless transparent solid was obtained at a collection rate of 83%.

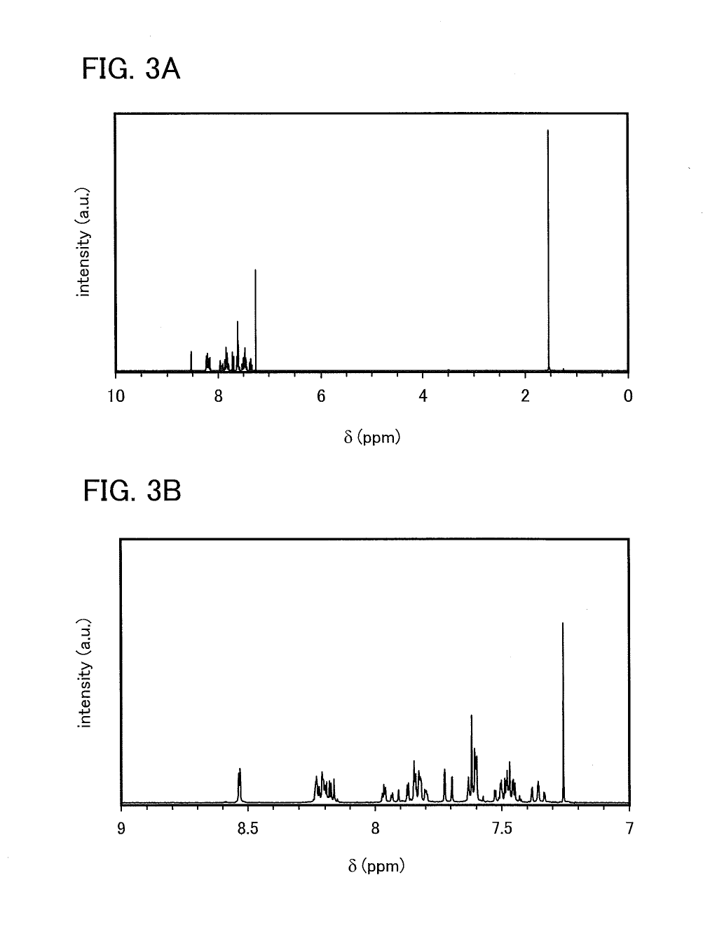

This compound was subjected to a nuclear magnetic resonance (NMR) measurement. The obtained NMR charts are shown in FIGS. 3A and 3B. Note that FIG. 3B is a chart where the range of from 7 ppm to 9 ppm in FIG. 3A is enlarged. In addition, ¹H NMR data of the obtained compound is shown below.

¹H NMR (CDCl₃, 300 MHz): δ (ppm)=7.36 (td, J=0.9 Hz, J₂=7.8 Hz, 2H), 7.43-7.53 (m, 6H), 7.58-7.63 (m, 6H), 7.71 (d, J=8.7 Hz, 2H), 7.80-7.97 (m, 8H), 8.15-8.24 (m, 6H), 8.53 (d, J=1.5 Hz, 2H)

Thus, the solid obtained in this synthesis example was confirmed to be 3,3′-bis(dibenzothiophen-4-yl)-N,N′-(1,3-phenylene)bicarbazole (abbreviation: mDBTCz2P-II).

<<Physical Properties of mDBTCz2P-II>>

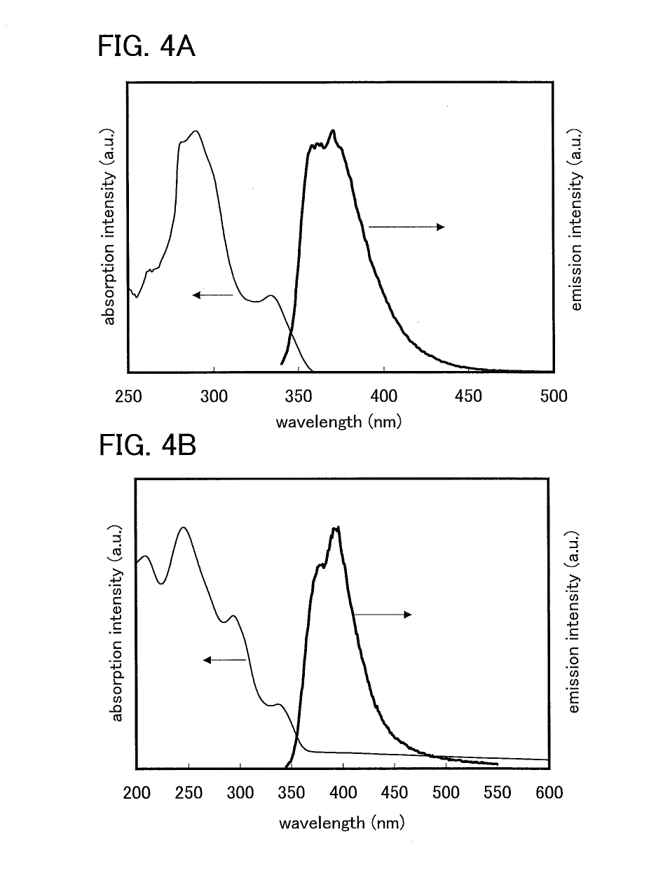

FIG. 4A shows an absorption spectrum and an emission spectrum of mDBTCz2P-II in a toluene solution of mDBTCz2P-II, and FIG. 4B shows an absorption spectrum and an emission spectrum of a thin film of mDBTCz2P-II. The spectra were measured with a UV-visible spectrophotometer (V550, produced by JASCO Corporation). The spectra of the toluene solution were measured with a toluene solution of mDBTCz2P-II put in a quartz cell. The spectra of the thin film were measured with a sample prepared by deposition of mDBTCz2P-II on a quartz substrate by evaporation. Note that in the case of the absorption spectrum of mDBTCz2P-II in the toluene solution of mDBTCz2P-II, the absorption spectrum obtained by subtraction of the absorption spectra of quartz and toluene from the measured spectra is shown in the drawing and that in the case of the absorption spectrum of the thin film of mDBTCz2P-II, the absorption spectrum obtained by subtraction of the absorption spectrum of the quartz substrate from the measured spectra is shown in the drawing.

FIG. 4A shows that the absorption peak wavelengths of mDBTCz2P-II in the toluene solution of mDBTCz2P-II were around 332 nm, 288 nm, and 281 nm, and the emission peak wavelength thereof was around 370 nm (excitation wavelength: 334 nm). Further, FIG. 4B shows that the absorption peak wavelengths of the thin film of mDBTCz2P-II were around 337 nm, 294 nm, 246 nm, and 209 nm, and the emission peak wavelengths thereof were around 393 nm and 380 nm (excitation wavelength: 342 nm).

Further, the ionization potential of a thin film of mDBTCz2P-II was measured by a photoelectron spectrometer (AC-2, produced by Riken Keiki, Co., Ltd.) in the air. The obtained value of the ionization potential was converted to a negative value, so that the HOMO level of mDBTCz2P-II was −5.93 eV. From the data of the absorption spectra of the thin film in FIG. 4B, the absorption edge of mDBTCz2P-II, which was obtained from a Tauc plot with an assumption of direct transition, was 3.45 eV. Therefore, the optical energy gap of mDBTCz2P-II in the solid state was estimated at 3.45 eV; from the values of the HOMO level obtained above and this energy gap, the LUMO level of mDBTCz2P-II was able to be estimated at −2.48 eV. It was thus found that mDBTCz2P-II had a wide energy gap of 3.45 eV in the solid state.

### Example 2

In this example is described a light-emitting element in which 3,3′-bis(dibenzothiophen-4-yl)-N,N′-(1,3-phenylene)bicarbazole (abbreviation: mDBTCz2P-II, Structural Formula (100)), which is the compound described in Embodiment 1, was used for a material of a hole-transport layer adjacent to a light-emitting layer using an emission center substance that emits blue fluorescence. Note that in this example, mDBTCz2P-II was also used for a composite material with molybdenum oxide in a hole-injection layer.

The molecular structures of organic compounds used in this example are represented by Structural Formulae (i) to (iii) and (100). In the element structure in FIG. 1A, an electron-injection layer is provided between the electron-transport layer 114 and the second electrode 104.

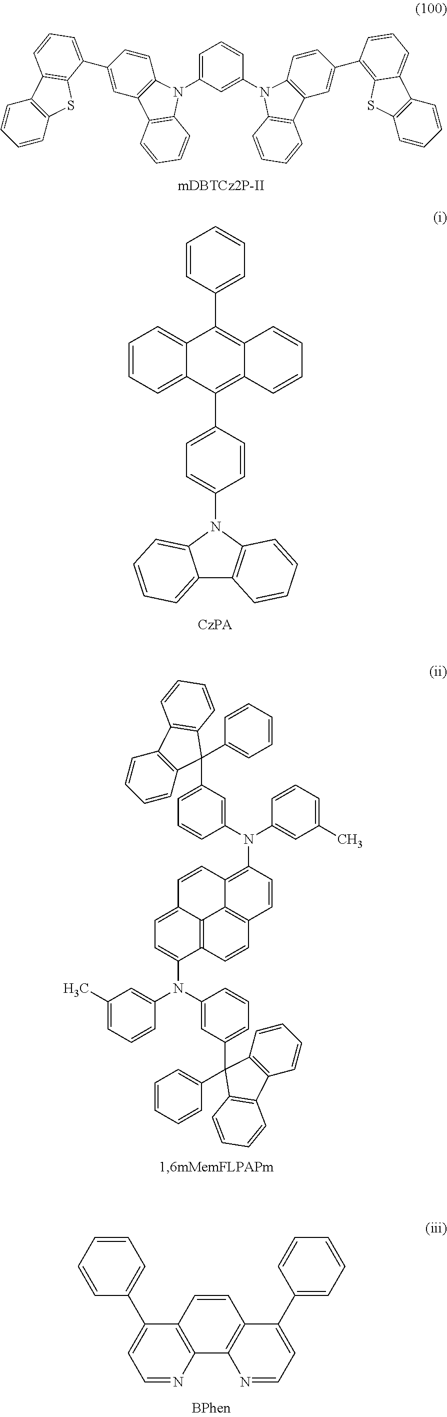

### <<Fabrication of Light-emitting Element 1>>

First, the glass substrate 101, over which a film of indium tin oxide containing silicon (ITSO) was formed to a thickness of 110 nm as the first electrode 102, was prepared. A surface of the ITSO film was covered with a polyimide film so that an area of 2 mm×2 mm of the surface was exposed. The electrode area was 2 mm×2 mm. As pretreatment for forming the light-emitting element over the substrate, the surface of the substrate was washed with water and baked at 200° C. for 1 hour, and then UV-ozone treatment was performed for 370 seconds. After that, the substrate was transferred into a vacuum evaporation apparatus where the pressure had been reduced to approximately 10⁻⁴ Pa, and was subjected to vacuum baking at 170° C. for 30 minutes in a heating chamber of the vacuum evaporation apparatus, and then the substrate was cooled down for about 30 minutes.

Then, the substrate 101 was fixed to a holder provided in the vacuum evaporation apparatus such that the surface of the substrate 101 over which the ITSO film was formed faced downward.

After the pressure in the vacuum evaporation apparatus was reduced to 10⁻⁴ Pa, 3,3′-bis(dibenzothiophen-4-yl)-N,N′-(1,3-phenylene)bicarbazole (abbreviation: mDBTCz2P-II), which is the compound described in Embodiment 1 and represented by Structural Formula (100), and molybdenum(VI) oxide were deposited by co-evaporation so that the weight ratio of mDBTCz2P-II to molybdenum oxide was 2:1; thus, the hole-injection layer 111 was formed. The thickness thereof was set to 50 nm. Note that the co-evaporation is an evaporation method in which a plurality of different substances are concurrently vaporized from the respective different evaporation sources.

Next, mDBTCz2P-II was deposited by evaporation to a thickness of 10 nm, thereby forming the hole-transport layer 112.

Further, over the hole-transport layer 112, 9-[4-(10-phenyl-9-anthryl)phenyl]-9H-carbazole (abbreviation: CzPA) represented by Structural Formula (I) and N,N′-bis(3-methylphenyl)-N,N′-bis[3-(9-phenyl-9H-fluoren-9-yl)phenyl]pyrene-1,6-diamine (abbreviation: 1,6mMemFLPAPrn) represented by Structural Formula (II) were deposited by co-evaporation to a thickness of 30 nm so that the weight ratio of CzPA to 1,6mMemFLPAPrn was 1:0.04. Thus, the light-emitting layer 113 was formed.

Next, CzPA was deposited by evaporation to a thickness of 10 nm, and then bathophenanthroline (abbreviation: BPhen) represented by Structural Formula (iii) was deposited by evaporation to a thickness of 15 nm, thereby forming the electron-transport layer 114.

Further, lithium fluoride was deposited by evaporation to a thickness of 1 nm over the electron-transport layer 114, thereby forming the electron-injection layer. Lastly, an aluminum film was formed to a thickness of 200 nm as the second electrode 104 functioning as a cathode. Thus, the light-emitting element 1 was completed. Note that in all the above evaporation steps, evaporation was performed by a resistance heating method.

### <<Operation Characteristics of Light-Emitting Element 1>>

The light-emitting element 1 thus obtained was sealed in a glove box under a nitrogen atmosphere without being exposed to the air. Then, the operation characteristics of this light-emitting element were measured. Note that the measurements were carried out at room temperature (in an atmosphere kept at 25° C.).

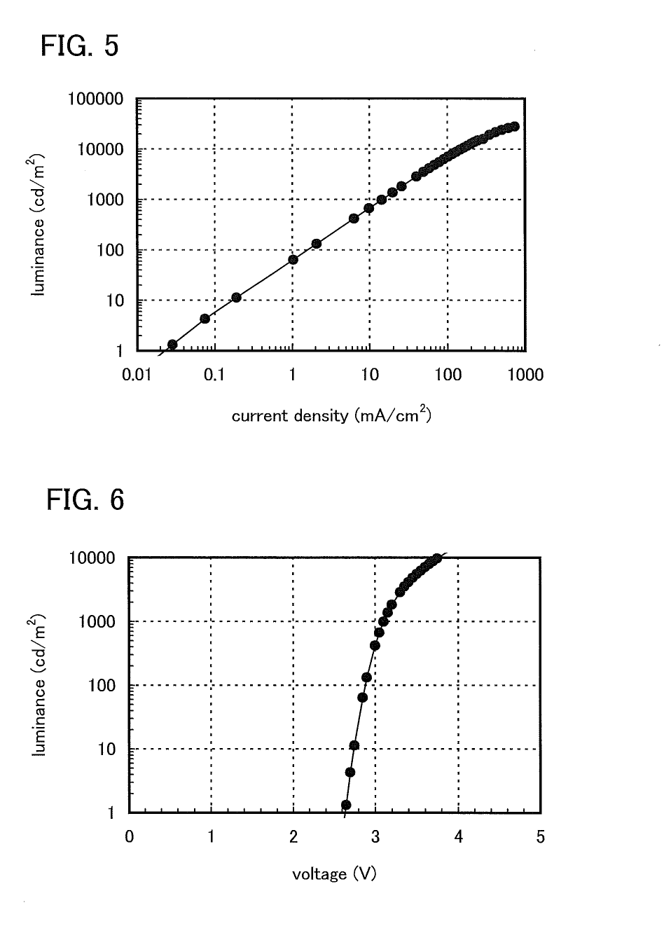

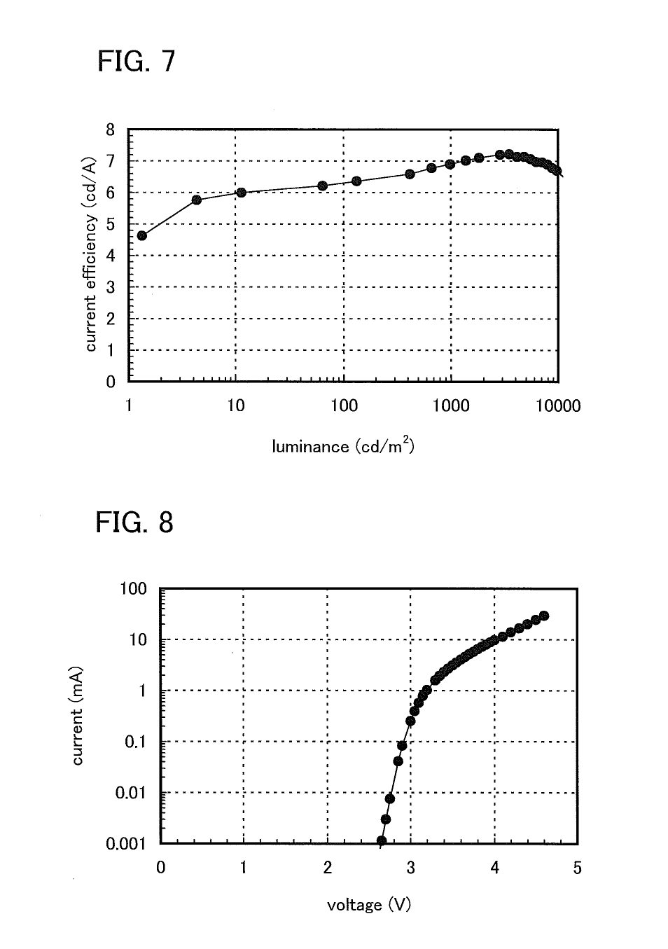

FIG. 5 shows luminance-current density characteristics of the light-emitting element 1, FIG. 6 shows its luminance-voltage characteristics, FIG. 7 shows its current efficiency-luminance characteristics, and FIG. 8 shows its current-voltage characteristics. In FIG. 5, the vertical axis represents luminance (cd/m²) and the horizontal axis represents current density (mA/cm²). In FIG. 6, the vertical axis represents luminance (cd/m²) and the horizontal axis represents voltage (V). In FIG. 7, the vertical axis represents current efficiency (cd/A) and the horizontal axis represents luminance (cd/m²). In FIG. 8, the vertical axis represents current (mA) and the horizontal axis represents voltage (V).

FIG. 7 shows the favorable current efficiency-luminance characteristics of the light-emitting element, in which the compound represented by General Formula (G1) was used for the hole-transport material adjacent to the light-emitting layer emitting blue fluorescence and for the hole-injection layer (as the composite material with molybdenum oxide). Thus, the light-emitting element was found to have high emission efficiency. Since CzPA as the host material of the light-emitting layer in the light-emitting element 1 is a material having a relatively high electron-transport property, a light-emitting region in the light-emitting layer is probably localized on the hole-transport layer side. The high emission efficiency of the light-emitting element despite such a state results from the wide energy gap of the compound represented by General Formula (G1). In other words, since mDBTCz2P-II, which is the compound described in Embodiment 1, has a wide energy gap, even when it is used for the hole-transport layer adjacent to the emission center substance that emits blue fluorescence, a reduction in emission efficiency is inhibited without transfer of excitation energy to the hole-transport layer.

In addition, FIG. 6 shows the favorable luminance-voltage characteristics of the light-emitting element in which the compound represented by General Formula (G1) was used for the host material of the light-emitting layer emitting blue fluorescence. Thus, the light-emitting element was found to have low driving voltage. This indicates that the compound represented by General Formula (G1) has an excellent carrier-transport property and the composite material including the compound represented by General Formula (G1) has an excellent carrier-injection property.

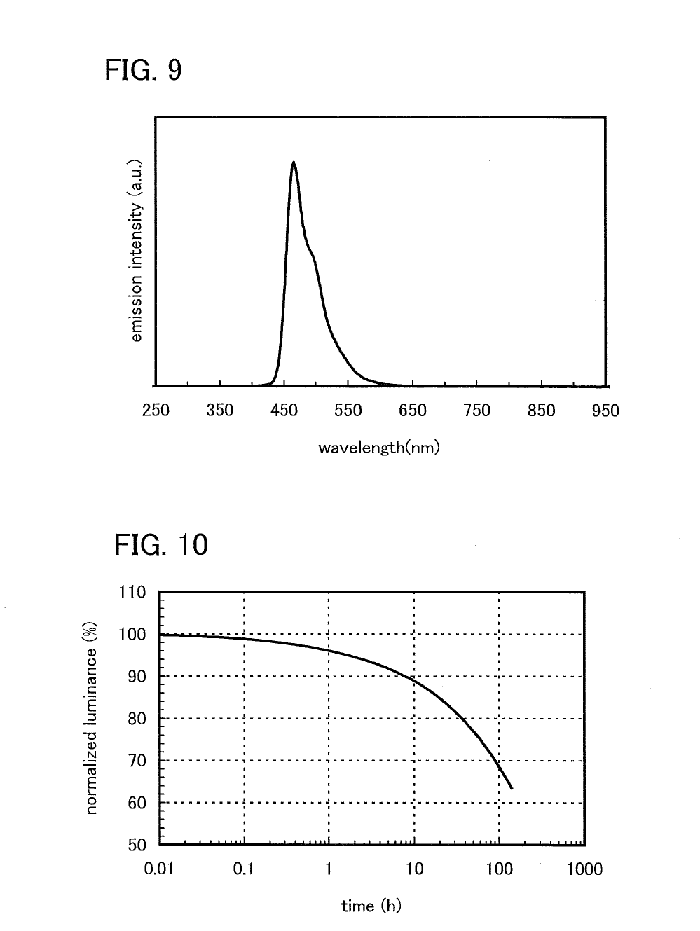

FIG. 9 shows an emission spectrum obtained when a current of 1 mA was made to flow in the light-emitting element 1. In FIG. 9, the vertical axis represents emission intensity (arbitrary unit) and the horizontal axis represents wavelength (nm). The emission intensity is shown as a value relative to the maximum emission intensity assumed to be 1. FIG. 9 indicates that the light-emitting element 1 emits blue light that originates from 1,6mMemFLPAPrn, which is the emission center substance.

Next, with an initial luminance set to 1000 cd/m², the light-emitting element 1 was driven under a condition where the current density was constant, and changes in luminance relative to driving time were examined. FIG. 10 shows the normalized luminance-time characteristics. FIG. 10 shows the favorable characteristics of the light-emitting element 1, and thus the element was found to have high reliability.

### Example 3

In this example is described a light-emitting element in which 3,3′-bis(dibenzothiophen-4-yl)-N,N′-(1,3-phenylene)bicarbazole (abbreviation: mDBTCz2P-II, Structural Formula (100)), which is the compound described in Embodiment 1, was used for a host material of a light-emitting layer using an emission center substance that emits green phosphorescence.

The molecular structures of organic compounds used in this example are represented by Structural Formulae (iii) to (viii) and (100). In the element structure in FIG. 1A, an electron-injection layer is provided between the electron-transport layer 114 and the second electrode 104.

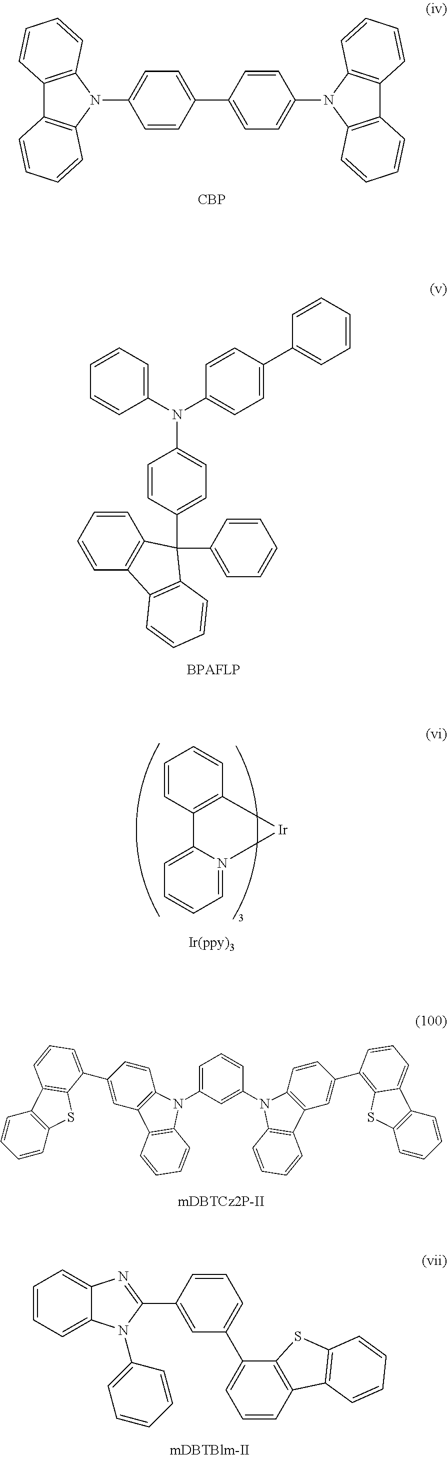

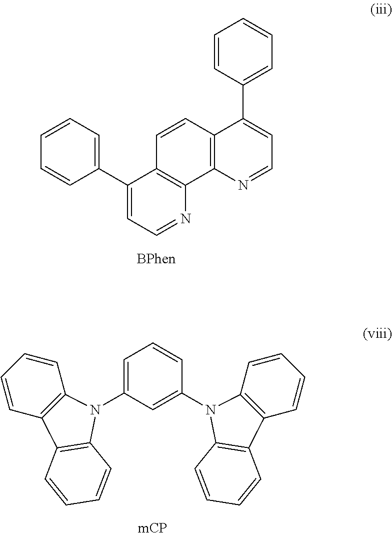 [SMILES: c1ccc(-c2ccnc3c2ccc2c(-c4ccccc4)ccnc23)cc1 ; c1cc(-n2c3ccccc3c3ccccc32)cc(-n2c3ccccc3c3ccccc32)c1]

### <<Fabrication of Light-Emitting Element 2 and Comparative Light-Emitting Element 2>>

First, the glass substrate 101, over which a film of indium tin oxide containing silicon (ITSO) was formed to a thickness of 110 nm as the first electrode 102, was prepared. A surface of the ITSO film was covered with a polyimide film so that an area of 2 mm×2 mm of the surface was exposed. The electrode area was 2 mm×2 mm. As pretreatment for forming the light-emitting element over the substrate, the surface of the substrate was washed with water and baked at 200° C. for 1 hour, and then UV-ozone treatment was performed for 370 seconds. After that, the substrate was transferred into a vacuum evaporation apparatus where the pressure had been reduced to approximately 10⁻⁴ Pa, and was subjected to vacuum baking at 170° C. for 30 minutes in a heating chamber of the vacuum evaporation apparatus, and then the substrate was cooled down for about 30 minutes.

Then, the substrate 101 was fixed to a holder provided in the vacuum evaporation apparatus such that the surface of the substrate 101 over which the ITSO film was formed faced downward.

After the pressure in the vacuum evaporation apparatus was reduced to 10⁻⁴ Pa, 4,4′-bis(N-carbazolyl)biphenyl (abbreviation: CBP) represented by Structural Formula (Iv) and molybdenum(VI) oxide were deposited by co-evaporation so that the weight ratio of CBP to molybdenum oxide was 2:1; thus, the hole-injection layer 111 was formed. The thickness thereof was set to 60 nm. Note that the co-evaporation is an evaporation method in which a plurality of different substances are concurrently vaporized from the respective different evaporation sources.

Next, 4-phenyl-4′-(9-phenylfluoren-9-yl)triphenylamine (abbreviation: BPAFLP) represented by Structural Formula (v) was deposited by evaporation to a thickness of 20 nm, thereby forming the hole-transport layer 112.

Further, over the hole-transport layer 112, 3,3′-bis(dibenzothiophen-4-yl)-N,N′-(1,3-phenylene)bicarbazole (abbreviation: mDBTCz2P-II), which is the compound described in Embodiment 1 and represented by Structural Formula (100), and tris(2-phenylpyridine)iridium (abbreviation: Ir(ppy)₃) represented by Structural Formula (vi) were deposited by co-evaporation to a thickness of 30 nm so that the weight ratio of mDBTCz2P-II to Ir(ppy)₃ was 1:0.08. Thus, the light-emitting layer 113 was formed.

Next, 2-[3-(dibenzothiophen-4-yl)phenyl]-1-phenyl-1H-benzimidazole (abbreviation: mDBTBIm-II) represented by Structural Formula (vii) was deposited by evaporation to a thickness of 15 nm, and then bathophenanthroline (abbreviation: BPhen) represented by Structural Formula (iii) was deposited by evaporation to a thickness of 15 nm, thereby forming the electron-transport layer 114.

Further, lithium fluoride was deposited by evaporation to a thickness of 1 nm over the electron-transport layer 114, thereby forming the electron-injection layer. Lastly, an aluminum film was formed to a thickness of 200 nm as the second electrode 104 functioning as a cathode. Thus, the light-emitting element 2 was completed. Note that in all the above evaporation steps, evaporation was performed by a resistance heating method.

In fabrication of the comparative light-emitting element 2, 1,3-bis(N-carbazolyl)benzene (abbreviation: mCP) represented by Structural Formula (viii) was substituted for mDBTCz2P-II in the light-emitting layer 113 of the light-emitting element 2.

### <<Operation Characteristics of Light-Emitting Element 2 and Comparative Light-Emitting Element 2>>

The light-emitting element 2 and the comparative light-emitting element 2 thus obtained were sealed in a glove box under a nitrogen atmosphere without being exposed to the air. Then, the operation characteristics of these light-emitting elements were measured. Note that the measurements were carried out at room temperature (in an atmosphere kept at 25° C.).

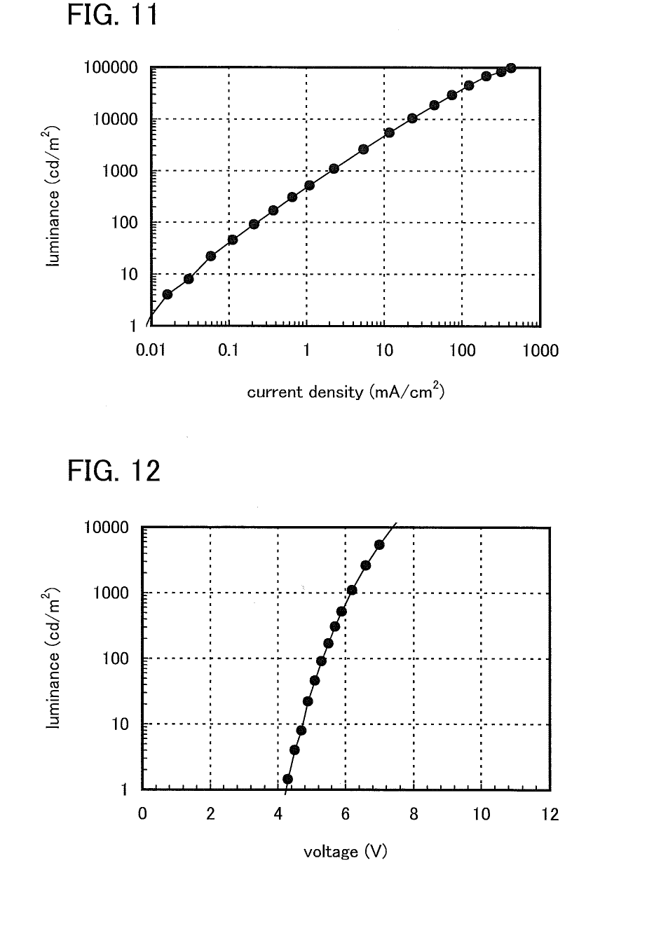

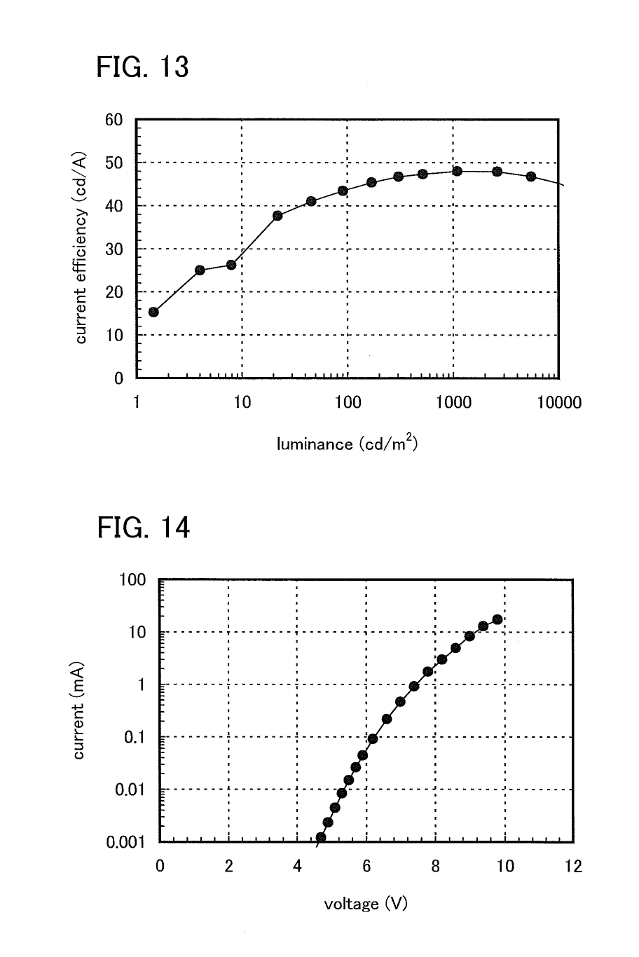

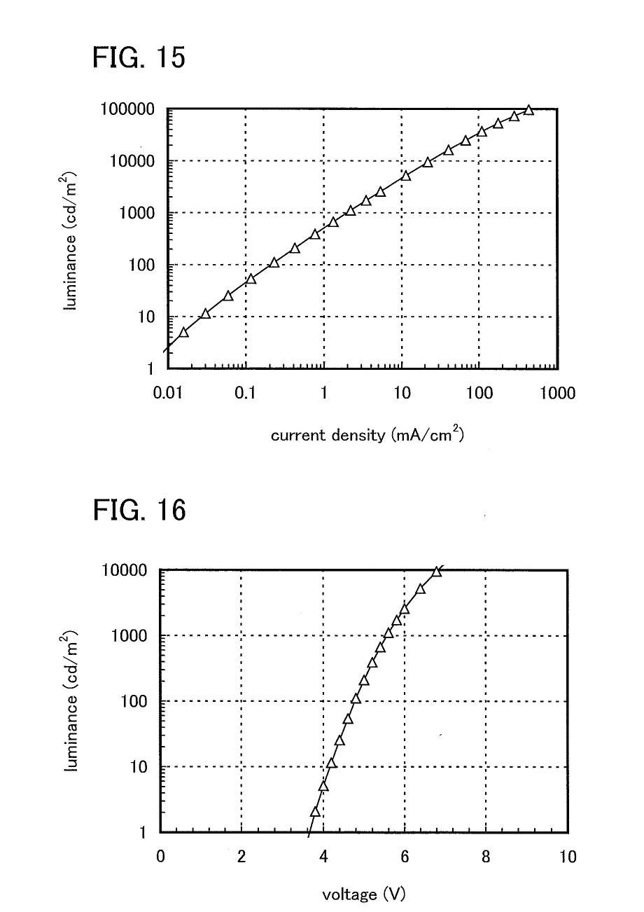

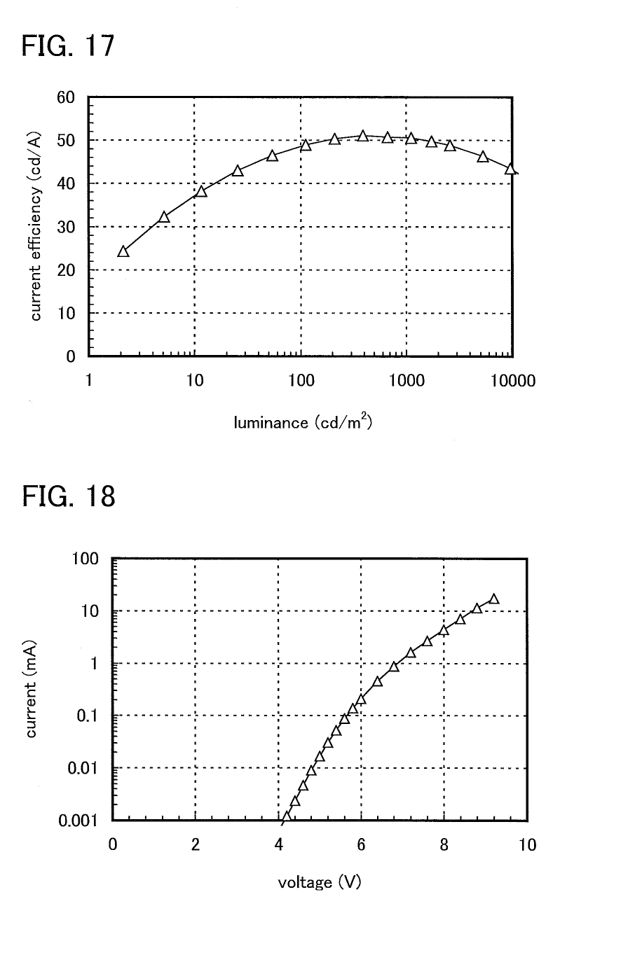

FIG. 11 shows luminance-current density characteristics of the light-emitting element 2, FIG. 12 shows its luminance-voltage characteristics, FIG. 13 shows its current efficiency-luminance characteristics, and FIG. 14 shows its current-voltage characteristics. FIG. 15 shows luminance-current density characteristics of the comparative light-emitting element 2, FIG. 16 shows its luminance-voltage characteristics, FIG. 17 shows its current efficiency-luminance characteristics, and FIG. 18 shows its current-voltage characteristics. In each of FIG. 11 and FIG. 15, the vertical axis represents luminance (cd/m²) and the horizontal axis represents current density (mA/cm²). In each of FIG. 12 and FIG. 16, the vertical axis represents luminance (cd/m²) and the horizontal axis represents voltage (V). In each of FIG. 13 and FIG. 17, the vertical axis represents current efficiency (cd/A) and the horizontal axis represents luminance (cd/m²). In each of FIG. 14 and FIG. 18, the vertical axis represents current (mA) and the horizontal axis represents voltage (V).

FIG. 13 and FIG. 17 indicate that the light-emitting element 2, in which the compound represented by General Formula (G1) was used for the host material of the light-emitting layer emitting green phosphorescence, exhibits as good current efficiency-luminance characteristics as the characteristics of the comparative light-emitting element 2, in which mCP was used for the host material in the same way. Thus, the light-emitting element 2 was found to have high emission efficiency. This is because the compound represented by General Formula (G1) has as high triplet excitation energy and as a wide energy gap as mCP such that even a light-emitting substance that emits green phosphorescence can be effectively excited. In addition, FIG. 12 shows the favorable luminance-voltage characteristics of the light-emitting element in which the compound represented by General Formula (G1) was used for the host material of the light-emitting layer emitting green phosphorescence. Thus, the light-emitting element was found to have low driving voltage. This means that the compound represented by General Formula (G1) has an excellent carrier-transport property.

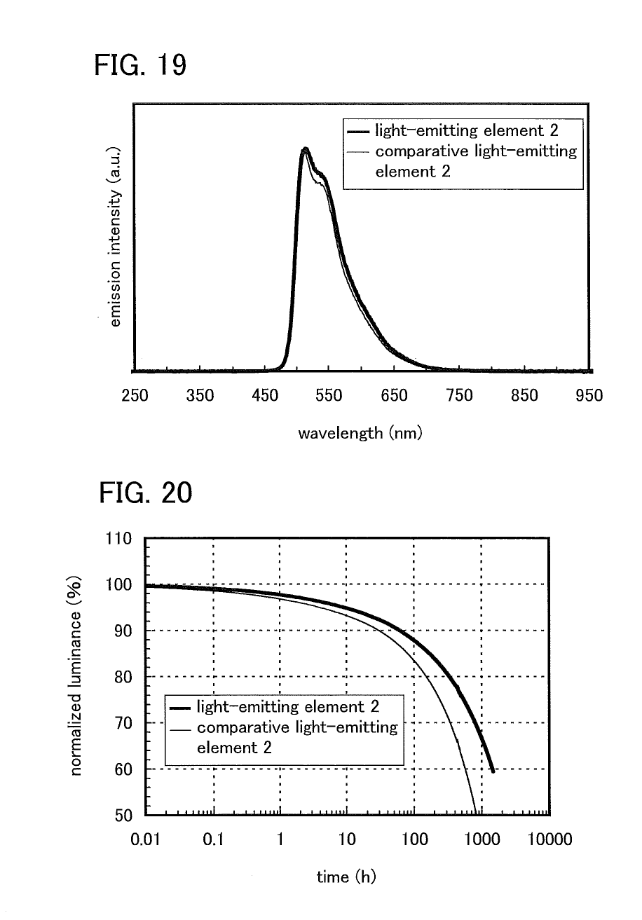

FIG. 19 shows emission spectra obtained when a current of 1 mA was made to flow in each of the light-emitting element 2 and the comparative light-emitting element 2. In FIG. 19, the vertical axis represents emission intensity (arbitrary unit) and the horizontal axis represents wavelength (nm). The emission intensity is shown as a value relative to the maximum emission intensity assumed to be 1. FIG. 19 indicates that the emission spectra of the light-emitting element 2 and the comparative light-emitting element 2 almost overlap with each other and each element exhibit green light emission that originates from Ir(ppy)₃, which is the emission center substance.

Next, with an initial luminance set to 1000 cd/m², these elements were driven under a condition where the current density was constant, and changes in luminance relative to driving time were examined. FIG. 20 shows normalized luminance-time characteristics. FIG. 20 shows that a decrease in luminance relative to driving time is smaller in the light-emitting element 2 than in the comparative light-emitting element 2. Thus, the light-emitting element 2 was found to have high reliability. Since mCP has a wide energy gap and high triplet excitation energy, the substance has been often used for a host material in an element to emit short-wavelength phosphorescence, thereby fabricating a phosphorescent light-emitting element having favorable emission efficiency. However, a light-emitting element using mCP decreases in luminance greatly relative to driving time, that is, has a short lifetime, which has been problematic. Having as a wide energy gap and as high triplet excitation energy as an element using mCP, the light-emitting element 2 using the compound described in Embodiment 1 as the host material was able to achieve an improved lifetime while exhibiting as high emission efficiency as the element using mCP.

### Example 4

In this example are described a light-emitting element (light-emitting element 3) in which 3,3′-bis(dibenzothiophen-4-yl)-N,N′-(1,3-phenylene)bicarbazole (abbreviation: mDBTCz2P-II, Structural Formula (100)), which is the compound described in Embodiment 1, was used for a host material of a light-emitting layer using an emission center substance that emits blue green phosphorescence, and a light-emitting element (light-emitting element 4) in which mDBTCz2P-II was used for a material of a hole-transport layer adjacent to a light-emitting layer using an emission center substance that emits blue green phosphorescence.

The molecular structures of organic compounds used in this example are represented by Structural Formulae (iii), (iv), (vii) to (ix) and (100). In the element structure in FIG. 1A, an electron-injection layer is provided between the electron-transport layer 114 and the second electrode 104.

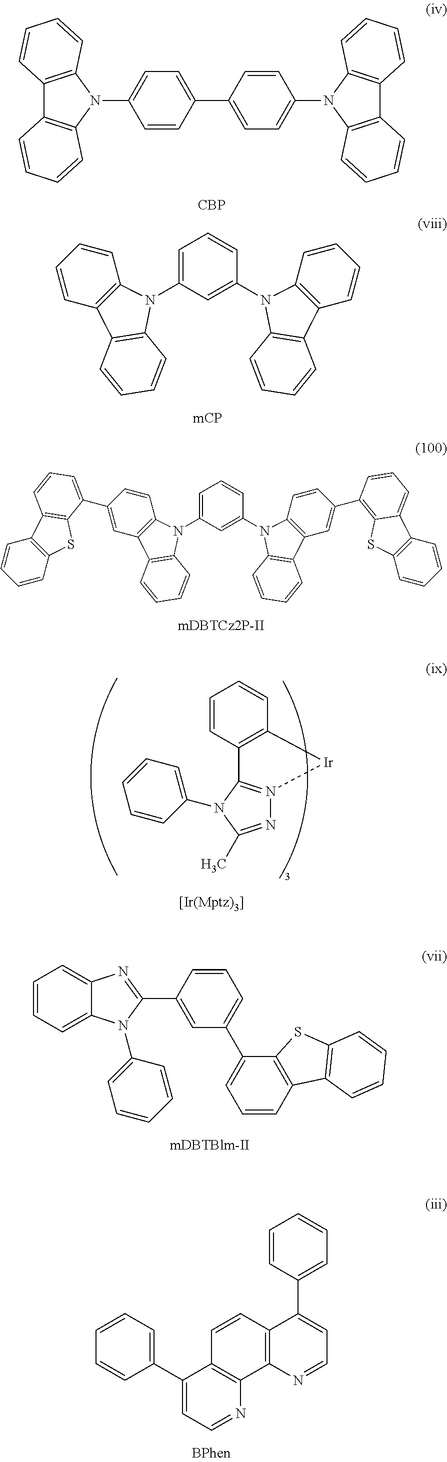

### <<Fabrication of Light-Emitting Element 3 and Light-Emitting Element 4>>

First, the glass substrate 101, over which a film of indium tin oxide containing silicon (ITSO) was formed to a thickness of 110 nm as the first electrode 102, was prepared. A surface of the ITSO film was covered with a polyimide film so that an area of 2 mm×2 mm of the surface was exposed. The electrode area was 2 mm×2 mm. As pretreatment for forming the light-emitting element over the substrate, the surface of the substrate was washed with water and baked at 200° C. for 1 hour, and then UV-ozone treatment was performed for 370 seconds. After that, the substrate was transferred into a vacuum evaporation apparatus where the pressure had been reduced to approximately 10⁻⁴ Pa, and was subjected to vacuum baking at 170° C. for 30 minutes in a heating chamber of the vacuum evaporation apparatus, and then the substrate was cooled down for about 30 minutes.

Then, the substrate 101 was fixed to a holder provided in the vacuum evaporation apparatus such that the surface of the substrate 101 over which the ITSO film was formed faced downward.

After the pressure in the vacuum evaporation apparatus was reduced to 10⁻⁴ Pa, 4,4′-bis(N-carbazolyl)biphenyl (abbreviation: CBP) represented by Structural Formula (Iv) and molybdenum(VI) oxide were deposited by co-evaporation so that the weight ratio of CBP to molybdenum oxide was 2:1; thus, the hole-injection layer 111 was formed. The thickness thereof was set to 60 nm. Note that the co-evaporation is an evaporation method in which a plurality of different substances are concurrently vaporized from the respective different evaporation sources.

Next, for the light-emitting element 3, 1,3-bis(N-carbazolyl)benzene (abbreviation: mCP) represented by Structural Formula (viii) was deposited by evaporation to a thickness of 20 nm, thereby forming the hole-transport layer 112. For the light-emitting element 4, 3,3′-bis(dibenzothiophen-4-yl)-N,N′-(1,3-phenylene)bicarbazole (abbreviation: mDBTCz2P-II), which is the compound described in Embodiment 1 and represented by Structural Formula (100), was deposited by evaporation to a thickness of 20 nm, thereby forming the hole-transport layer 112.

Further, for the light-emitting element 3, the light-emitting layer 113 was formed over the hole-transport layer 112 by forming a stacked layer in such a way that mDBTCz2P-II and tris(5-methyl-3,4-diphenyl-4H-1,2,4-triazolato)iridium(III) (abbreviation: [Ir(Mptz)₃]) represented by Structural Formula (ix) were deposited by co-evaporation to a thickness of 30 nm so that the weight ratio of mDBTCz2P-II to [Ir(Mptz)₃] was 1:0.08, and thereover, 2-[3-(dibenzothiophen-4-yl)phenyl]-1-phenyl-1H-benzimidazole (abbreviation: mDBTBIm-II) represented by Structural Formula (vii) and [Ir(Mptz)₃] were deposited by co-evaporation to a thickness of 10 nm so that the weight ratio of mDBTBIm-II to [Ir(Mptz)₃] was 1:0.08.

For the light-emitting element 4, the light-emitting layer 113 was formed by forming a stacked layer in such a way that mCP and tris(5-methyl-3,4-diphenyl-4H-1,2,4-triazolato)iridium(III) (abbreviation: [Ir(Mptz)₃]) represented by Structural Formula (ix) were deposited by co-evaporation to a thickness of 30 nm so that the weight ratio of mCP to [Ir(Mptz)₃] was 1:0.08, and thereover, 2-[3-(dibenzothiophen-4-yl)phenyl]-1-phenyl-1H-benzimidazole (abbreviation: mDBTBIm-II) represented by Structural Formula (vii) and [Ir(Mptz)₃] were deposited by co-evaporation to a thickness of 10 nm so that the weight ratio of mDBTBIm-II to [Ir(Mptz)₃] was 1:0.08.

Next, bathophenanthroline (abbreviation: BPhen) represented by Structural Formula (iii) was deposited by evaporation to a thickness of 15 nm, thereby forming the electron-transport layer 114.

Further, lithium fluoride was deposited by evaporation to a thickness of 1 nm over the electron-transport layer 114, thereby forming the electron-injection layer. Lastly, an aluminum film was formed to a thickness of 200 nm as the second electrode 104 functioning as a cathode. Thus, the light-emitting elements 3 and 4 were completed. Note that in all the above evaporation steps, evaporation was performed by a resistance heating method.

### <<Operation Characteristics of Light-Emitting Element 3 and Light-Emitting Element 4>>

The light-emitting elements 3 and 4 thus obtained were sealed in a glove box under a nitrogen atmosphere without being exposed to the air. Then, the operation characteristics of these light-emitting elements were measured. Note that the measurements were carried out at room temperature (in an atmosphere kept at 25° C.).

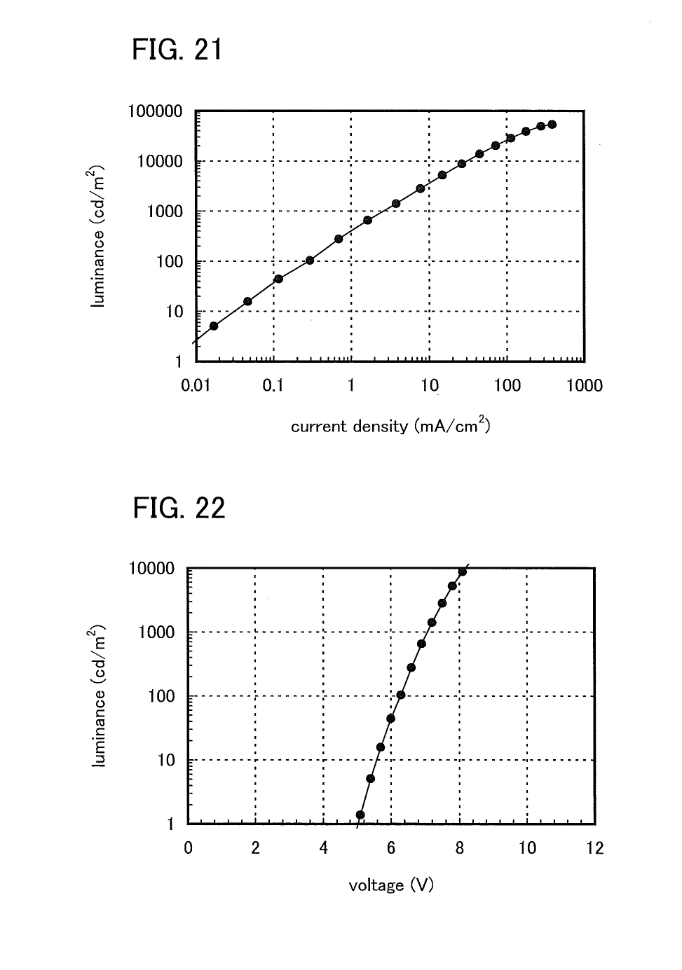

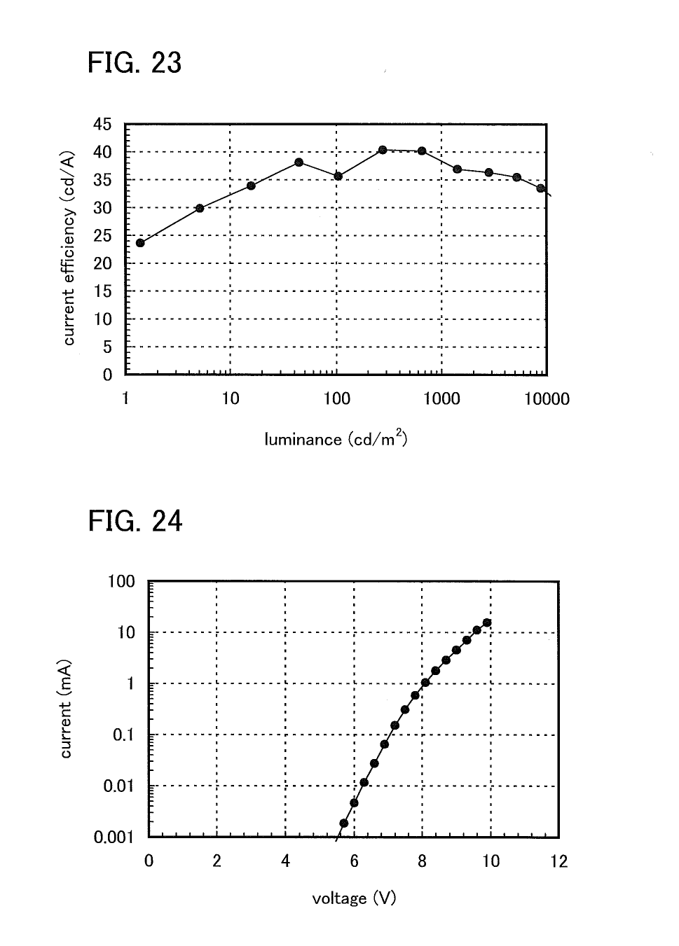

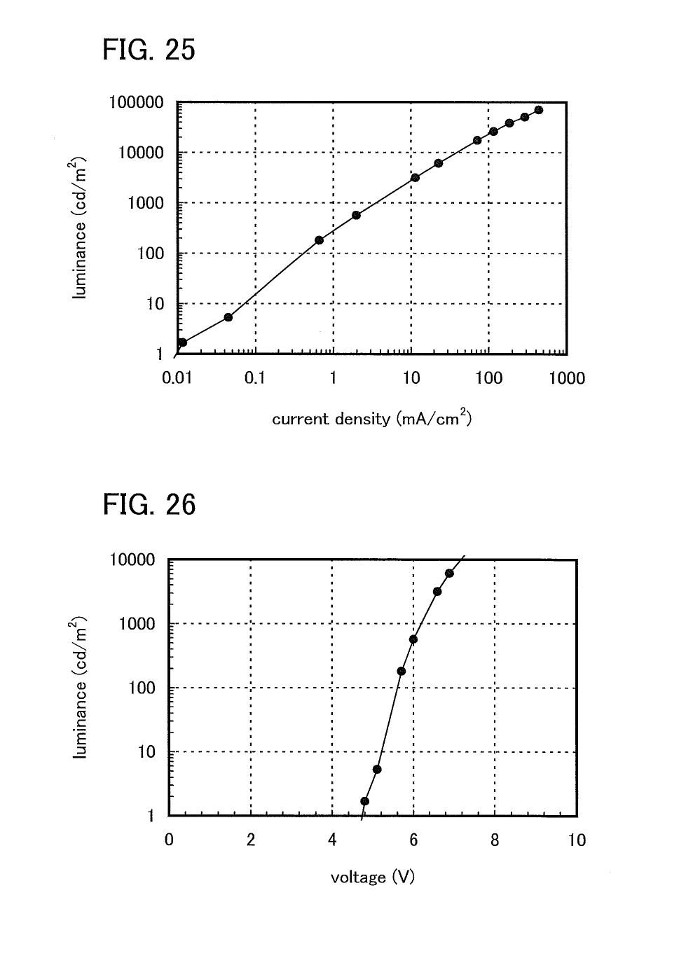

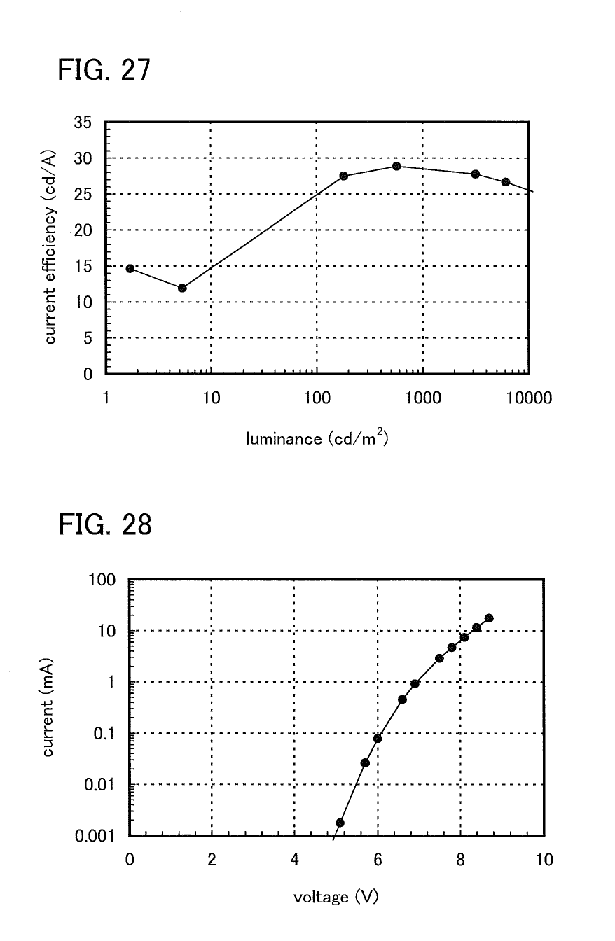

FIG. 21 shows luminance-current density characteristics of the light-emitting element 3, FIG. 22 shows its luminance-voltage characteristics, FIG. 23 shows its current efficiency-luminance characteristics, and FIG. 24 shows its current-voltage characteristics. FIG. 25 shows luminance-current density characteristics of the light-emitting element 4, FIG. 26 shows its luminance-voltage characteristics, FIG. 27 shows its current efficiency-luminance characteristics, and FIG. 28 shows its current-voltage characteristics. In each of FIG. 21 and FIG. 25, the vertical axis represents luminance (cd/m²) and the horizontal axis represents current density (mA/cm²). In each of FIG. 22 and FIG. 26, the vertical axis represents luminance (cd/m²) and the horizontal axis represents voltage (V). In each of FIG. 23 and FIG. 27, the vertical axis represents current efficiency (cd/A) and the horizontal axis represents luminance (cd/m²). In each of FIG. 24 and FIG. 28, the vertical axis represents current (mA) and the horizontal axis represents voltage (V).

FIG. 23 shows the favorable current efficiency-luminance characteristics of the light-emitting element 3, in which the compound represented by General Formula (G1) was used for the host material of the light-emitting layer emitting blue green phosphorescence. Thus, the element was found to have high emission efficiency. This is because the compound represented by General Formula (G1) has high triplet excitation energy and a wide energy gap such that even a light-emitting substance that emits blue green phosphorescence can be effectively excited. In addition, FIG. 22 shows the favorable luminance-voltage characteristics of the light-emitting element in which the compound represented by General Formula (G1) was used for the host material of the light-emitting layer emitting blue green phosphorescence. Thus, the light-emitting element was found to have low driving voltage. This means that the compound represented by General Formula (G1) has an excellent carrier-transport property.

FIG. 27 shows the favorable current efficiency-luminance characteristics of the light-emitting element 4, in which the compound represented by General Formula (G1) was used for the hole-transport material adjacent to the light-emitting layer emitting blue green phosphorescence. Thus, the element was found to have high emission efficiency. This is because since mDBTCz2P-II, which is the compound described in Embodiment 1, has a wide energy gap and a high triplet excitation energy accordingly, even when it is used for the hole-transport layer adjacent to the emission center substance that emits blue green phosphorescence, a reduction in emission efficiency is inhibited without transfer of excitation energy to the hole-transport layer. In addition, FIG. 26 shows the favorable luminance-voltage characteristics of the light-emitting element in which the compound represented by General Formula (G1) was used for the host material of the light-emitting layer emitting blue green phosphorescence. Thus, the element was found to have low driving voltage. This means that the compound represented by General Formula (G1) has an excellent carrier-transport property.

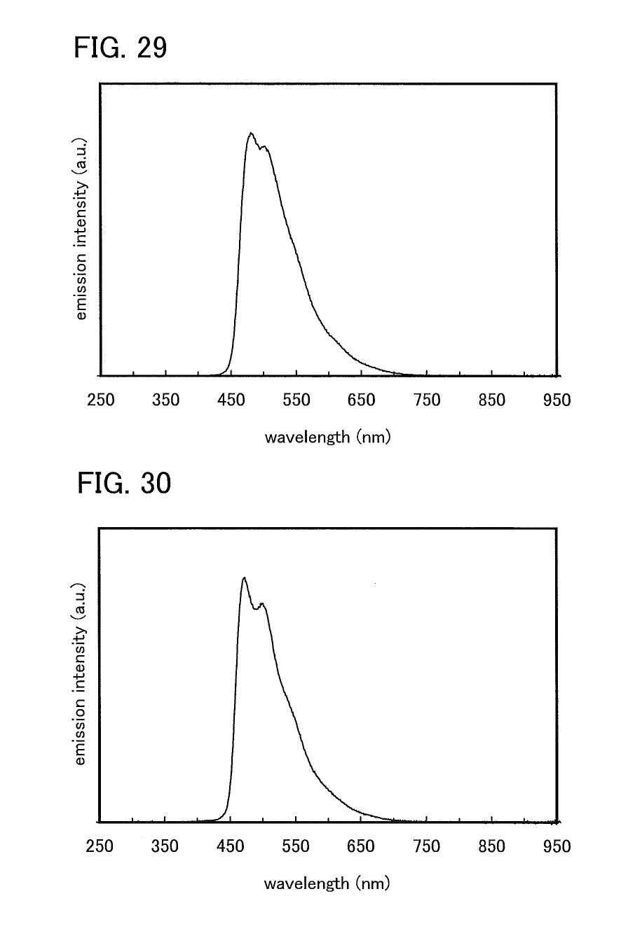

FIG. 29 shows an emission spectrum when a current of 0.1 mA was made to flow in the fabricated light-emitting element 3, and FIG. 30 shows an emission spectrum when a current of 0.1 mA was made to flow in the light-emitting element 4. In each of FIG. 29 and FIG. 30, the vertical axis represents emission intensity (arbitrary unit) and the horizontal axis represents wavelength (nm). The emission intensity is shown as a value relative to the maximum emission intensity assumed to be 1. FIG. 29 and FIG. 30 indicate that each of the light-emitting elements 3 and 4 emits blue green light that originates from [Ir(Mptz)₃], which is the emission center substance.

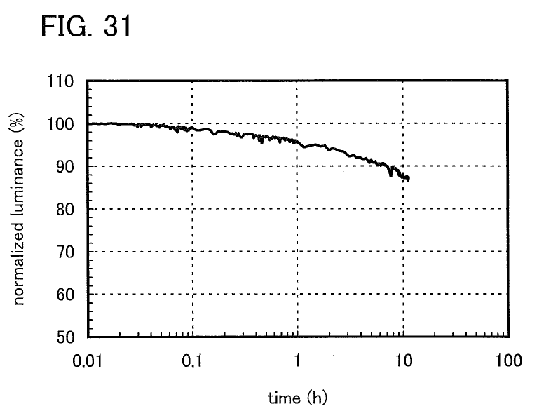

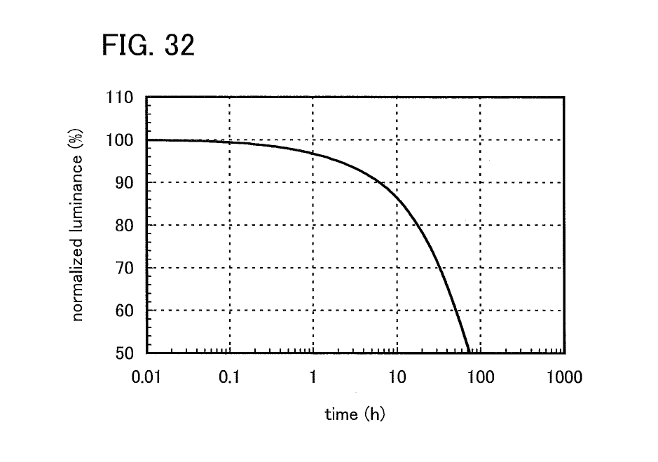

Next, with an initial luminance set to 1000 cd/m², these elements were driven under a condition where the current density was constant, and changes in luminance relative to driving time were examined FIG. 31 shows normalized luminance-time characteristics of the light-emitting element 3, and FIG. 32 shows those of the light-emitting element 4. As can be seen from FIG. 31 and FIG. 32, the decrease in the luminance of each of the light-emitting elements 3 and 4 relative to driving time is small. Thus, each element was found to have high reliability.

Thus, a light-emitting element, in which an emission center substance emits blue green phosphorescence and the compound described in Embodiment 1 is used for a host material or for a hole-transport material, can have high emission efficiency by effective excitation for blue green phosphorescence which is the light emission from the high triplet excitation energy or by prevention of a loss due to energy transfer. This demonstrates the high triplet excitation energy of the compound described in Embodiment 1.

### Example 5

In this example are described a light-emitting element (light-emitting element 5) in which 3,3′-bis(dibenzothiophen-4-yl)-N,N′-(1,3-phenylene)bicarbazole (abbreviation: mDBTCz2P-II, Structural Formula (100)), which is the compound described in Embodiment 1, was used for a host material of a light-emitting layer using an emission center substance that emits blue phosphorescence, and a light-emitting element (light-emitting element 6) in which mDBTCz2P-II was used for a material of a hole-transport layer adjacent to a light-emitting layer using an emission center substance that emits blue phosphorescence.

The molecular structures of organic compounds used in this example are represented by Structural Formulae (iii), (iv), (vii), (viii), (x), and (100). In the element structure in FIG. 1A, an electron-injection layer is provided between the electron-transport layer 114 and the second electrode 104.

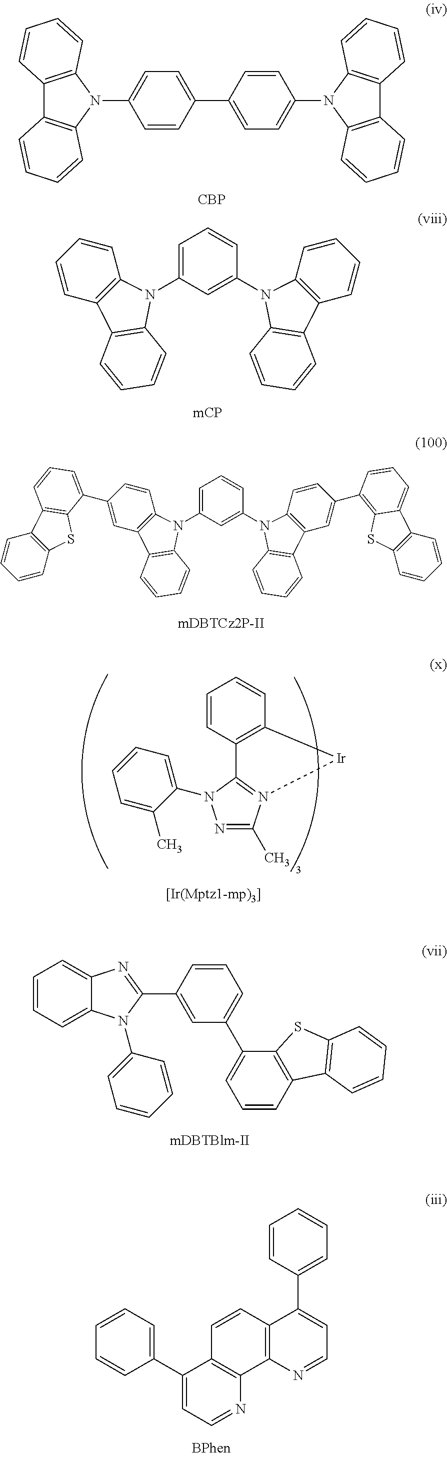

### <<Fabrication of Light-Emitting Element 5 and Light-Emitting Element 6>>

First, the glass substrate 101, over which a film of indium tin oxide containing silicon (ITSO) was formed to a thickness of 110 nm as the first electrode 102, was prepared. A surface of the ITSO film was covered with a polyimide film so that an area of 2 mm×2 mm of the surface was exposed. The electrode area was 2 mm×2 mm. As pretreatment for forming the light-emitting element over the substrate, the surface of the substrate was washed with water and baked at 200° C. for 1 hour, and then UV-ozone treatment was performed for 370 seconds. After that, the substrate was transferred into a vacuum evaporation apparatus where the pressure had been reduced to approximately 10⁻⁴ Pa, and was subjected to vacuum baking at 170° C. for 30 minutes in a heating chamber of the vacuum evaporation apparatus, and then the substrate was cooled down for about 30 minutes.

Then, the substrate 101 was fixed to a holder provided in the vacuum evaporation apparatus such that the surface of the substrate 101 over which the ITSO film was formed faced downward.

After the pressure in the vacuum evaporation apparatus was reduced to 10⁻⁴ Pa, 4,4′-bis(N-carbazolyl)biphenyl (abbreviation: CBP) represented by Structural Formula (Iv) and molybdenum(VI) oxide were deposited by co-evaporation so that the weight ratio of CBP to molybdenum oxide was 2:1; thus, the hole-injection layer 111 was formed. The thickness thereof was set to 60 nm. Note that the co-evaporation is an evaporation method in which a plurality of different substances are concurrently vaporized from the respective different evaporation sources.

Next, for the light-emitting element 5,1,3-bis(N-carbazolyl)benzene (abbreviation: mCP) represented by Structural Formula (viii) was deposited by evaporation to a thickness of 20 nm, thereby forming the hole-transport layer 112. For the light-emitting element 6, 3,3′-bis(dibenzothiophen-4-yl)-N,N′-(1,3-phenylene)bicarbazole (abbreviation: mDBTCz2P-II), which is the compound described in Embodiment 1 and represented by Structural Formula (100), was deposited by evaporation to a thickness of 20 nm, thereby forming the hole-transport layer 112.

Further, for the light-emitting element 5, the light-emitting layer 113 was formed over the hole-transport layer 112 by forming a stacked layer in such a way that mDBTCz2P-II and tris[3-methyl-1-(2-methylphenyl)-5-phenyl-1H-1,2,4-triazolato]iridium(III) (abbreviation: [Ir(Mptz1-mp)₃]) represented by Structural Formula (x) were deposited by co-evaporation to a thickness of 30 nm so that the weight ratio of mDBTCz2P-II to [Ir(Mptz1-mp)₃] was 1:0.08, and thereover, 2-[3-(dibenzothiophen-4-yl)phenyl]-1-phenyl-1H-benzimidazole (abbreviation: mDBTBIm-II) represented by Structural Formula (vii) and [Ir(Mptz1-mp)₃] were deposited by co-evaporation to a thickness of 10 nm so that the weight ratio of mDBTBIm-II to [Ir(Mptz1-mp)₃] was 1:0.08.

For the light-emitting element 6, the light-emitting layer 113 was formed by forming a stacked layer in such a way that mCP and [Ir(Mptz1-mp)₃] were deposited by co-evaporation to a thickness of 30 nm so that the weight ratio of mCP to [Ir(Mptz1-mp)₃] was 1:0.08, and thereover, mDBTBIm-II and [Ir(Mptz1-mp)₃] were deposited by co-evaporation to a thickness of 10 nm so that the weight ratio of mDBTBIm-II to [Ir(Mptz1-mp)₃] was 1:0.08.

Next, bathophenanthroline (abbreviation: BPhen) represented by Structural Formula (iii) was deposited by evaporation to a thickness of 15 nm, thereby forming the electron-transport layer 114.

Further, lithium fluoride was deposited by evaporation to a thickness of 1 nm over the electron-transport layer 114, thereby forming the electron-injection layer. Lastly, an aluminum film was formed to a thickness of 200 nm as the second electrode 104 functioning as a cathode. Thus, the light-emitting elements 5 and 6 were completed. Note that in all the above evaporation steps, evaporation was performed by a resistance heating method.

### <<Operation Characteristics of Light-Emitting Element 5 and Light-Emitting Element 6>>

The light-emitting elements 5 and 6 thus obtained were sealed in a glove box under a nitrogen atmosphere without being exposed to the air. Then, the operation characteristics of these light-emitting elements were measured. Note that the measurements were carried out at room temperature (in an atmosphere kept at 25° C.).

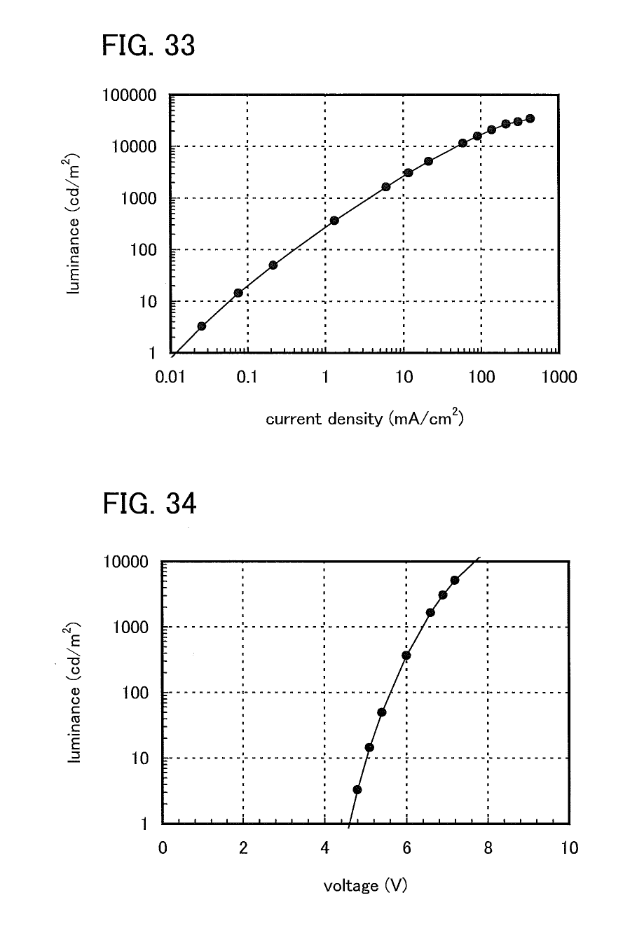

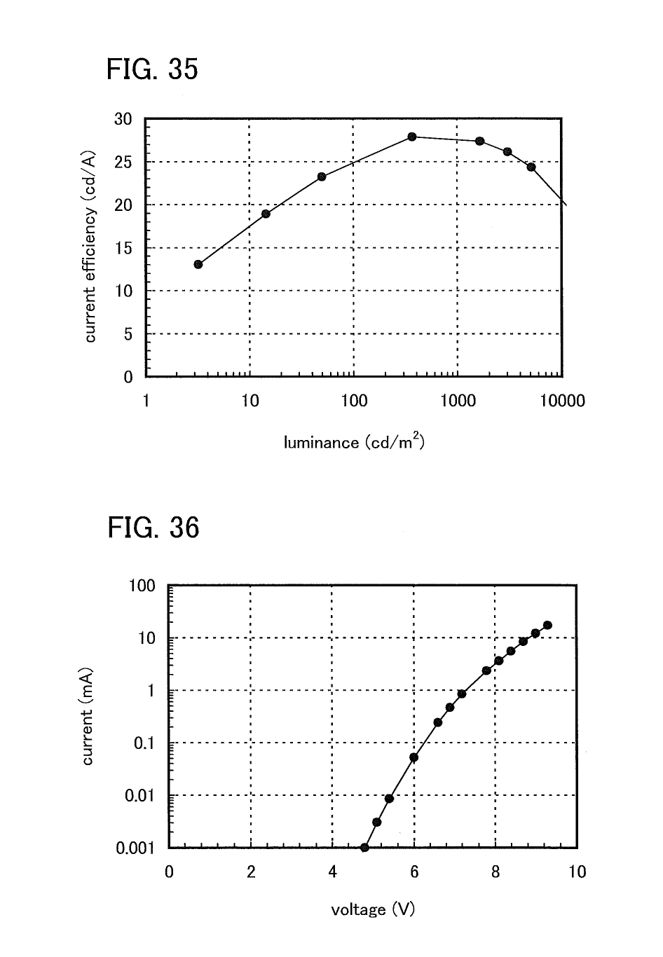

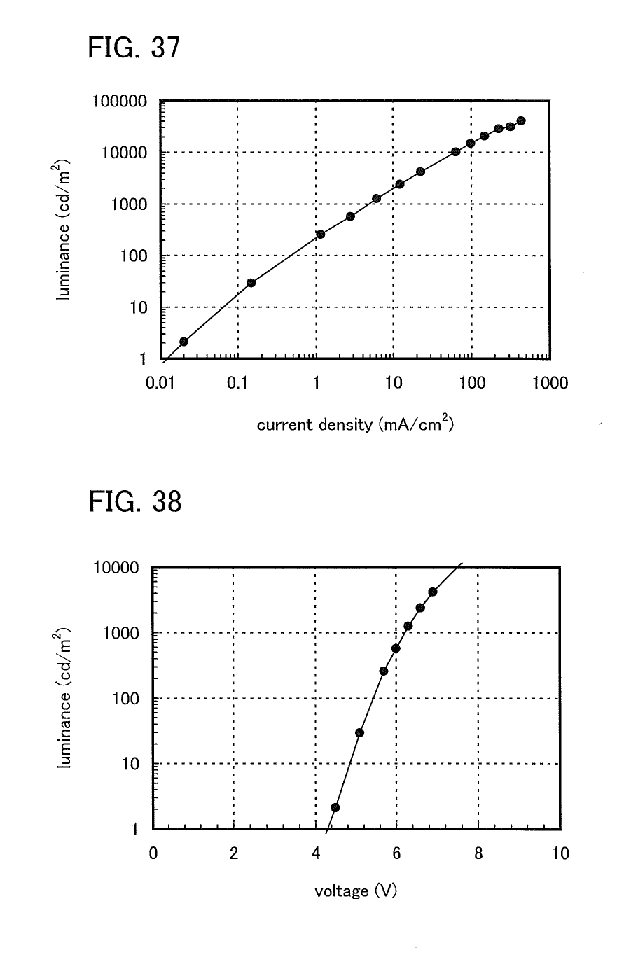

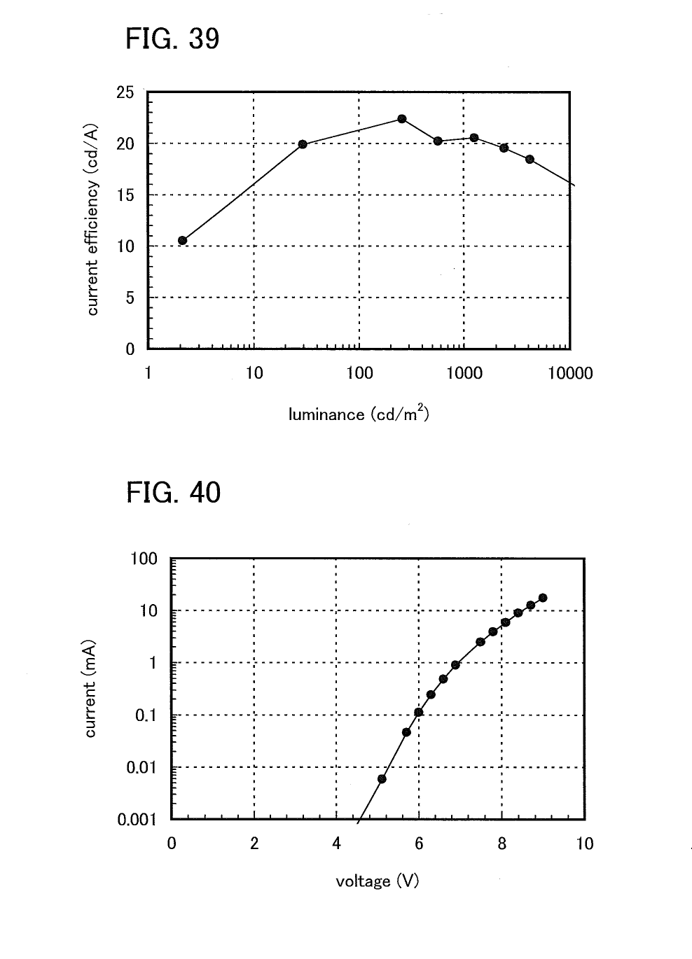

FIG. 33 shows luminance-current density characteristics of the light-emitting element 5, FIG. 34 shows its luminance-voltage characteristics, FIG. 35 shows its current efficiency-luminance characteristics, and FIG. 36 shows its current-voltage characteristics. FIG. 37 shows luminance-current density characteristics of the light-emitting element 6, FIG. 38 shows its luminance-voltage characteristics, FIG. 39 shows its current efficiency-luminance characteristics, and FIG. 40 shows its current-voltage characteristics. In each of FIG. 33 and FIG. 37, the vertical axis represents luminance (cd/m²) and the horizontal axis represents current density (mA/cm²). In each of FIG. 34 and FIG. 38, the vertical axis represents luminance (cd/m²) and the horizontal axis represents voltage (V). In each of FIG. 35 and FIG. 39, the vertical axis represents current efficiency (cd/A) and the horizontal axis represents luminance (cd/m²). In each of FIG. 36 and FIG. 40, the vertical axis represents current (mA) and the horizontal axis represents voltage (V).

FIG. 35 shows the favorable current efficiency-luminance characteristics of the light-emitting element 5, in which the compound represented by General Formula (G0 was used for the host material of the light-emitting layer emitting blue phosphorescence. Thus, the element was found to have high emission efficiency. This is because the compound represented by General Formula (G1) has high triplet excitation energy and a wide energy gap such that even a light-emitting substance that emits blue phosphorescence can be effectively excited. In addition, FIG. 34 shows the favorable luminance-voltage characteristics of the light-emitting element in which the compound represented by General Formula (G1) was used for the host material of the light-emitting layer emitting blue phosphorescence. Thus, the element was found to have low driving voltage. This means that the compound represented by General Formula (G1) has an excellent carrier-transport property.

FIG. 39 shows the favorable current efficiency-luminance characteristics of the light-emitting element 6, in which the compound represented by General Formula (G1) was used for the hole-transport material adjacent to the light-emitting layer emitting blue phosphorescence. Thus, the element was found to have high emission efficiency. This is because since mDBTCz2P-II, which is the compound described in Embodiment 1, has a wide energy gap and a high triplet excitation energy accordingly, even when it is used for the hole-transport layer adjacent to the emission center substance that emits blue phosphorescence, a reduction in emission efficiency is inhibited without transfer of excitation energy to the hole-transport layer. In addition, FIG. 38 shows the favorable luminance-voltage characteristics of the light-emitting element in which the compound represented by General Formula (G1) was used for the host material of the light-emitting layer emitting blue phosphorescence. Thus, the element was found to have low driving voltage. This means that the compound represented by General Formula (G1) has an excellent carrier-transport property.

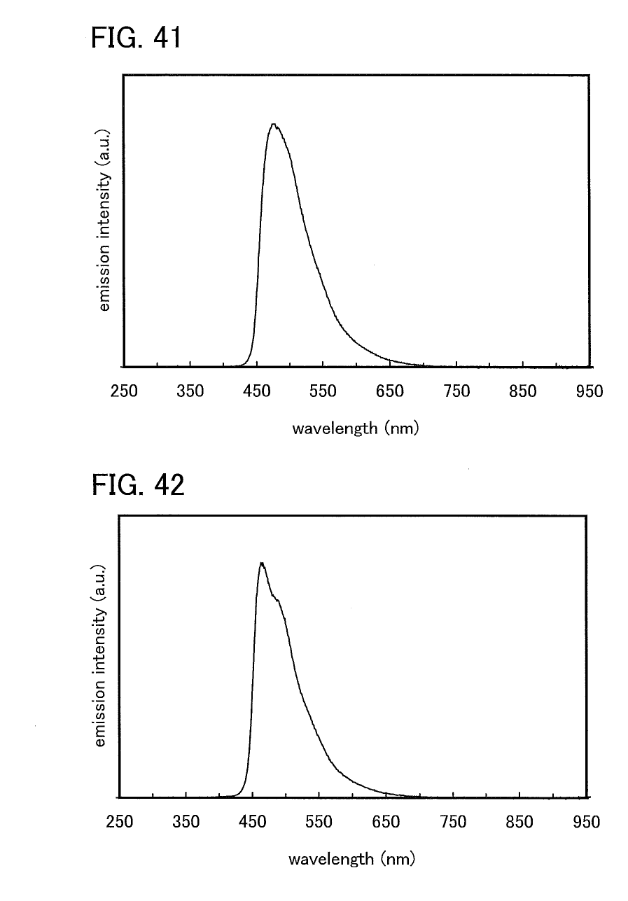

FIG. 41 shows an emission spectrum when a current of 0.1 mA was made to flow in the fabricated light-emitting element 5, and FIG. 42 shows an emission spectrum when a current of 0.1 mA was made to flow in the light-emitting element 6. In each of FIG. 41 and FIG. 42, the vertical axis represents emission intensity (arbitrary unit) and the horizontal axis represents wavelength (nm). The emission intensity is shown as a value relative to the maximum emission intensity assumed to be 1. FIG. 41 and FIG. 42 indicate that each of the light-emitting elements 5 and 6 emits blue light that originates from [Ir(Mptz1-mp)₃], which is the emission center substance.

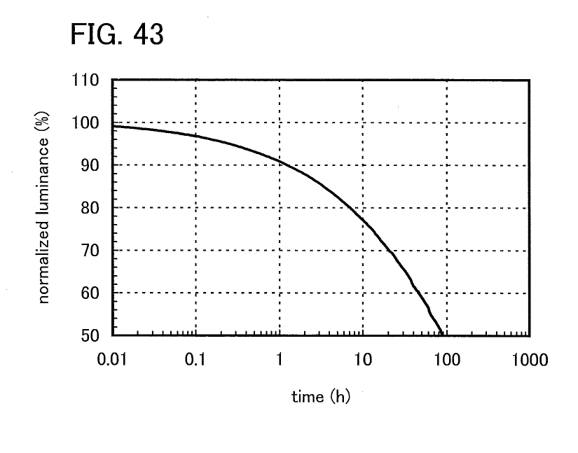

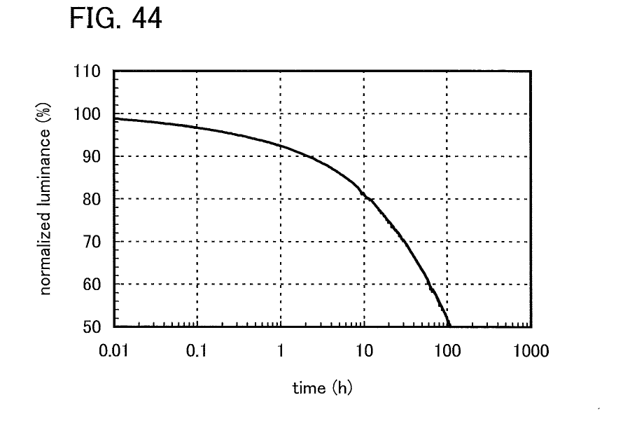

Next, with an initial luminance set to 1000 cd/m², these elements were driven under a condition where the current density was constant, and changes in luminance relative to driving time were examined. FIG. 43 shows normalized luminance-time characteristics of the light-emitting element 5, and FIG. 44 shows those of the light-emitting element 6. As can be seen from FIG. 43 and FIG. 44, the decrease in the luminance of each of the light-emitting elements 5 and 6 relative to driving time is small. Thus, each element was found to have high reliability.

Thus, a light-emitting element, in which an emission center substance emits blue green phosphorescence and the compound described in Embodiment 1 is used for a host material or for a hole-transport material, can have high emission efficiency by effective excitation for blue green phosphorescence which is the light emission from the high triplet excitation energy or by prevention of a loss due to energy transfer. This demonstrates the extremely high triplet excitation energy of the compound described in Embodiment 1.

### Example 6

In this example is described results of a mass spectrometric analysis of 3,3′-bis(dibenzothiophen-4-yl)-N,N′-(1,3-phenylene)bicarbazole (abbreviation: mDBTCz2P-II). The mass spectrometric analysis was carried out with a liquid chromatography mass spectrometer (LC/MS) and a time-of-flight secondary ion mass spectrometer (ToF-SIMS).

<<Results of the Analysis with the Liquid Chromatography Mass Spectrometer (LC/MS)>>

First, results of the mass spectrometric analysis with the liquid chromatography mass spectrometer (LC/MS) are described.

The LC/MS analysis was carried out with Acquity UPLC (produced by Waters Corporation) and Xevo G2 T of MS (produced by Waters Corporation). Ionization was carried out by an electrospray ionization (ESI) method. At this time, the capillary voltage and the sample cone voltage were set to 3.00 kV and 30 V, respectively, and detection was performed in a positive mode. A component which underwent the ionization under the above conditions was collided with an argon gas in a collision cell. Energy (collision energy) for the collision with argon was 30 eV, 50 eV, and 70 eV. A range for the measurement was m/z (mass to charge ratio)=100-1200.

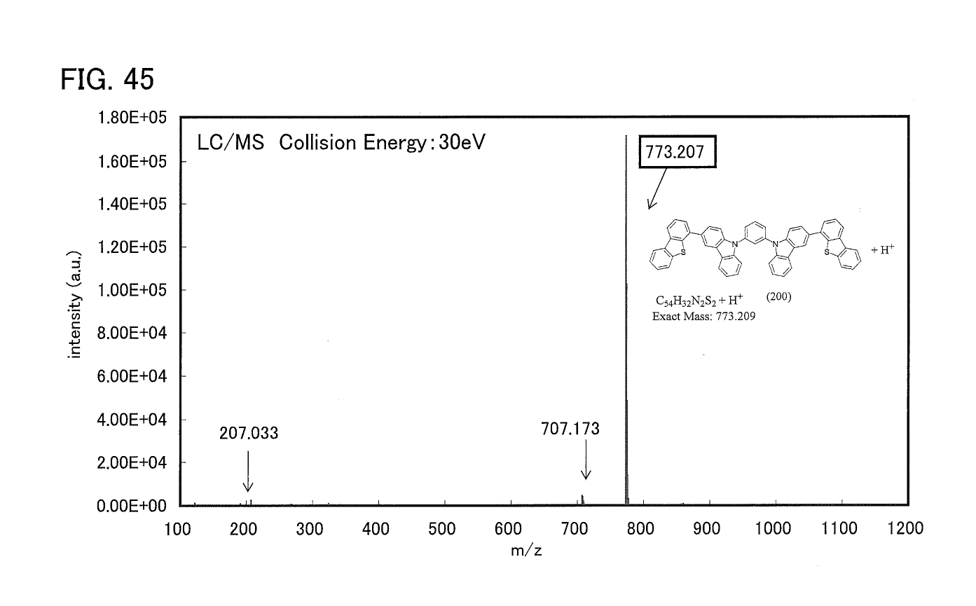

FIG. 45 shows measurement results given at the time when the collision energy was 30 eV. Peaks were observed at m/z=207.033, m/z=707.173, and m/z=773.207.

Among these peaks, one at m/z=773.207 was presumably derived from mDBTCz2P-II which was protonated (a compound represented by Structural Formula (200)) and whose composition formula is C₅₄H₃₂N₂S₂+H⁺ (exact mass: 773.209).

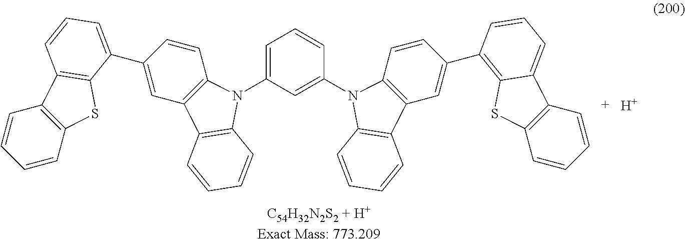

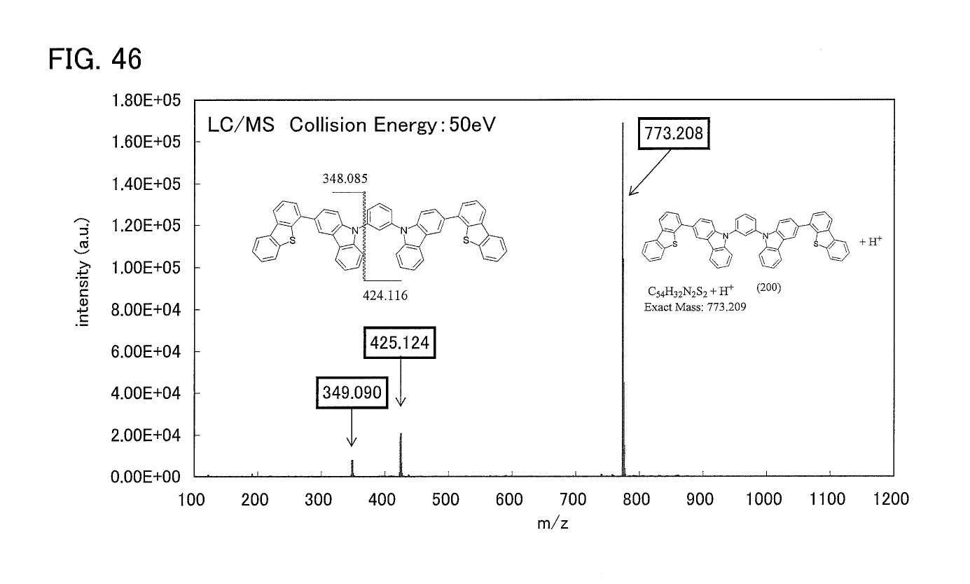

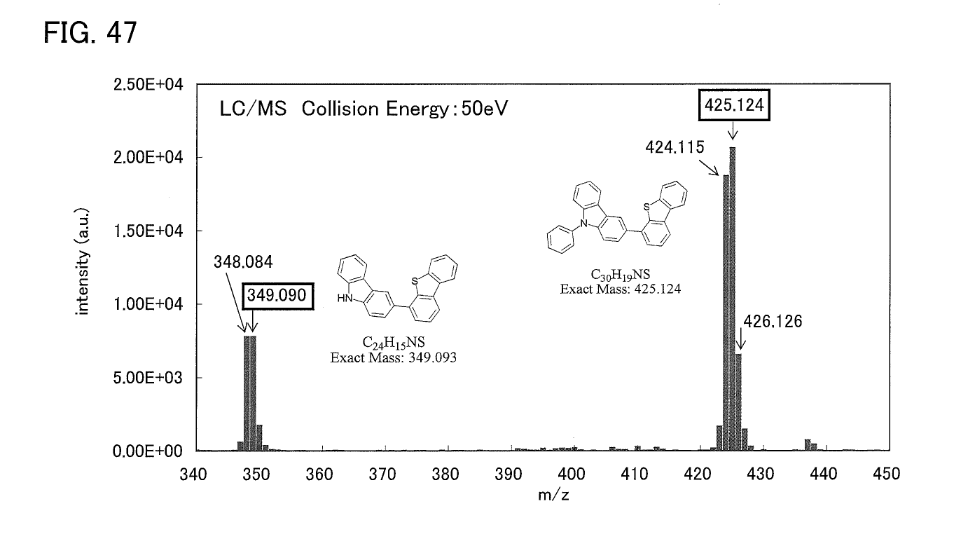

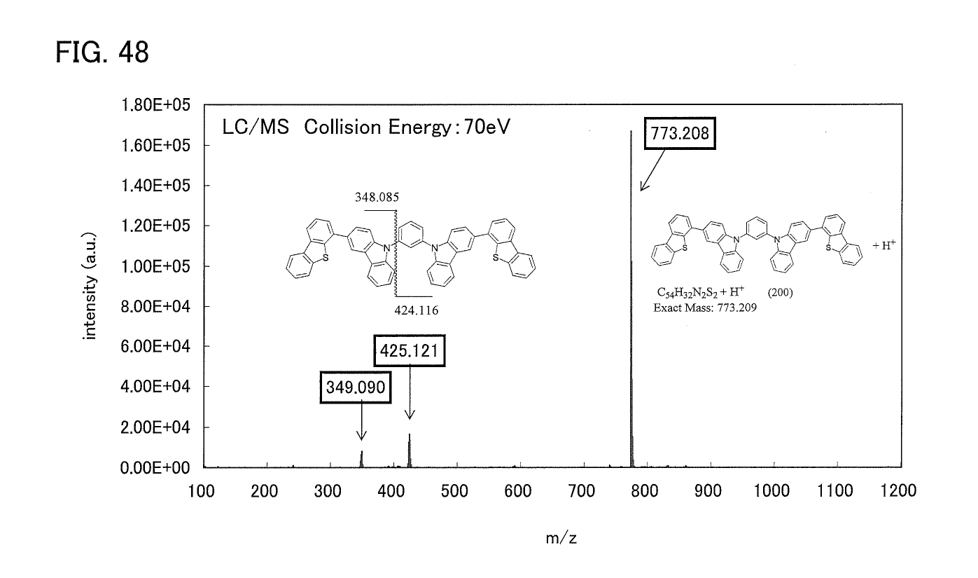

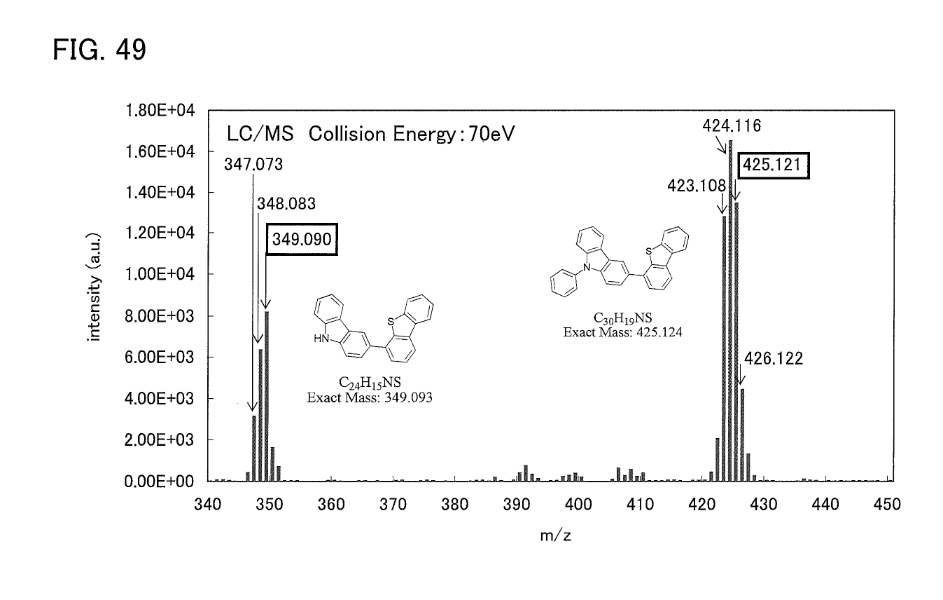

FIG. 46 and FIG. 47 show measurement results given at the time when the collision energy was 50 eV. FIG. 47 is a graph where part of FIG. 46 (the range of m/z=340-450) is enlarged.

As can be seen in FIG. 47, peaks were observed at m/z=348.084, m/z=349.090, m/z=424.115, m/z=425.124, and m/z=426.126. Further, as can be seen in FIG. 46, a peak was observed at m/z=773.208.

Among these peaks, one at m/z=349.090 was presumably derived from a cation, whose composition formula is C₂₄H₁₅NS⁺ (exact mass: 349.093), of a compound which has a dibenzothiophene skeleton and a carbazole skeleton (a compound represented by Structural Formula (201)).

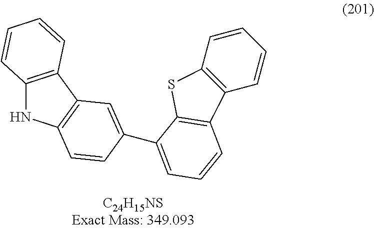 [SMILES: c1ccc2c(c1)[nH]c1ccc(-c3cccc4c3sc3ccccc34)cc12]

The peak at m/z=425.124 was presumably derived from a cation, whose composition formula is C₃₀H₁₉NS⁺ (exact mass: 425.124), of a compound which has a dibenzothiophene skeleton and a carbazole skeleton (a compound represented by Structural Formula (202)).

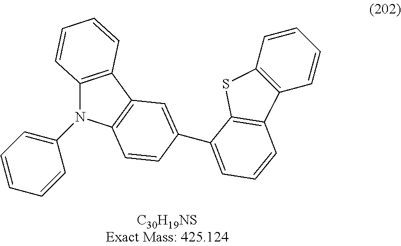 [SMILES: c1ccc(-n2c3ccccc3c3cc(-c4cccc5c4sc4ccccc45)ccc32)cc1]

The peak at m/z=773.208 was presumably derived from mDBTCz2P-II which was protonated (a compound represented by Structural Formula (200)) and whose composition formula is C₅₄H₃₂N₂S₂+H⁺ (exact mass: 773.209).

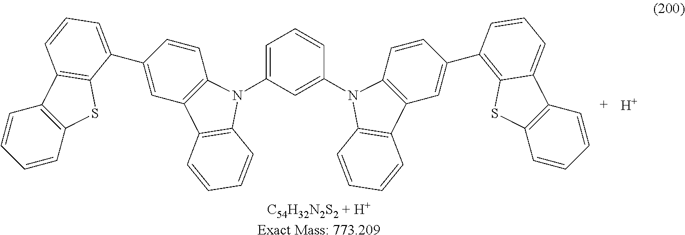

FIG. 48 and FIG. 49 show measurement results given at the time when the collision energy was 70 eV. FIG. 49 is a graph where part of FIG. 48 (the range of m/z=340-450) is enlarged.

As can be seen in FIG. 49, peaks were observed at m/z=347.073, m/z=348.083, m/z=349.090, m/z=423.108, m/z=424.116, m/z=425.121, and m/z=426.122. Further, as can be seen in FIG. 48, a peak was observed at m/z=773.208.

Among these peaks, one at m/z=349.090 was presumably derived from a cation, whose composition formula is C₂₄H₁₅NS⁺ (exact mass: 349.093), of a compound which has a dibenzothiophene skeleton and a carbazole skeleton.

The peak at m/z=425.121 was presumably derived from a cation, whose composition formula is C₃₀H₁₉NS⁺ (exact mass: 425.124), of a compound which has a dibenzothiophene skeleton, a carbazole skeleton, and a benzene ring.

The peak at m/z=773.208 was presumably derived from mDBTCz2P-II which was protonated and whose composition formula is C₅₄H₃₂N₂S₂+H⁺ (exact mass: 773.209).

From FIG. 45, FIG. 46, FIG. 47, FIG. 48, and FIG. 49, it was found that a peak presumably derived from mDBTCz2P-II which was protonated and whose composition formula is C₅₄H₃₂N₂S₂+H⁺ is observed in the LC/MS analysis where the collision energy is set to 30 eV, 50 eV, or 70 eV.

Further, it was shown that a peak presumably derived from a cation, whose composition formula is C₂₄H₁₄NS⁺ (exact mass: 349.093), of a compound which has a dibenzothiophene skeleton and a carbazole skeleton is observed in the LC/MS analysis where the collision energy is set to 50 eV or 70 eV. It was also shown that a peak presumably derived from a cation, whose composition formula is C₃₀H₁₉NS⁺ (exact mass: 425.124), of a compound which has a dibenzothiophene skeleton, a carbazole skeleton, and a benzene ring is observed in the LC/MS analysis where the collision energy is set to 50 eV or 70 eV. These two cations are presumably ones of compounds generated due to a cleavage of the C—N bond between N at the 9-position of the carbazole skeleton and the benzene ring which is bonded to the 9-position of the carbazole skeleton in mDBTCz2P-II.

That is, in an LC/MS analysis, as a result of cleavage in a cation presumed to be mDBTCz2P-II whose composition formula is C₅₄H₃₂N₂S₂ (exact mass: 772.201), at least one of a cation, whose composition formula is C₂₄H₁₄NS⁺ (exact mass: 349.092), of a compound which has a dibenzothiophene skeleton and a carbazole skeleton and a cation, whose composition formula is C₃₀H₁₉NS⁺ (exact mass: 425.124), of a compound which has a dibenzothiophene skeleton, a carbazole skeleton, and a benzene ring is possibly detected as a product ion(s).

Specifically, near a peak derived from a cation whose composition can be inferred, another peak is possibly observed at a mass/charge ratio (m/z) obtained by adding or subtracting a mass/charge ratio (m/z) of approximately 1 to or from a mass/charge ratio (m/z) at which the above peak is observed, as shown in FIG. 47 and FIG. 49. These peaks are derived from an ion which is generated due to protonation to or deprotonation from the compound with the above composition, or an ion which is generated due to the presence of an isotope of an element of the compound with the above composition.

Thus, in an LC/MS analysis carried out in a positive mode, as a cation which is presumed to be mDBTCz2P-II, a mass/charge ratio (m/z) corresponding to a molecular weight of C₅₄H₃₀N₂S₂, C₅₄H₃₁N₂S₂, C₅₄H₃₂N₂S₂, C₅₄H₃₃N₂S₂ or C₅₄H₃₄N₂S₂ is possibly detected. As a cation which is presumed to be a compound having a dibenzothiophene skeleton and a carbazole skeleton, a mass/charge ratio (m/z) corresponding to a molecular weight of C₂₄H₁₂NS, C₂₄H₁₃NS, C₂₄H₁₄NS, C₂₄H₁₅NS or C₂₄H₁₆NS is possibly detected. Further, as a cation which is presumed to be a compound having a dibenzothiophene skeleton, a carbazole skeleton, and a benzene ring, a mass/charge ratio (m/z) corresponding to a molecular weight of C₃₀H₁₇NS, C₃₀H₁₈NS, C₃₀H₁₉NS, C₃₀H₂₀NS or C₃₀H₂₁NS is possibly detected.

Such ions are possibly detected also when an EL layer which is included in a light-emitting element and which contains in mDBTCz2P-II is subjected to an LC/MS analysis.

In other words, when an EL layer which contains mDBTCz2P-II is analyzed by mass spectrometry, an ion having a mass/charge ratio (m/z) of 772 is detected. When cleavage in the ion occurs, at least one of an ion having a mass/charge ratio (m/z) of 349 and an ion having a mass/charge ratio (m/z) of 425 is possibly detected. Here, the ion having a mass/charge ratio (m/z) of 349 and the ion having a mass/charge ratio (m/z) of 425 can be regarded as product ions of the ion having a mass/charge ratio (m/z) of 772.

The above may also be described as follows. When an EL layer which is included in a light-emitting element and which contains mDBTCz2P-II is analyzed by mass spectrometry, an ion whose composition formula is C₅₄H₃₀N₂S₂, C₅₄H₃₁N₂S₂, C₅₄H₃₂N₂S₂, C₅₄H₃₃N₂S₂ or C₅₄H₃₄N₂S₂ is detected. When the ion is analyzed by mass spectrometry, at least one of an ion whose composition formula is C₂₄H₁₂NS, C₂₄H₁₃NS, C₂₄H₁₄NS, C₂₄H₁₅NS or C₂₄H₁₆NS and an ion whose composition formula is C₃₀H₁₇NS, C₃₀H₁₈NS, C₃₀H₁₉NS, C₃₀H₂₀NS or C₃₀H₂₁NS is possibly detected.

The above may also be described as follows. When an EL layer which is included in a light-emitting element and which contains mDBTCz2P-II is analyzed by mass spectrometry, at least one of a mass/charge ratio (m/z) corresponding to a molecular weight of C₅₄H₃₀N₂S₂, C₅₄H₃₁N₂S₂, C₅₄H₃₂N₂S₂, C₅₄H₃₃N₂S₂ or C₅₄H₃₄N₂S₂, a mass/charge ratio (m/z) corresponding to a molecular weight of C₃₀H₁₇NS, C₃₀H₁₈NS, C₃₀H₁₉NS, C₃₀H₂₀NS or C₃₀H₂₁NS, and a mass/charge ratio (m/z) corresponding to a molecular weight of C₂₄H₁₂NS, C₂₄H₁₃NS, C₂₄H₁₄NS, C₂₄H₁₅NS or C₂₄H₁₆NS is possibly detected.

<<Results of the Analysis with the Time-of-Flight Secondary Ion Mass Spectrometer (ToF-SIMS)>>

Next, results of the mass spectrometric analysis with the time-of-flight secondary ion mass spectrometer (ToF-SIMS) are described.

In the ToF-SIMS analysis, TOF.SIMS 5 (produced by ION-TOF GmbH) was used as an apparatus, and Bi₃⁺⁺ was used as a primary ion source. Note that irradiation with primary ions was performed in a pulsed manner with a pulse width of 7 nm to 12 nm. The irradiation amount was greater than or equal to 8.2×10¹⁰ ions/cm² and less than or equal to 6.7×10¹¹ ions/cm² (or less than or equal to 1×10¹² ions/cm²), the acceleration voltage was 25 eV, and the current value was 0.2 pA. In the measurement, a powder of 3,3′-bis(dibenzothiophen-4-yl)-N,N′-(1,3-phenylene)bicarbazole (abbreviation: mDBTCz2P-II) was used as the sample.

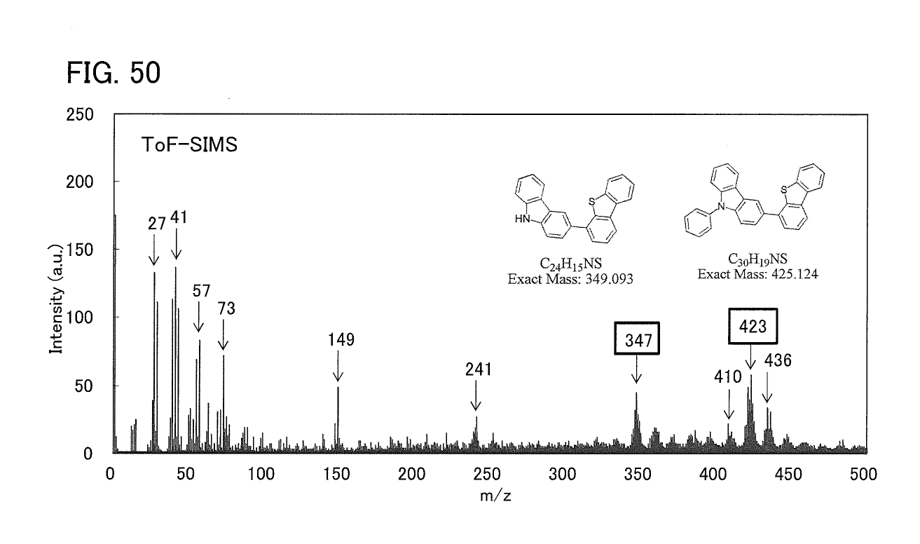

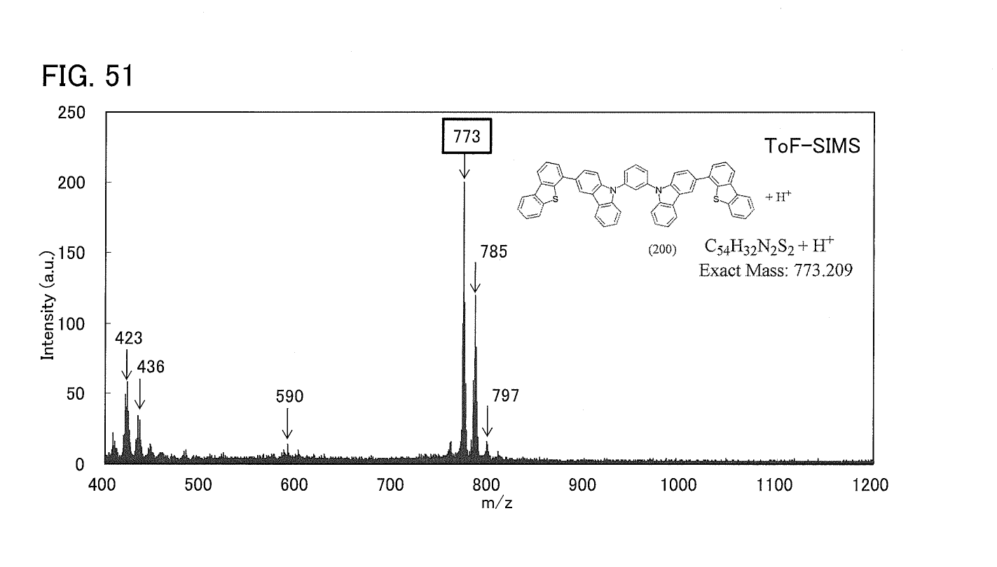

FIG. 50 and FIG. 51 show qualitative spectra (positive ions) measured with the ToF-SIMS as described above. In FIG. 50, the horizontal axis shows the range of m/z=0-500, and in FIG. 51, the horizontal axis shows the range of m/z=400-1200. In each graph, the vertical axis represents intensity (arbitrary unit).

As can be seen in FIG. 50, peaks were observed at m/z=27, m/z=41, m/z=57, m/z=73, m/z=149, m/z=241, m/z=347, m/z=410, m/z=423, and m/z=436. Further, as can be seen in FIG. 51, peaks were observed at m/z=590, m/z=773, m/z=785, and m/z=797.

Among these peaks, one at m/z=347 was presumably derived from a cation whose composition formula is C₂₄H₁₅NS⁺ (exact mass: 349.093) and which was generated by deprotonation from a compound having a dibenzothiophene skeleton and a carbazole skeleton. In the ToF-SIMS analysis, due to protonation to or deprotonation from a compound, or the presence of an isotope of an element of the compound with the above composition, a different cation might be observed at a mass/charge ratio (m/z) obtained by adding or subtracting a mass/charge ratio (m/z) of approximately 1 to or from the exact mass of the compound, and a peak with the highest intensity might be derived from the cation.

The peak at m/z=423 was presumably derived from a cation generated by deprotonation from a compound whose composition formula is C₃₀H₁₉NS (exact mass: 425.124) and which has a dibenzothiophene skeleton, a carbazole skeleton, and a benzene ring.

The peak at m/z=773 was presumably derived from mDBTCz2P-II which was protonated and whose composition formula is C₅₄H₃₂N₂S₂+H⁺ (exact mass: 773.209).

From FIG. 50 and FIG. 51, it was found that a peak presumably derived from mDBTCz2P-II whose composition formula is C₅₄H₃₂N₂S₂ is observed also in a ToF-SIMS analysis. It was also shown that a peak presumably derived from a compound whose composition formula is C₂₄H₁₄NS and which has a dibenzothiophene skeleton and a carbazole skeleton is observed. Further, it was shown that a peak presumably derived from a compound whose composition formula is C₃₀H₁₉NS and which has a dibenzothiophene skeleton, a carbazole skeleton, and a benzene ring is observed.

This application is based on Japanese Patent Application serial no. 2012-249635 filed with Japan Patent Office on Nov. 13, 2012, the entire contents of which are hereby incorporated by reference.

What is claimed is:

1. A compound configured to give a first peak at a mass/charge ratio (m/z) of 773, a second peak at a mass/charge ratio (m/z) of 349 and a third peak at a mass/charge ratio (m/z) of 425 in analysis of the compound by mass spectrometry.

2. The compound according to claim 1,
wherein the analysis of the compound by the mass spectrometry is performed under a condition that a collision energy of an argon gas is set at greater than or equal to 50 eV and less than or equal to 100 eV.

3. The compound according to claim 1,
wherein a first ion having the mass/charge ratio (m/z) of 773, a second ion having the mass/charge ratio (m/z) of 349 and a third ion having the mass/charge ratio (m/z) of 425 are detected in the analysis the compound by the mass spectrometry.

4. The compound according to claim 3,
wherein the second ion and the third ion are each a product ion of the first ion.

5. The compound according to claim 3,
wherein the first ion has a structure in which a carbazole skeleton and a dibenzothiophene skeleton are bonded to each other.

6. The compound according to claim 3,
wherein the second ion has a structure in which a carbazole skeleton and a dibenzothiophene skeleton are bonded to each other, and
wherein the third ion has a structure in which a carbazole skeleton, a dibenzothiophene skeleton and a benzene ring are bonded to one another.

7. A light-emitting element comprising an EL layer between a pair of electrodes, wherein the EL layer comprises the compound according to claim 1.

8. A light-emitting device comprising the light-emitting element according to claim 7.

9. A lighting device comprising the light-emitting element according to claim 7.

10. An electronic device comprising the light-emitting element according to claim 7.

11. A light-emitting element comprising:
an EL layer between a pair of electrodes,
wherein a mass spectrum of the EL layer includes a first peak at a mass/charge ratio (m/z) of 773, a second peak at a mass/charge ratio (m/z) of 349 and a third peak at a mass/charge ratio (m/z) of 425 in analysis of the EL layer by mass spectrometry.

12. The light-emitting element according to claim 11,
wherein the analysis of the EL layer by the mass spectrometry is performed under a condition that a collision energy of an argon gas is set at greater than or equal to 50 eV and less than or equal to 100 eV.

13. The light-emitting element according to claim 11,
wherein a first ion having the mass/charge ratio (m/z) of 773, a second ion having the mass/charge ratio (m/z) of 349 and a third ion having the mass/charge ratio (m/z) of 425 are detected in the analysis of the EL layer by the mass spectrometry.

14. The light-emitting element according to claim 13,
wherein the second ion and the third ion are each a product ion of the first ion.

15. The light-emitting element according to claim 13,
wherein the first ion has a structure in which a carbazole skeleton and a dibenzothiophene skeleton are bonded to each other.

16. The light-emitting element according to claim 13,
wherein the second ion has a structure in which a carbazole skeleton and a dibenzothiophene skeleton are bonded to each other, and
wherein the third ion has a structure in which a carbazole skeleton, a dibenzothiophene skeleton and a benzene ring are bonded to one another.

17. A light-emitting device comprising the light-emitting element according to claim 11.

18. A lighting device comprising the light-emitting element according to claim 11.

19. An electronic device comprising the light-emitting element according to claim 11.
